(19) United States
(12) Patent Application Publication
(10) Pub. No.: US 2013/0009196 A1
(43) Pub. Date: Jan. 10, 2013

(54) LIGHT-EMITTING DIODE ELEMENT AND LIGHT-EMITTING DIODE DEVICE

(75) Inventors: Junko IWANAGA, Osaka (JP); Toshiya YOKOGAWA, Nara (JP); Atsushi YAMADA, Osaka (JP)

(73) Assignee: PANASONIC CORPORATION, Osaka (JP)

(21) Appl. No.: 13/613,464

(22) Filed: Sep. 13, 2012

Related U.S. Application Data
(63) Continuation of application No. PCT/JP2011/001895, filed on Mar. 30, 2011.

(30) Foreign Application Priority Data
Apr. 1, 2010 (JP) 2010-085378
Apr. 1, 2010 (JP) 2010-085379

(51) Int. Cl. H01L 33/62

(52) U.S. Cl. 257/99; 257/E33.062

(57) ABSTRACT

A light-emitting diode element disclosed in the present application, comprises a first semiconductor layer made of a gallium nitride-based compound and having first and second front surface regions and a rear surface, a second semiconductor layer at the first front surface region and an active layer interposed therebetween. A first electrode is provided on a principal surface of the second semiconductor layer. A second electrode is provided at the second front surface region. A third electrode is provided on the rear surface. A thorough hole having openings in the second front surface region and the rear surface is provided in the first semiconductor layer, and a conductor portion is provided in the through hole.

This is a continuation of International Application No. PCT/JP2011/001895, with an international filing date of Mar. 30, 2011, which claims priority of Japanese Patent Application No. 2010-085378 filed on Apr. 1, 2010 and Japanese Patent Application No. 2010-085379 filed on Apr. 1, 2010, the contents of which are hereby incorporated by reference.

### BACKGROUND

1. Technical Field

The present application relates to a light-emitting diode element and a light-emitting diode device, and more particularly, to a light-emitting diode element having a through hole and a light-emitting diode device.

2. Description of the Related Art

A nitride semiconductor including nitrogen (N) as a Group V element is a prime candidate for a material to make a short-wave light-emitting device because its bandgap is sufficiently wide. Among other things, gallium nitride-based compound semiconductors (which will be referred to herein as “GaN-based semiconductors”) have been researched particularly extensively. As a result, blue light-emitting diodes (LEDs), green LEDs, and semiconductor laser diodes composed of GaN-based semiconductors have already been used in actual products (See, for example, Japanese Laid-Open Patent Publication No. 2001-308462 and Japanese Laid-Open Patent Publication No. 2003-332697).

A gallium nitride-based semiconductor has a wurtzite crystal structure. FIG. 1 schematically illustrates a unit cell of GaN. In an AlₐGa_{b}In_{c}N (where 0≦a, b, c≦1 and a+b+c=1) semiconductor crystal, some of the Ga atoms illustrated in FIG. 1 may be replaced with Al and/or In atoms.

FIG. 2 illustrates four primitive vectors a₁, a₂, a₃ and c, which are generally used to represent planes of a wurtzite crystal structure with four indices (i.e., hexagonal indices). The primitive vector c runs in the [0001] direction, which is called a “c-axis”. A plane that intersects with the c-axis at right angles is called either a “c-plane” or a “(0001) plane”. It should be noted that the “c-axis” and the “c-plane” are sometimes referred to as “C-axis” and “C-plane”, respectively.

The wurtzite crystal structure has other typical crystallographic plane orientations than the c-plane, as illustrated in FIG. 3. FIG. 3A illustrates a (0001) plane. FIG. 3B illustrates a (10-10) plane. FIG. 3C illustrates a (11-20) plane. FIG. 3D illustrates a (10-12) plane. As used herein, “—” attached on the left-hand side of a Miller-Bravais index in the parentheses means a “bar”. The (0001) plane, the (10-10) plane, the (11-20) plane, and the (10-12) plane are the c-plane, the m-plane, the a-plane, and the r-plane, respectively. The m-plane and the a-plane are “non-polar planes” that are parallel to the c-axis (primitive vector c), and the r-plane is a “semi-polar plane”.

For years, a light-emitting device in which a gallium nitride-based compound semiconductor is used is manufactured by means of “c-plane growth”. As used herein, the “X-plane growth” means epitaxial growth that is produced perpendicularly to the X plane (where X=c, m, a, r and so forth) of a hexagonal wurtzite structure. As for the X-plane growth, the X plane will be sometimes referred to herein as a “growing plane”. Furthermore, a layer of semiconductor crystals that have been formed as a result of the X-plane growth will be sometimes referred to herein as an “X-plane semiconductor layer”.

When a light-emitting device is manufactured using a semiconductor multilayer structure formed by means of the c-plane growth, strong internal polarization occurs in a direction perpendicular to the c-plane (c-axis direction) because the c-plane is a polar plane. The reason for occurrence of the polarization is that, on the c-plane, there is a shift in the c-axis direction between the positions of a Ga atom and a N atom. If such polarization occurs in a light-emitting section, a quantum confinement Stark effect of carriers occurs. This effect reduces the probability of radiative recombination of carriers in the light-emiting section and accordingly reduces the light emission efficiency.

In view of such circumstances, in recent years, intensive research has been carried out on growth of a gallium nitride-based compound semiconductor on a non-polar plane, such as m-plane and a-plane, and a semi-polar plane, such as r-plane. If a non-polar plane is available as the growing plane, no polarization occurs in the layer thickness direction (crystal growth direction) of the light-emiting section. Therefore, the quantum confinement Stark effect does not occur. Thus, a light-emitting device which potentially has high efficiency can be manufactured. Even when the growing plane is a semi-polar plane, the influence of the quantum confinement Stark effect can be greatly reduced.

Light-emitting diode products commercially available in the present market are manufactured by mounting to a submount a light-emitting diode element (LED chip) which is manufactured by epitaxially growing a GaN-based semiconductor layer, such as GaN, InGaN, AlGaN, or the like, on a c-plane substrate. The planar size of a light-emitting diode element (the planar size of the principal surface of the substrate: hereinafter, simply referred to as “chip size”) varies depending on the use of the light-emitting diode element. Typical chip size is, for example, 300 μm×300 μm or 1 mm×1 mm.

The arrangement of the electrodes of the light-emitting diode element can be generally classified into two types. One is the “opposite-surface electrode type” wherein the p-electrode (anode electrode) and the n-electrode (cathode electrode) are provided on the front surface and the rear surface, respectively, of the light-emitting diode element. The other one is the “front-surface electrode type” wherein both the p-electrode and the n-electrode are provided on the front surface of the light-emitting diode element. Hereinafter, the configurations of prior art light-emitting diode elements which have such electrode arrangements will be described.

FIG. 4A is a cross-sectional view illustrating a light-emitting diode element 115 of the opposite-surface electrode type. FIG. 4B is a top view of the light-emitting diode element 115 of the opposite-surface electrode type. FIG. 4C is a cross-sectional view illustrating the light-emitting diode element 115 of the opposite-surface electrode type which is mounted on a mounting base 112. FIG. 5A is a cross-sectional view illustrating a light-emitting diode element 114 of the front-surface electrode type which is mounted on the mounting base 112. FIG. 5B is a side view of the light-emitting diode element 114 of the front-surface electrode type, which is seen from the side including a p-electrode (anode electrode) 105 and an n-type front surface electrode (cathode electrode) 106.

In the example illustrated in FIG. 4A and FIG. 4B, a multilayer structure is provided on an n-type substrate 101 which is made of GaN. The multilayer structure includes an n-type conductive layer 102 which is made of GaN, an active layer 103 which is composed of a quantum well of InGaN and GaN, and a p-type conductive layer 104 which is made of GaN. The p-electrode 105 is provided on the p-type conductive layer 104, and an n-type rear surface electrode 107 is provided on the rear surface of the substrate 101. In this example, light emitted by the active layer 103 is extracted through the rear surface of the substrate 101. As such, the n-type rear surface electrode 107 is made of a transparent electrode material. When the n-type rear surface electrode 107 is made of a nontransparent conductive material, the n-type rear surface electrode 107 is provided in part of the rear surface of the substrate 101 so as not to block the light. When mounting a light-emitting diode element of the opposite-surface electrode type wherein the n-type rear surface electrode 107 is transparent, the p-electrode 105 is arranged so as to be located on the mounting base 112 side as illustrated in FIG. 4C. On the n-type rear surface electrode 107, a bonding pad 122 is provided. The bonding pad 122 is electrically connected to the mounting base 112 via a wire 123.

In the example illustrated in FIG. 5A and FIG. 5B, the p-type conductive layer 104, the active layer 103, and the n-type conductive layer 102 are partially removed, and the n-type front surface electrode 106 is provided on the exposed part of the n-type conductive layer 102. The p-electrode 105 is provided on the p-type conductive layer 104. In this example, light generated in the active layer 103 is extracted through the rear surface of the substrate 101. Therefore, when mounting a light-emitting diode element of this type, the diode element is mounted such that the p-electrode 105 and the n-type front surface electrode 106 are located on the mounting base 112 side.

In the case of the opposite-surface electrode type, the electric resistance between the p-electrode 105 and the n-type front surface electrode 106 is greatly affected by the resistance component of the substrate 101. Therefore, the resistance of the substrate 101 may be reduced as small as possible. The GaN semiconductor is doped with an n-type impurity at a relatively high concentration than a p-type impurity. Therefore, in general, a low resistance is realized more readily with the n-type impurity. Thus, commonly, the conductivity type of the substrate 101 is set to the n-type.

Also, in the case of the front-surface electrode type, the electric resistance between the p-electrode 105 and the n-type front surface electrode 106 is affected by the resistance component of the substrate 101. Therefore, commonly, the conductivity type of the substrate 101 is set to the n-type.

The above-described electrode arrangements have been employed in c-plane light-emitting diode elements.

### SUMMARY

The conventional devices are associated with the deterioration of a power efficiency due to the contact resistance and the resistance of the conductive layer and a decrease of the internal quantum efficiency due to an increase in chip temperature.

One non-limiting, and exemplary embodiments provides a light-emitting diode element having high power efficiency and high internal quantum efficiency, in which a contact resistance and a resistance in an n-type conductive layer are decreased to thereby suppress an increase in chip temperature.

In one general aspect, a light-emitting diode element, comprises: a first semiconductor layer of a first conductivity type having a first front surface region, a second front surface region, and a rear surface, the first semiconductor layer being made of a gallium nitride-based compound; a second semiconductor layer of a second conductivity type, which is provided at the first front surface region; an active layer, which is positioned between the first semiconductor layer and the second semiconductor layer; a first electrode, which is provided on a principal surface of the second semiconductor layer; a first insulating film, which is provided on an inner wall of a through hole, the through hole penetrating through the first semiconductor layer and having openings in the second front surface region and the rear surface; a conductor portion, which is provided on a surface of the first insulating film inside the through hole; a second electrode, which is provided at the second front surface region and is in contact with the conductor portion; and a third electrode, which is provided on the rear surface of the first semiconductor layer and is in contact with the conductor portion, wherein, when seen in a direction perpendicular to a principal surface of the first semiconductor layer, the third electrode is provided in a region that overlaps the first electrode.

In another aspect, a light-emitting diode device, comprises: the light-emitting diode element; and a mounting base, wherein the light-emitting diode element is disposed on the mounting base so that a side on which the first electrode and the second electrode are disposed faces the mounting base.

According to the above aspects, the third electrode (n-type rear surface electrode) is provided, and the third electrode is electrically connected to the second electrode (n-type front surface electrode) via the conductor portion provided in the through hole, and hence the contact area between the first semiconductor layer and the electrode can be increased as compared with the conventional one. This can decrease the contact resistance between the first semiconductor layer and the electrode as a whole. Therefore, the voltage to be applied to the active layer can be maintained to a sufficient level, to thereby increase power efficiency. Further, the third electrode and the first electrode are opposed to each other across the first semiconductor layer, and hence almost all electric currents flow uniformly between the third electrode and the first electrode. Therefore, as compared with the conventional front-surface electrode type light-emitting diode element, the concentration of electric current on the vicinity of a cathode electrode is alleviated, and hence the non-uniformity of electric current and the non-uniformity of light emission can be reduced.

Additional benefits and advantages of the disclosed embodiments will be apparent from the specification and Figures. The benefits and/or advantages may be individually provided by the various embodiments and features of the specification and drawings disclosure, and need not all be provided in order to obtain one or more of the same.

### BRIEF DESCRIPTION OF THE DRAWINGS

FIG. 1 is a diagram schematically illustrating a unit cell of GaN.

FIG. 2 is a diagram illustrating four primitive vectors a₁, a₂, a₃ and c, which are generally used to represent planes of a wurtzite crystal structure with four indices (i.e., hexagonal indices).

FIG. 3A illustrates the (0001) plane.

FIG. 3B illustrates the (10-10) plane.

FIG. 3C illustrates the (11-20) plane.

FIG. 3D illustrates the (10-12) plane.

FIG. 4A is a cross-sectional view illustrating a light-emitting diode element 115 of the opposite-surface electrode type.

FIG. 4B is a top view of the light-emitting diode element 115 of the opposite-surface electrode type.

FIG. 4C is a cross-sectional view illustrating the light-emitting diode element 115 of the opposite-surface electrode type which is mounted on a mounting base 112.

FIG. 5A is a cross-sectional view illustrating a light-emitting diode element 114 of the front-surface electrode type which is mounted on the mounting base 112.

FIG. 5B is a side view of the light-emitting diode element 114 of the front-surface electrode type, which is seen from the side including a p-electrode 105 and an n-type front surface electrode 106.

FIG. 6A is a cross-sectional view illustrating a light-emitting diode device 14A according to a reference example invented by the inventors.

FIG. 6B is a plan view illustrating a rear surface of a light-emitting diode element 14 illustrated in FIG. 6A.

FIG. 6C is a plan view illustrating a principal surface of the light-emitting diode element 14.

FIG. 7 is a graph showing simulation results of a light emission rate of the light-emitting diode element 14 illustrated in FIG. 6.

FIG. 8A is a cross-sectional view illustrating a light-emitting diode device 31A according to Embodiment 1.

FIG. 8B is a plan view illustrating a rear surface of a light-emitting diode element 30A illustrated in FIG. 8A.

FIG. 8C is a plan view illustrating a principal surface of the light-emitting diode element 30A.

FIG. 9A is a graph showing simulation results of a light emission rate of the light-emitting diode device 31A illustrated in FIG. 8.

FIG. 9B shows results obtained by a simulation assuming the light-emitting diode device 31A.

FIG. 10A is a cross-sectional view illustrating a light-emitting diode device 31B according to Embodiment 2.

FIG. 10B is a plan view illustrating a rear surface of a light-emitting diode element 30B illustrated in FIG. 10A.

FIG. 10C is a plan view illustrating a principal surface of the light-emitting diode element 30B.

FIG. 11A is a cross-sectional view illustrating a light-emitting diode device 31C according to Embodiment 3.

FIG. 11B is a plan view illustrating a rear surface of a light-emitting diode element 30C illustrated in FIG. 11A.

FIG. 11C is a plan view illustrating a principal surface of the light-emitting diode element 30C.

FIG. 12A is a cross-sectional view illustrating a first light-emitting diode device 33A according to Embodiment 4.

FIG. 12B is a plan view illustrating a rear surface of a light-emitting diode element 32A illustrated in FIG. 12A.

FIG. 12C is a plan view illustrating a principal surface of the light-emitting diode element 32A.

FIG. 13A is a cross-sectional view illustrating a second light-emitting diode device 33B according to Embodiment 4.

FIG. 13B is a plan view illustrating a rear surface of a light-emitting diode element 32B illustrated in FIG. 13A.

FIG. 13C is a plan view illustrating a principal surface of the light-emitting diode element 32B.

FIG. 14A is a cross-sectional view illustrating a third light-emitting diode device 33C according to Embodiment 4.

FIG. 14B is a plan view illustrating a light-emitting diode element 32C illustrated in FIG. 14A.

FIG. 14C is a plan view illustrating a principal surface of the light-emitting diode element 32C.

FIG. 15 is a graph showing simulation results of light emission rates of the first, second, and third light-emitting diode devices 33A, 33B, and 33C of Embodiment illustrated in FIGS. 12 to 14.

FIG. 16A is a cross-sectional view illustrating a first light-emitting diode device 35A according to Embodiment 5.

FIG. 16B is a plan view illustrating a rear surface of a light-emitting diode element 34A illustrated in FIG. 16A.

FIG. 16C is a plan view illustrating a principal surface of the light-emitting diode element 34A.

FIG. 17A is a cross-sectional view illustrating a second light-emitting diode device 35B according to Embodiment 5.

FIG. 17B is a plan view illustrating a rear surface of a light-emitting diode element 34B illustrated in FIG. 17A.

FIG. 17C is a plan view illustrating a principal surface of the light-emitting diode element 34B.

FIG. 18A is a cross-sectional view illustrating a third light-emitting diode device 35C according to Embodiment 5.

FIG. 18B is a plan view illustrating a rear surface of a light-emitting diode element 34C illustrated in FIG. 18A.

FIG. 18C is a plan view illustrating a principal surface of the light-emitting diode element 34C.

FIG. 19A is a cross-sectional view illustrating a first light-emitting diode device 37A according to Embodiment 6.

FIG. 19B is a plan view illustrating a rear surface of a light-emitting diode element 36A illustrated in FIG. 19A.

FIG. 19C is a plan view illustrating a front surface on a principal surface side of the light-emitting diode element 36A.

FIG. 20A, is a cross-sectional view illustrating a second light-emitting diode device 37B according to Embodiment 6.

FIG. 20B is a plan view illustrating a rear surface of a light-emitting diode element 36B illustrated in FIG. 20A.

FIG. 20C is a plan view illustrating a principal surface of the light-emitting diode element 36B.

FIG. 21A is a cross-sectional view illustrating a third light-emitting diode device 37C according to Embodiment 6.

FIG. 21B is a plan view illustrating a rear surface of a light-emitting diode element 36C illustrated in FIG. 21A.

FIG. 21C is a plan view illustrating a principal surface of the light-emitting diode element 36C.

FIG. 22 is a plan view illustrating an n-type rear surface electrode 7 having a lattice shape.

FIG. 23A is a cross-sectional view illustrating a first light-emitting diode device 39A according to Embodiment 7.

FIG. 23B is a plan view illustrating a rear surface of a light-emitting diode element 38A illustrated in FIG. 23A.

FIG. 23C is a plan view illustrating a principal surface of the light-emitting diode element 38A.

FIG. 24A is a cross-sectional view illustrating a second light-emitting diode device 39B according to Embodiment 7.

FIG. 24B is a plan view illustrating a rear surface of a light-emitting diode element 38B illustrated in FIG. 24A.

FIG. 24C is a plan view illustrating a principal surface of the light-emitting diode element 38B.

FIG. 25A is a cross-sectional view illustrating a third light-emitting diode device 39C according to Embodiment 7.

FIG. 25B is a plan view illustrating a rear surface of a light-emitting diode element 38C illustrated in FIG. 25A.

FIG. 25C is a plan view-illustrating a principal surface of the light-emitting diode element 38C.

FIG. 26A is a cross-sectional view illustrating first a light-emitting diode device 41A according to Embodiment 8, FIG. 26B is a plan view illustrating a rear surface of a light-emitting diode element 40A illustrated in FIG. 26A.

FIG. 26C is a plan view illustrating a principal surface of the light-emitting diode element 40A illustrated in FIG. 26A.

FIG. 27A is a cross-sectional view illustrating a second light-emitting diode device 41B according to Embodiment 8.

FIG. 27B is a plan view illustrating a rear surface of a light-emitting diode element 40B illustrated in FIG. 27A.

FIG. 27C is a plan view illustrating a principal surface of the light-emitting diode element 40B illustrated in FIG. 27A.

FIG. 28A is a cross-sectional view illustrating a light-emitting diode device 51A according to Embodiment 9.

FIG. 28B is a plan view illustrating a rear surface of a light-emitting diode element 50A illustrated in FIG. 28A.

FIG. 28C is a plan view illustrating a principal surface of the light-emitting diode element 50A.

FIGS. 29A and 29B are graphs showing a temperature distribution and a light emission rate, respectively, along the A-A′ cross section of an active layer 3 of the light-emitting diode device 51A illustrated in FIG. 28.

FIG. 29C is a graph showing an electric current dependence of a light output.

FIG. 30A is a cross-sectional view illustrating a light-emitting diode device 51B of Embodiment 10.

FIG. 30B is a plan view illustrating a rear surface of a light-emitting diode element 50B illustrated in FIG. 30A.

FIG. 30C is a plan view illustrating a principal surface of the light-emitting diode element 50B illustrated in FIG. 30A.

FIG. 31A is a cross-sectional view illustrating a light-emitting diode device 51C according to Embodiment 11.

FIG. 31B is a plan view illustrating a rear surface of a light-emitting diode element 50C illustrated in FIG. 31A.

FIG. 31C is a plan view illustrating a principal surface of the light-emitting diode element 50C illustrated in FIG. 31A.

FIG. 32A is a cross-sectional view illustrating a light-emitting diode device 51D according to Embodiment 12.

FIG. 32B is a plan view illustrating a rear surface of a light-emitting diode element 50D illustrated in FIG. 32A.

FIG. 32C is a plan view illustrating a principal surface of the light-emitting diode element 50D illustrated in FIG. 32A.

FIG. 33A is a cross-sectional view illustrating a first light-emitting diode device 53A according to Embodiment 13.

FIG. 33B is a plan view illustrating a rear surface of a light-emitting diode element 52A illustrated in FIG. 33A.

FIG. 33C is a plan view illustrating a principal surface of the light-emitting diode element 52A illustrated in FIG. 33A.

FIG. 34A is a cross-sectional view illustrating a second light-emitting diode device 53B according to Embodiment 13.

FIG. 34B is a plan view illustrating a rear surface of a light-emitting diode element 52B illustrated in FIG. 34A.

FIG. 34C is a plan view illustrating a principal surface of the light-emitting diode element 52B illustrated in FIG. 34A.

FIG. 35 is a graph showing simulation results of light emission rates of the light-emitting diode devices 51A, 51C, and 53A illustrated in FIGS. 28, 31, and 33.

FIG. 36A is a cross-sectional view illustrating a first light-emitting diode device 55A according to Embodiment 14.

FIG. 36B is a plan view illustrating a rear surface of a light-emitting diode element 54A illustrated in FIG. 36A.

FIG. 36C is a plan view illustrating a principal surface of the light-emitting diode element 54A illustrated in FIG. 36A.

FIG. 37A is a cross-sectional view illustrating a second light-emitting diode device 55B according to Embodiment 14.

FIG. 37B is a plan view illustrating a rear surface of a light-emitting diode element 54B illustrated in FIG. 37A.

FIG. 37C is a plan view illustrating a principal surface of the light-emitting diode element 54B illustrated in FIG. 37A.

FIG. 38A is a cross-sectional view illustrating a first light-emitting diode device 57A according to Embodiment 15.

FIG. 38B is a plan view illustrating a rear surface of a light-emitting diode element 56A illustrated in FIG. 38A.

FIG. 38C is a plan view illustrating a principal surface of the light-emitting diode element 56A illustrated in FIG. 38A.

FIG. 39A is a cross-sectional view illustrating a second light-emitting diode device 57B according to Embodiment 15.

FIG. 39B is a plan view illustrating a rear surface of a light-emitting diode element 56B illustrated in FIG. 39A.

FIG. 39C is a plan view illustrating a principal surface of the light-emitting diode element 56B illustrated in FIG. 39A.

FIG. 40A is a cross-sectional view illustrating a third light-emitting diode device 57C according to Embodiment 15.

FIG. 40B is a plan view illustrating a light-emitting diode element 56C illustrated in FIG. 40A.

FIG. 40C is a plan view illustrating a principal surface of the light-emitting diode element 56C illustrated in FIG. 40A.

FIG. 41A is a cross-sectional view illustrating a fourth light-emitting diode device 57D according to Embodiment 15.

FIG. 41B is a plan view illustrating a rear surface of a light-emitting diode element 56D illustrated in FIG. 41A.

FIG. 41C is a plan view illustrating a principal surface of the light-emitting diode element 56D illustrated in FIG. 41A.

FIG. 42A is a cross-sectional view illustrating a first light-emitting diode device 59A according to Embodiment 16.

FIG. 42B is a plan view illustrating a rear surface of a light-emitting diode element 58A illustrated in FIG. 42A.

FIG. 42C is a plan view illustrating a principal surface of the light-emitting diode element 58A illustrated in FIG. 42A.

FIG. 43A is a cross-sectional view illustrating a second light-emitting diode device 59B according to Embodiment 17.

FIG. 43B is a plan view illustrating a rear surface of a light-emitting diode element 58B illustrated in FIG. 43A.

FIG. 43C is a plan view illustrating a principal surface of the light-emitting diode element 58B illustrated in FIG. 43A.

FIG. 44 is a plan view illustrating the n-type rear surface electrode 7 having a lattice shape.

FIG. 45A is a cross-sectional view illustrating a light-emitting diode device 61A according to Embodiment 17.

FIG. 45B is a plan view illustrating a rear surface of a light-emitting diode element 60A illustrated in FIG. 45A.

FIG. 45C is a plan view illustrating a principal surface of the light-emitting diode element 60A.

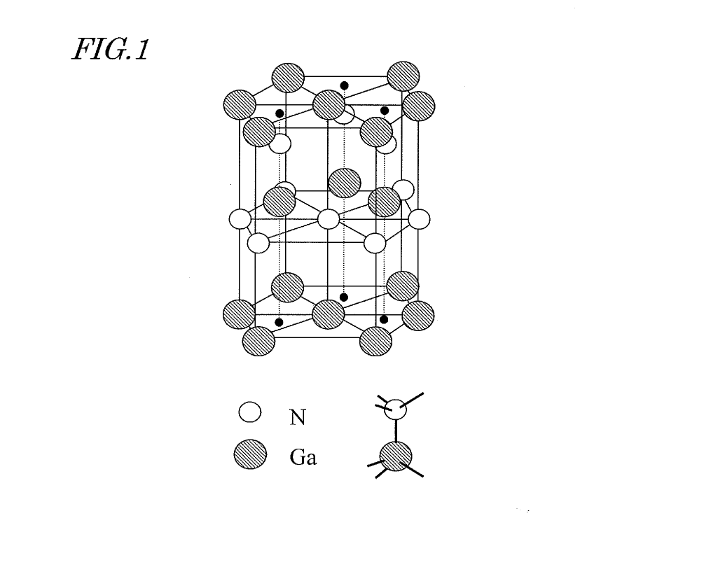

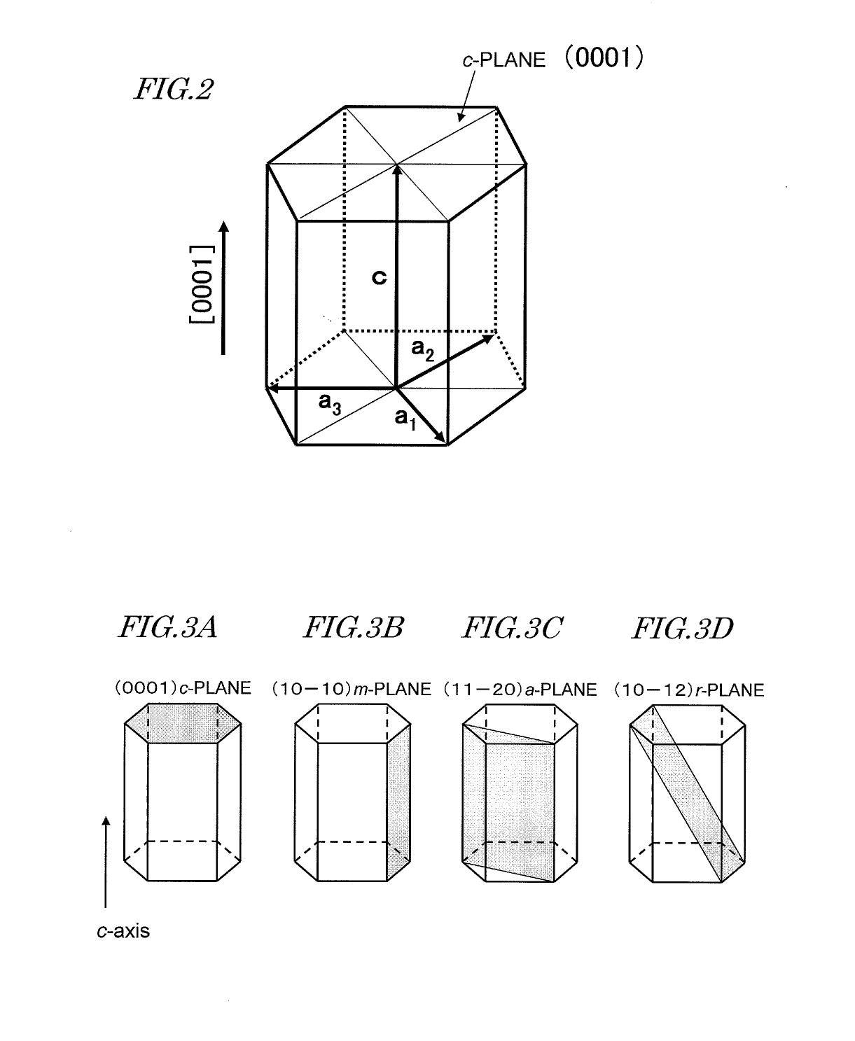

### DETAILED DESCRIPTION

The inventors carefully studied the conventional devices and found that as the input current increases, the voltage applied to the active layer decreases so that the power efficiency deteriorates due to the contact resistance and the resistance of the conductive layer. Also, the inventors found a problem in that a dark current generated due to carriers overflowing from the active layer, or an increase in chip temperature which is attributed to the resistances of the conductive layer and the contact portion, leads to a decrease of the internal quantum efficiency.

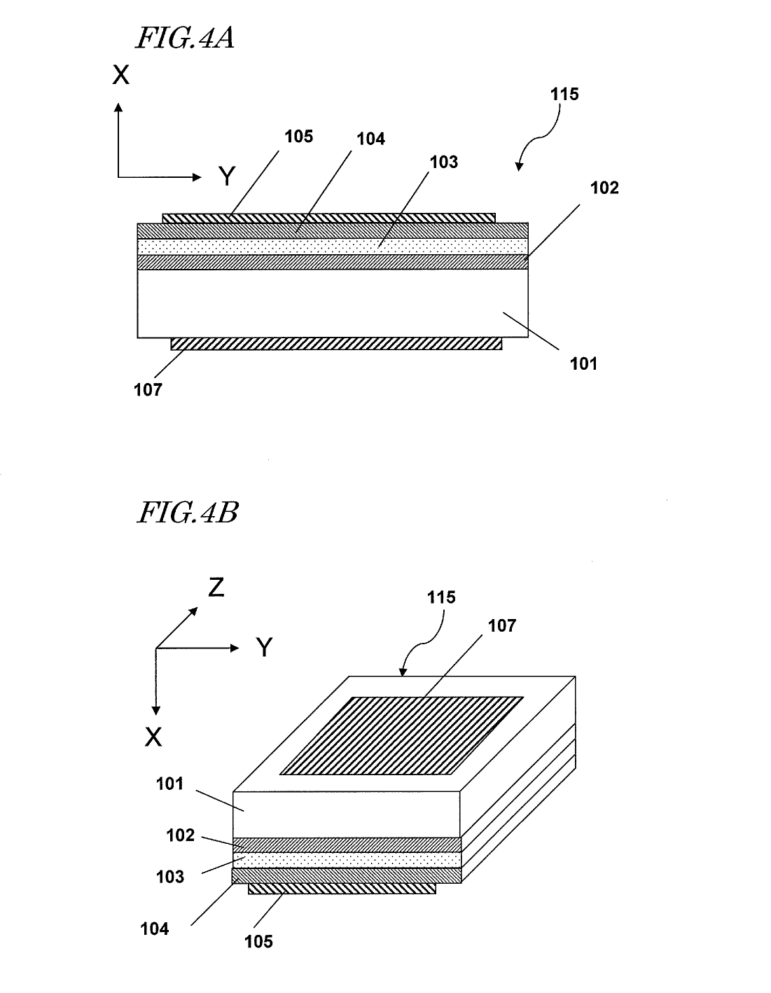

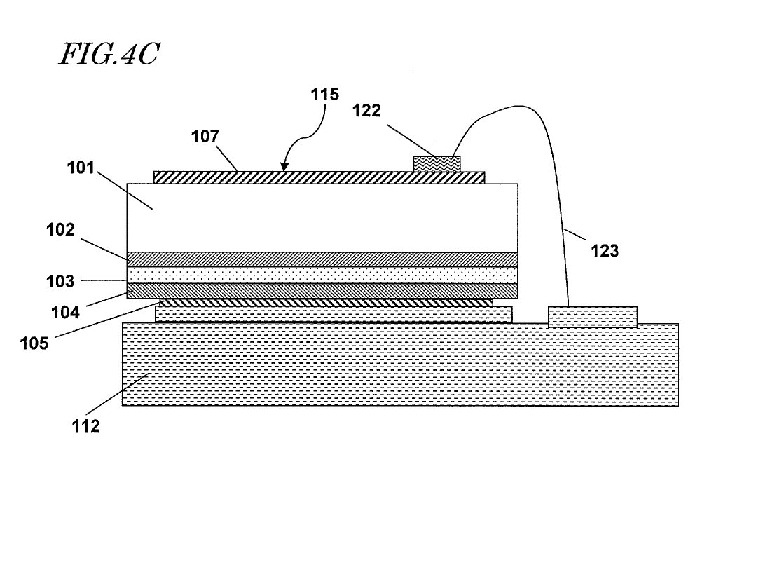

In the opposite-surface electrode type light-emitting diode element 115 illustrated in FIGS. 4A to 4C, the n-type rear surface electrode 107 and the mounting base 112 are connected to each other by wire bonding. The light-emitting diode element 115 generates heat during high-power operation, and the chip temperature becomes around 400 K. The heat releasability of wire bonding is lower than that of bumps, and the light-emitting diode element 115 mounted by wire bonding is heated to high temperature. Therefore, the opposite-surface electrode type light-emitting diode element 115 has a problem in that the reliability of wire bonding is decreased under heat generation.

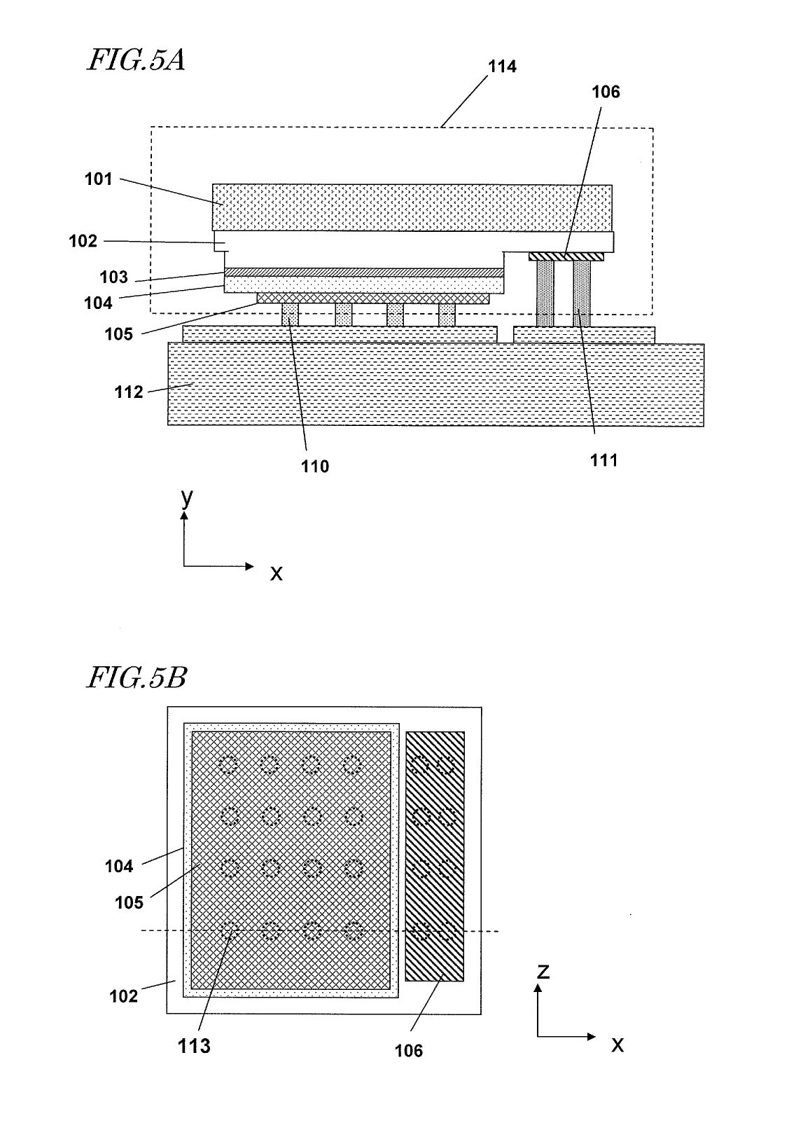

In the case of the front-surface electrode type light-emitting diode element 114 illustrated in FIG. 5, a large amount of electric current concentrates on the vicinity of the n-type front surface electrode 106 during high-power operation. Therefore, there is a problem in that a portion having high electric current density generates heat to decrease light emission efficiency. Further, due to the resistance of the n-type conductive layer 102, a bias cannot be easily applied to a region of the active layer 103 which is far from the n-type front surface electrode 106, and a sufficient electric current does not flow. Therefore, sufficient light emission intensity cannot be obtained. In addition, the electric current density is non-uniform, and hence a light emission distribution is also non-uniform.

As described above, the opposite-surface electrode type light-emitting diode element has a structure in which the electric current density is uniform and high power can be input easily, but has a problem of low reliability when mounted. On the other hand, the front-surface electrode type light-emitting diode element has high reliability because mounting is performed with the use of bumps, but has a problem in that the electric current density is non-uniform and the efficiency is low when high power is input.

Particularly in the case of using an m-plane GaN layer, the impurity concentration of an n-type conductive layer is low and the resistance in the n-type conductive layer increases, as compared with the case of using a c-plane GaN layer. Further, the m-plane GaN layer has a tendency that the contact resistance of an n-electrode is higher due to its crystal structure than the c-plane GaN. As a result of the increase in those resistances, the power efficiency deteriorates, and heat is more likely to be generated.

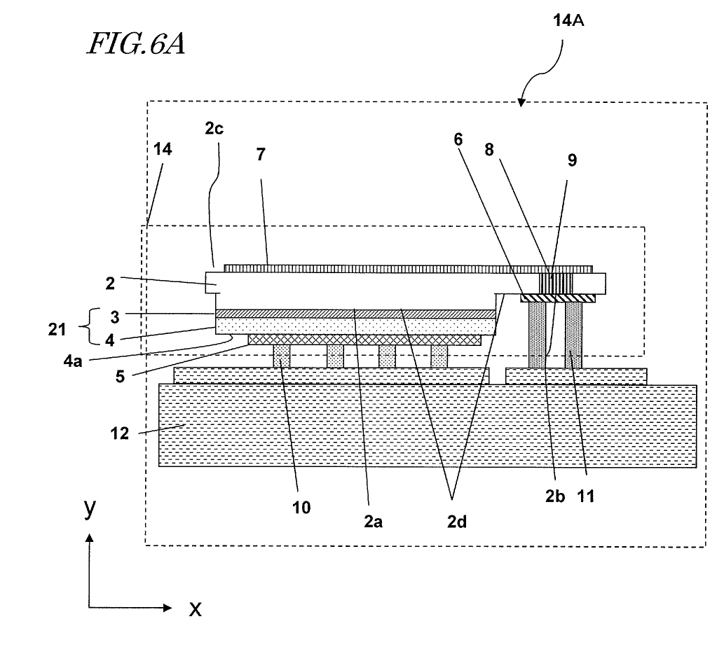

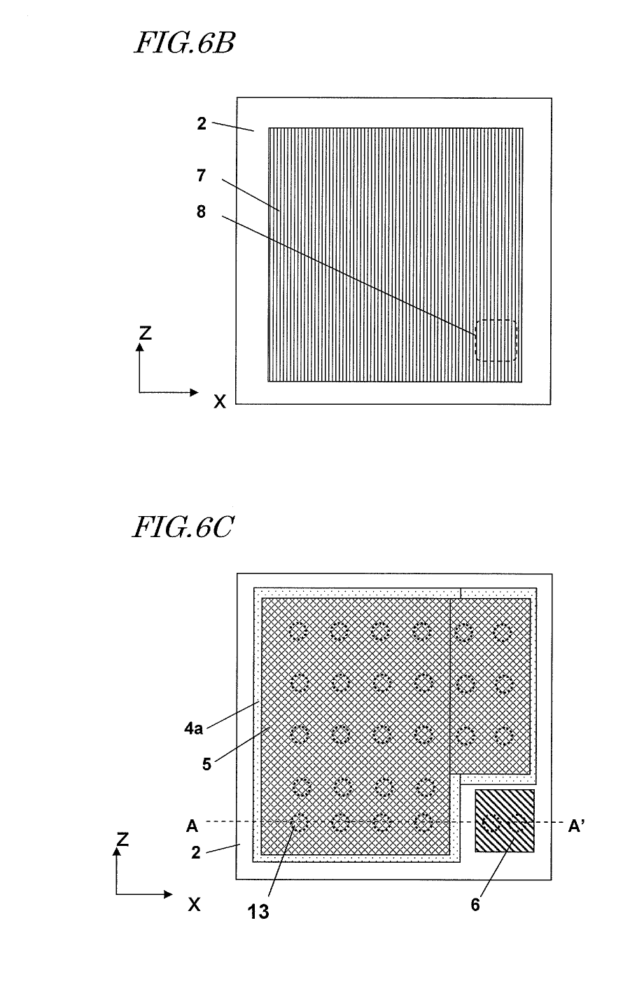

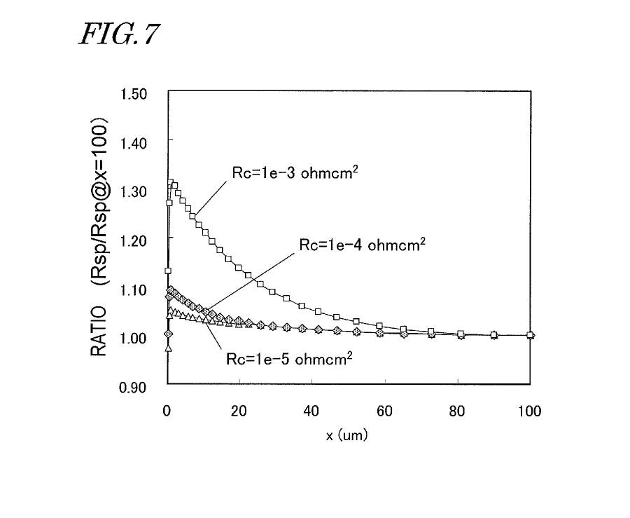

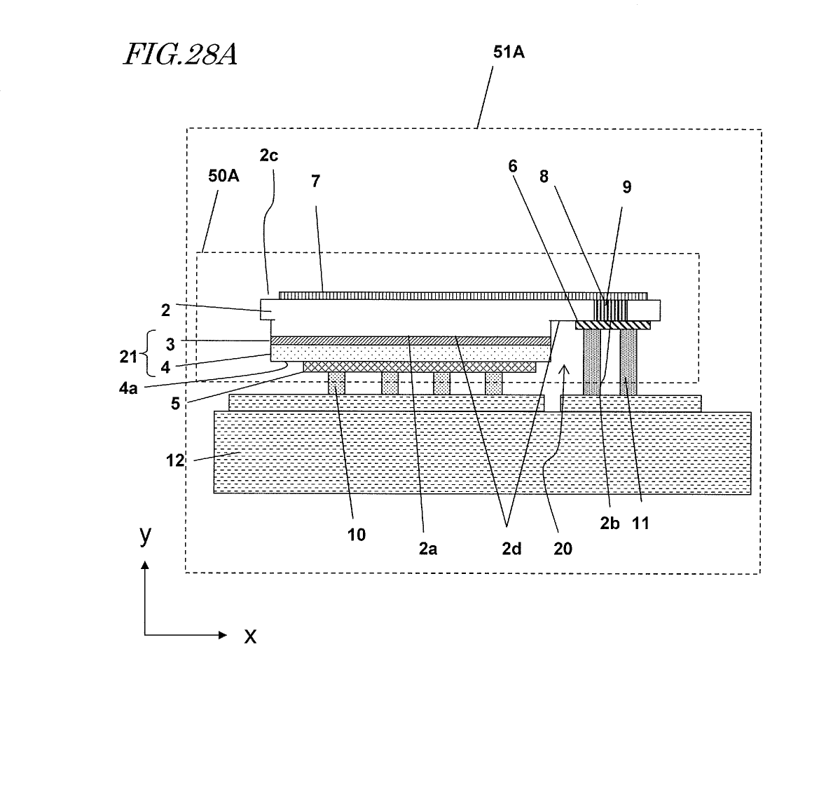

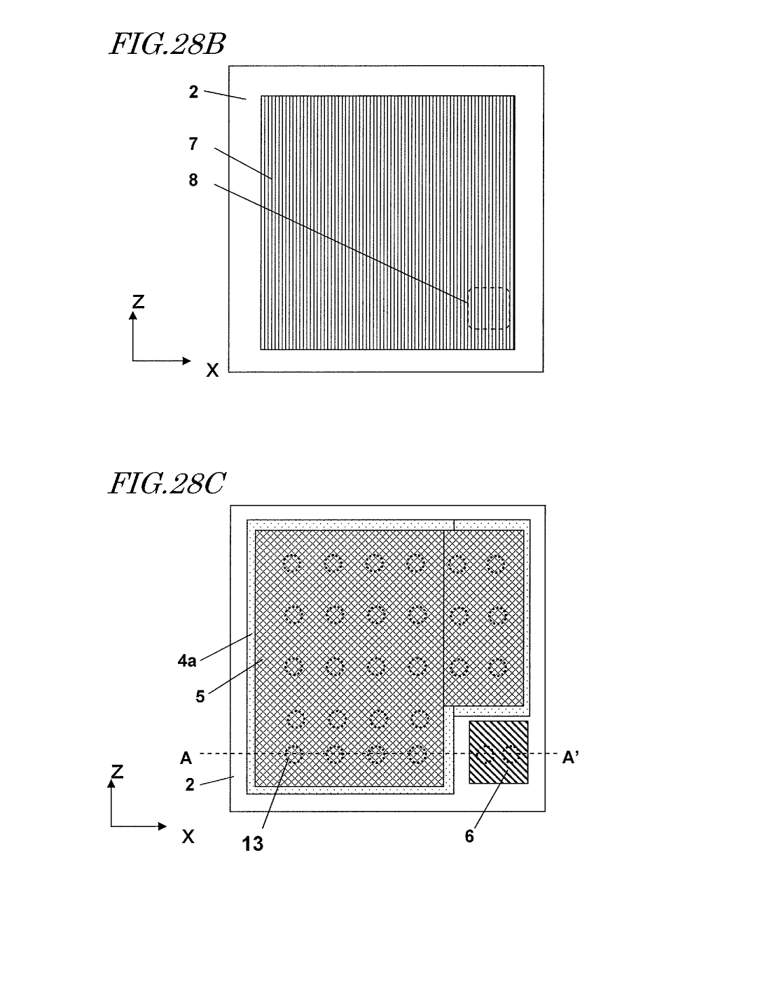

Hereinafter, first, a light-emitting diode device having an m-plane principal surface according to a reference example is described with reference to FIGS. 6A to 6C. After that, light-emitting diode devices each having an m-plane principal surface are described with reference to FIGS. 7 to 27 (Embodiments 1 to 8), and light-emitting diode devices each having a principal surface other than the m-plane are described with reference to FIGS. 28 to 45 (Embodiments 9 to 17).

FIG. 6A is a cross-sectional view illustrating a light-emitting diode device 14A according to the reference example invented by the inventors. FIG. 6B is a plan view illustrating a rear surface of a light-emitting diode element illustrated in FIG. 6A. FIG. 6C is a plan view illustrating a principal surface of the light-emitting diode element 14. Note that, FIG. 6A is a cross-sectional view taken along the line A-A′ of FIG. 6C.

As illustrated in FIG. 6A, the light-emitting diode device 14A of the reference example has a configuration in which the light-emitting diode element (chip) 14 is mounted on a mounting base 12. The light-emitting diode element 14 is provided on the mounting base 12 via bumps 10 and 11. The bump 10 connects a p-electrode 5 of the light-emitting diode element 14 and the mounting base 12 to each other. The bump 11 connects an n-type front surface electrode 6 of the light-emitting diode element 14 and the mounting base 12 to each other.

The light-emitting diode element 14 includes an n-type conductive layer 2 made of n-type GaN, an active layer 3 provided in a first region 2a (first front surface region) of a principal surface 2d of the n-type conductive layer 2, and a p-type conductive layer 4 made of p-type GaN provided on a principal surface of the active layer 3.

The active layer 3 has, for example, a quantum well structure which is formed by stacked layers of, for example, InGaN and GaN. Each of the n-type conductive layer 2, the active layer 3, and the p-type conductive layer 4 is an epitaxially grown layer which is formed by means of m-plane growth. The n-type impurity concentration in the n-type conductive layer 2 is, for example, 1×10¹⁷ cm⁻³ or more and 1×10¹⁸ cm⁻³ or less.

As illustrated in FIG. 6C, the p-electrode 5 is provided on a principal surface 4a of the p-type conductive layer 4, and the n-type front surface electrode 6 is provided on a second region (second front surface region) 2b of the principal surface 2d of the n-type conductive layer 2.

The n-type conductive layer 2 is provided with a through hole 8 that penetrates through the n-type conductive layer 2. The through hole 8 is filled with a conductor portion (n-type through electrode) 9 which is formed by Ti/Al layers. The conductor portion 9 is in contact with the n-type front surface electrode 6 in the second region 2b of the principal surface 2d of the n-type conductive layer 2. On the other hand, on a rear surface 2c of the n-type conductive layer 2, an n-type rear surface electrode 7 is provided so as to be in contact with the conductor portion 9. As illustrated in FIG. 6B, on the rear surface 2c of the n-type conductive layer 2, the n-type rear surface electrode 7 covers the conductor portion 9. When seen in the direction perpendicular to the principal surface 2d of the n-type conductive layer 2 (y direction), the n-type rear surface electrode 7 is provided not only at a portion that overlaps the n-type front surface electrode 6 but also at a portion that overlaps the p-electrode 5 with the active layer 3 sandwiched therebetween.

The inner wall of the through hole 8 includes a plane which is different from the m-plane. Specifically, the inner wall of the through hole 8 includes the lateral surface of the c-plane and the a-plane. The contact resistance between the +c-plane or the a-plane and the conductor portion 9 is lower than a contact resistance which is achieved when the m-plane is in contact with the n-type front surface electrode 6. The “m-plane”, the “c-plane”, and the “a-plane” as used herein may not be completely parallel to the respective planes, and may be inclined from the respective planes in a predetermined direction within the range of ±5°. The inclination angle is defined by an angle formed between the normal to an actual principal surface of a nitride semiconductor layer and the normal to each plane (m-plane, c-plane, or a-plane which is not inclined). In other words, the “m-plane” in the present invention includes a plane which is inclined from the m-plane (m-plane which is not inclined) in a predetermined direction within the range of ±5°. The same applies to the c-plane and the a-plane.

In the light-emitting diode element 14, light emitted from the active layer 3 is extracted from the rear surface 2c of the n-type conductive layer 2, and hence the n-type rear surface electrode 7 is made of a transparent conductive material. In the case where the n-type rear surface electrode 7 is formed from a non-transparent conductive material, the n-type rear surface electrode 7 may be disposed only in a partial region of the rear surface of the n-type conductive layer 2 so as not to block light.

The contact resistance of the m-plane is higher than those of the c-plane and the a-plane, and hence a light-emitting diode having an m-plane principal surface has a tendency that its power efficiency is decreased or its efficiency is decreased due to heat generation. In the light-emitting diode element 14 illustrated in the reference example, the conductor portion 9 serving as an electric current path is provided inside the through hole 8, to thereby decrease the contact resistance. Note that, the light-emitting diode element 14 of the reference example is described in WO 2011/010436 A1.

FIG. 7 is a graph showing simulation results of a light emission rate of the light-emitting diode element 14 illustrated in FIG. 6. The graph of FIG. 7 shows the light emission rate of the active layer 3 along the A-A′ cross section in FIG. 6C. The simulation was performed assuming an element having an anode electrode width of 100 μm. The horizontal axis of the graph of FIG. 7 represents the position, provided that a terminal of the anode electrode on the A′ side of the A-A′ cross section is x=0 μm and a terminal of the anode electrode on the A side is x=100 μm. The vertical axis represents a value of the ratio, provided that the light emission rate for x=100 μm is 1.

As shown in FIG. 7, in any of the simulation results in which a contact resistance Rc is 1×10⁻³ Ω/cm², 1×10⁻⁴ Ω/cm², and 1×10⁻⁵ Ω/cm², stronger light is emitted on the p-electrode 5 (anode electrode) in a region close to the conductor portion (on the A′ side) than in a region far from the conductor portion 9 (on the A side). Specifically, the light emission rates for x=0 in the case where the contact resistance Rc is 1×10⁻⁵ Ω/cm², 1×10⁻⁴ Ω/cm², and 1×10⁻³ Ω/cm² are increased by about 5%, 10%, and 30%, respectively, as compared with the light emission rates for x=100. It is understood from the results that the unevenness in light emission becomes larger as the contact resistance Rc is larger.

The concentration of n-type impurities in an m-plane GaN layer (n-type conductive layer 2) is lower than the concentration of n-type impurities in a c-plane GaN layer. Therefore, in a light-emitting diode device including a semiconductor layer having an m-plane principal surface, the resistance in the n-type semiconductor layer is increased, and the unevenness in light emission becomes larger. The uniformity in light emission is required in the case of using a light-emitting diode element as a backlight unit of a display device or the like. As a result of study, the inventors of the present application have conceived of a light-emitting diode element having high power efficiency and high internal quantum efficiency, in which a contact resistance and a resistance in an n-type conductive layer are decreased to thereby suppress an increase in chip temperature. The inventors have also conceived a light-emitting diode element which has an improved uniformity of a light emission distribution and which has good connection to a mounting base so as to have excellent reliability.

In one general aspect, a light-emitting diode element, comprises: a first semiconductor layer of a first conductivity type having a first front surface region, a second front surface region, and a rear surface, the first semiconductor layer being made of a gallium nitride-based compound; a second semiconductor layer of a second conductivity type, which is provided at the first front surface region; an active layer, which is positioned between the first semiconductor layer and the second semiconductor layer; a first electrode, which is provided on a principal surface of the second semiconductor layer; a first insulating film, which is provided on an inner wall of a through hole, the through hole penetrating through the first semiconductor layer and having openings in the second front surface region and the rear surface; conductor portion, which is provided on a surface of the first insulating film inside the through hole; a second electrode, which is provided at the second front surface region and is in contact with the conductor portion; and a third electrode, which is provided on the rear surface of the first semiconductor layer and is in contact with the conductor portion, wherein, when seen in a direction perpendicular to a principal surface of the first semiconductor layer, the third electrode is provided in a region that overlaps the first electrode.

The first semiconductor layer may include a semiconductor substrate and a gallium nitride-based compound semiconductor layer formed on a principal surface of the semiconductor substrate. The rear surface of the first semiconductor layer may comprise a rear surface of the semiconductor substrate. The first front surface region and the second front surface region may comprise regions on a surface of the gallium nitride-based compound semiconductor layer.

The light-emitting diode element may further comprises a second insulating film, which is provided in a region of the second front surface region which is positioned around the through hole, wherein the second electrode is provided on the second insulating film.

When viewed in the direction perpendicular to the principal surface of the first semiconductor layer, the through hole may be provided along one side of the first semiconductor layer, and the active layer may be provided in a substantially square shape in plan so as to be adjacent to a region of the first semiconductor layer in which the through hole is provided.

When viewed in the direction perpendicular to the principal surface of the first semiconductor layer, the third electrode may comprise third electrodes disposed in the region overlapping the first electrode so that the third electrodes are spaced apart from each other.

The through hole may have a space inside surrounded by the conductor portion.

The light-emitting diode element may further comprises a third insulating film, which is provided in a region of the rear surface of the first semiconductor layer which is positioned around the through hole, wherein the third electrode is provided on a rear surface side of the third insulating film.

The first front surface region and the second front surface region may comprise regions on an m-plane.

The first front surface region and the second front surface region may comprise regions on a plane other than an m-plane.

In another aspect, a light-emitting diode element, comprises: a first semiconductor layer of a first conductivity type including a semiconductor substrate of the first conductivity type and a gallium nitride-based compound semiconductor layer, the semiconductor substrate having a principal surface and a rear surface, the gallium nitride-based compound semiconductor layer being formed on the principal surface of the semiconductor substrate; a second semiconductor layer of a second conductivity type, which is provided at a principal surface of the gallium nitride-based compound semiconductor layer; an active layer, which is positioned between the first semiconductor layer and the second semiconductor layer; a first electrode, which is provided in a first region of a principal surface of the second semiconductor layer; a first insulating film, which is provided on an inner wall of a through hole, the through hole penetrating through the first semiconductor layer, the second semiconductor layer, and the active layer and having openings in a second region of the principal surface of the second semiconductor layer and in the rear surface of the semiconductor substrate; a conductor portion, which is provided on a surface of the first insulating film inside the through hole; a second electrode, which is provided at the second region and is in contact with the conductor portion; and a third electrode, which is provided on the rear surface of the semiconductor substrate and is in contact with the conductor portion, wherein: when seen in a direction perpendicular to the principal surface of the first semiconductor layer, the third electrode is provided in a region that overlaps the first electrode; and the light-emitting diode element further comprises a second insulating film which is provided in a region of the second region which is positioned around the through hole, and the second electrode is provided on the second insulating film.

When viewed in the direction perpendicular to the principal surface of the first semiconductor layer, the third electrode may comprise third electrodes disposed in the region overlapping the first electrode so that the third electrodes are spaced apart from each other.

The through hole may have a space inside surrounded by the conductor portion.

The light-emitting diode element may further comprises a third insulating film, which is provided in a region of the rear surface of the first semiconductor layer which is positioned around the through hole, wherein the third electrode is provided on a rear surface side of the third insulating film.

The principal surface of the gallium nitride-based compound semiconductor layer may comprise an m-plane.

The principal surface of the gallium nitride-based compound semiconductor layer may comprise a region on a plane other than an m-plane.

In still another aspect, a light-emitting diode device comprises: the light-emitting diode element according to one of the above explained light-emitting diode and a mounting base, wherein the light-emitting diode element is disposed on the mounting base so that a side on which the first electrode and the second electrode are disposed faces the mounting base.

In still another aspect, a light-emitting diode device, comprises: the light-emitting diode element of claim 10; and a mounting base, wherein the light-emitting diode element is disposed on the mounting base so that a side on which the first electrode and the second electrode are disposed faces the mounting base.

According to the aspects, the third electrode (n-type rear surface electrode) is provided, and the third electrode is electrically connected to the second electrode (n-type front surface electrode) via the conductor portion provided in the through hole, and hence the contact area between the first semiconductor layer and the electrode can be increased as compared with the conventional one. This can decrease the contact resistance between the first semiconductor layer and the electrode as a whole. Therefore, the voltage to be applied to the active layer can be maintained to a sufficient level, to thereby increase power efficiency. Further, the third electrode and the first electrode are opposed to each other across the first semiconductor layer, and hence almost all electric currents flow uniformly between the third electrode and the first electrode. Therefore, as compared with the conventional front-surface electrode type light-emitting diode element, the concentration of electric current on the vicinity of a cathode electrode is alleviated, and hence the non-uniformity of electric current and the non-uniformity of light emission can be reduced.

Further, local heat generation is less likely to occur because an electric current can be allowed to flow uniformly from the first electrode to the third electrode. In addition, the thermal conductivities of the conductor portion and the third electrode are high, and hence the release of heat is more likely to proceed as a whole. This suppresses the increase in temperature of the active layer, thus suppressing the decrease in light emission efficiency and internal quantum efficiency.

In addition, the first insulating film is provided between the through hole and the conductor portion, and hence an electric current can be prevented from flowing from the first semiconductor layer to the conductor portion. With this, a uniform electric current flows through the third electrode, and the unevenness of light emission can be reduced.

Further, the second electrode is brought into contact with the conductor portion provided in the through hole, and hence the adhesion of the second electrode can be enhanced. With this, in the step of flip-chip mounting, defects of electrode peeling are less likely to occur.

Further, the second electrode is provided on the front surface, and hence it is unnecessary to bond wires on the rear surface of the semiconductor chip at the time of mounting, and hence there is no problem of peeling-off of wires and pad electrodes caused by the problem of adhesion, thus improving reliability.

Further, the conductor portion having high thermal conductivity is provided on the first semiconductor layer, and hence heat releasability can be improved. Thus, the increase in temperature of the active layer is suppressed, thus improving light emission efficiency and internal quantum efficiency.

Further, the first insulating film is provided between the first semiconductor layer and the conductor portion, and hence a stress that occurs due to the difference in coefficient of thermal expansion between the first semiconductor layer and the conductor portion can be alleviated. Thus, cracks or peeling-off in the vicinity of the through hole can be prevented.

Hereinafter, light-emitting diode devices according to embodiments of the present invention are described with reference to the drawings.

### Embodiment 1

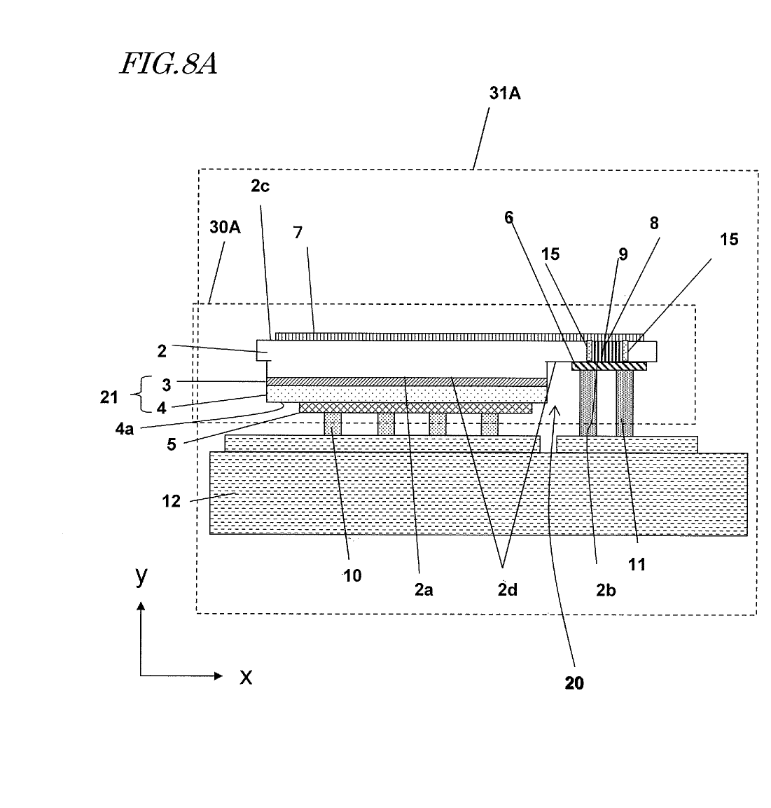

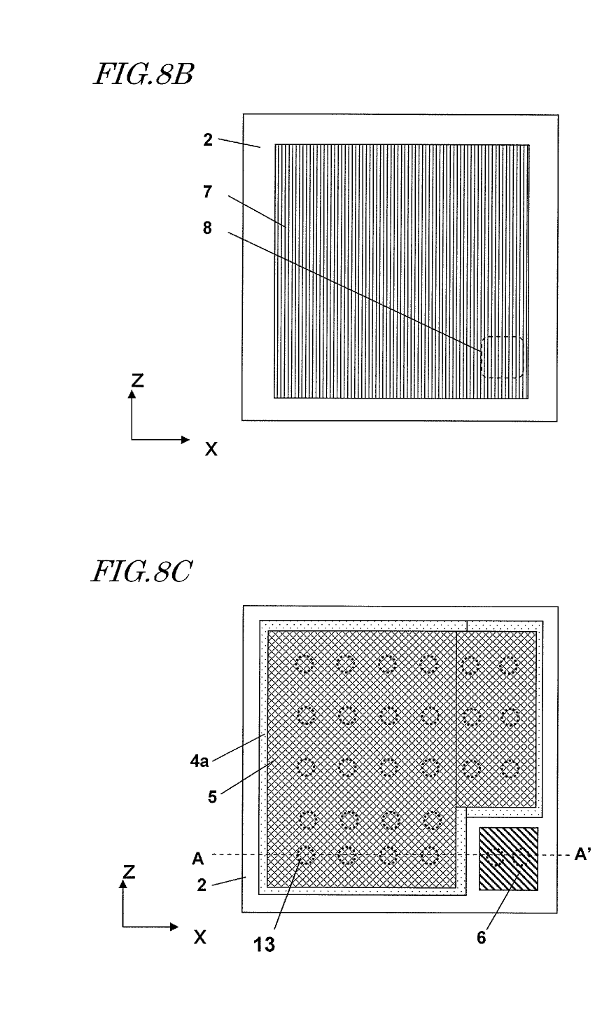

FIG. 8A is a cross-sectional view illustrating a light-emitting diode device 31A of Embodiment 1. FIG. 8B is a plan view illustrating a rear surface of a light-emitting diode element 30A illustrated in FIG. 8A. FIG. 8C is a plan view illustrating a principal surface of the light-emitting diode element 30A. Note that, FIG. 8A is a cross-sectional view taken along the line A-A′ of FIG. 8C. In FIGS. 8A to 8C, the same components as those in FIGS. 6A to 6C are denoted by the same reference symbols.

As illustrated in FIG. 8A, the light-emitting diode device 31A of this embodiment has a configuration in which the light-emitting diode element (chip) 30A is mounted on a mounting base 12 via bumps 10 and 11. The light-emitting diode element 30A is mounted on the mounting base 12 so that the principal surface of the light-emitting diode element 30A faces downward. The bump 10 connects a p-electrode 5 of the light-emitting diode element 30A and the mounting base 12 to each other. The bump 11 connects an n-type front surface electrode 6 of the light-emitting diode element 30A and the mounting base 12 to each other.

The light-emitting diode element 30A includes an n-type conductive layer (n-type semiconductor layer) 2 made of n-type GaN whose principal surface 2d is an m-plane, and a semiconductor multilayer structure 21 provided in a first region 2a of the principal surface 2d of the n-type conductive layer 2. For convenience of description, the principal surface 2d of the n-type conductive layer 2 is divided into the first region 2a (first front surface region) and a second region 2b (second front surface region). In the principal surface 2d of the n-type conductive layer 2, a portion constituting the bottom side of a recessed portion 20 is referred to as second region 2b. In the principal surface 2d of the n-type conductive layer 2, the outside of the recessed portion 20 is referred to as first region 2a. The semiconductor multilayer structure 21 includes an active layer provided on the principal surface 2d of the n-type conductive layer 2, and a p-type conductive layer (p-type semiconductor layer) 4 made of p-type GaN and provided on a principal surface of the active layer 3. The active layer 3 has a quantum well structure which is formed by stacked layers of, for example, InGaN and GaN. All parts of the n-type conductive layer 2 or a surface layer of the n-type conductive layer 2, and the active layer 3 and the p-type conductive layer 4 are each an epitaxially grown layer which is formed by means of m-plane growth. The n-type impurity concentration in the n-type conductive layer 2 is, for example, 1×10¹⁷ cm⁻³ or more and 1×10¹⁸ cm⁻³ or less.

As illustrated in FIG. 8C, the p-electrode 5 is provided on a principal surface 4a of the p-type conductive layer 4. On the other hand, the n-type front surface electrode 6 is provided in the second region 2b of the principal surface 2d of the n-type conductive layer 2. In this embodiment, the p-electrode 5 is composed of, for example, a Pd/Pt layer, and the n-type front surface electrode 6 is composed of, for example, a Ti/Al layer. However, the configurations of the p-electrode 5 and the n-type front surface electrode 6 are not limited thereto.

The n-type conductive layer 2 is provided with a through hole 8 that penetrates through the n-type conductive layer 2. An insulating film 15 made of, for example, a SiO₂ film is formed on the inner wall of the through hole 8 so as to cover GaN. In addition, a conductor portion (n-type through electrode) 9 made of, for example, Al is embedded in the through hole 8 on the inner side of the insulating film 15. The conductor portion 9 is in contact with the n-type front surface electrode 6 in the second region 2b of the principal surface 2d of the n-type conductive layer 2. On the other hand, an n-type rear surface electrode 7 is formed on a rear surface 2c of the n-type conductive layer 2 so as to be in contact with the conductor portion 9. As illustrated in FIG. 8B, the n-type rear surface electrode 7 covers the conductor portion 9 on the rear surface 2c of the n-type conductive layer 2. The n-type rear surface electrode 7 is formed from a transparent material, such as indium tin oxide (ITO). The n-type rear surface electrode 7 is disposed at a position opposed to the p-electrode 5.

The n-type conductive layer 2 made of m-plane GaN is formed on, for example, an m-plane n-type GaN substrate (not shown) by using epitaxial growth. After the manufacturing step on the principal surface side of the light-emitting diode element 30A is completed, polishing or etching is performed from the rear surface side, to thereby peel off the n-type GaN substrate. The light-emitting diode element 30A illustrated in FIGS. 8A to 8C is formed by removing the n-type GaN substrate entirely, but the n-type GaN substrate may be thinned by polishing or etching so that a part of the n-type GaN substrate may be left. Alternatively, the n-type conductive layer 2 made of m-plane GaN may be formed by epitaxial growth on a substrate made of a material different from that of the n-type conductive layer 2, such as a sapphire substrate, and then the substrate may be peeled off. The thickness of the n-type conductive layer 2 is in the range of, for example, from 3 μm to 50 μm. Light generated in the active layer 3 is extracted through the rear surface 2c of the n-type conductive layer 2. In this case, in order to improve light extraction efficiency, the n-type conductive layer 2 may be thinned as much as possible so as to reduce an absorption loss caused by the n-type conductive layer 2. Considering the mechanical strength of the light-emitting diode element 30A, some structural measures may be taken, such as bonding a Si support substrate on which p-electrode wirings to be connected to the p-electrode and n-electrode wirings to be connected to the n-electrode are patterned onto a chip to prevent cracks in the chip. As an example of the steps in this case, after the completion of the process on the element front surface side, the patterned Si support substrate is bonded on the element front surface side, and after that, the step of thinning, such as peeling off the substrate, is performed. Then, the process on the element rear surface is performed, and the chip which is manufactured by being separated from the substrate is mounted on the mounting base.

An overflow stopper layer, which has the effect of preventing overflow of carriers so as to improve light emission efficiency, may be interposed between the active layer 3 and the p-type conductive layer 4 in the light-emitting diode element 30A. The overflow stopper layer may be composed of, for example, an AlGaN layer. In this embodiment, these measures may be incorporated into the structure, although these measures are not illustrated in the drawings and the detailed descriptions thereof are herein omitted.

Hereinafter, an example of a method of fabricating the light-emitting diode element 30A of this embodiment is described with reference to FIG. 8.

Firstly, an n-type GaN substrate (not shown) is provided whose principal surface is the m-plane. This n-type GaN substrate may be manufactured by using a hydride vapor phase epitaxy (HVPE) method. For example, in the beginning, a thick GaN film, which has a thickness on the order of several micrometers, is grown on a c-plane sapphire substrate. Thereafter, the thick GaN film is cleaved at the m-plane that is vertical to the c-plane, and hence an m-plane GaN substrate is obtained. The method of manufacturing the GaN substrate is not limited to the above-mentioned example but may be a method in which an ingot of bulk GaN is manufactured by using, for example, a liquid phase growth method, such as a sodium flux method, or a melt growth method, such as an amonothermal method, and the ingot is cleaved at the m-plane. In this case, the concentration in the m-plane n-type GaN layer is 1×10¹⁷ cm⁻³ to 1×10¹⁸ cm⁻³, and the concentration in the c-plane n-type GaN layer is 1×10¹⁸ cm⁻³ to 1×10¹⁹ cm⁻³, and hence the concentration in the m-plane is lower as compared to that in the c-plane.

In this embodiment, crystalline layers are sequentially formed on a substrate by metal organic chemical vapor deposition (MOCVD). Firstly, on the n-type GaN substrate, a GaN layer having a thickness of 3 μm to 50 μm is formed as the n-type conductive layer 2. Specifically, a GaN layer is deposited on the n-type GaN substrate by supplying TMG (Ga(CH₃)₃), TMA (Al(CH₃)₃), and NH₃ at 1,100° C., for example. In this step, an AlᵤGaᵥIn_{w}N layer (u≧0, v≧0, w≧0) may be formed as the n-type conductive layer 2, instead of the GaN layer. Note that, a substrate of a different type, which is different from the n-type GaN substrate, may be used.

Then, the active layer 3 is formed on the n-type conductive layer 2. The active layer 3 has a 81 nm thick GaInN/GaN multi-quantum well (MQW) structure which is realized by, for example, alternately stacking 9 nm thick Ga_{0.9}In_{0.1}N well layers and 9 nm thick GaN barrier layers. In forming the Ga_{0.9}In_{0.1}N well layers, the growth temperature may decreased to 800° C. in order to enhance incorporation of In.

Next, on the active layer 3, the 70 nm thick p-type conductive layer 4 of GaN is formed by supplying TMG, TMA, NH₃, and Cp₂Mg (cyclopentadienyl magnesium) as the p-type impurities. The p-type conductive layer 4 may have a p-GaN contact layer (not shown) at the surface. As the p-type conductive layer 4, for example, a p-AlGaN layer may be formed instead of the GaN layer.

After the end of the above-mentioned epitaxial growth step by means of MOCVD, chlorine dry etching is performed to partially remove the p-type conductive layer 4 and the active layer 3 so that the recessed portion 20 is formed, and hence the second region 2b of the n-type conductive layer 2 is exposed.

Then, the through hole 8 is formed by using a dry etching process, for example. Specifically, a resist mask is formed over the p-type conductive layer 4 and the principal surface 2d of the n-type conductive layer 2, and thereafter, an opening is formed in part of the resist mask which is assigned for formation of the through hole 8. By performing dry etching using the resultant resist mask, a hole can be formed through the n-type conductive layer 2 and the n-type GaN substrate, which is to become the through hole 8. In this case, the dry etching is stopped before the hole penetrates through the n-type GaN substrate. As illustrated in FIG. 8B, the through hole 8 is formed so as to have a square shape when seen in the direction perpendicular to the principal surface 2d of the n-type conductive layer 2. The dimensions of the through hole 8 (the dimensions in a plane which is parallel to the principal surface) may be 100 μm×100 μm, for example. The corners of the through hole 8 may be round.

Next, by CVD, the insulating film 15 composed of, for example, a SiO₂ film is formed along the inner wall and the bottom surface of the above-mentioned hole which is to become the through hole 8. Subsequently, by vapor deposition or sputtering, an Al layer having a thickness of 100 nm is formed on the insulating film 15, and another Al layer is formed thereon by plating. In this way, the conductor portion 9 composed of an Al layer is formed. In order to prevent the disconnection of the conductor portion 9, it is desired that the dimensions of the through hole 8 in a plane which is parallel to the principal surface be set to be equal to or larger than the dimensions of the through hole 8 in a plane perpendicular thereto.

The insulating film 15 may not cover the entire inner wall of the through hole 8. However, in order to insulate the n-type conductive layer 2 constituting the inner wall of the through hole 8 from the conductor portion 9, the insulating film 15 may be a continuous film which is uniform to some extent. The thickness of the insulating film 15 may be 100 nm or more and 1 μm or less. When the thickness of the insulating film 15 is 100 nm or more, the n-type conductive layer 2 and the conductor portion 9 can be reliably insulated from each other. Further, when the thickness of the insulating film 15 is 1 μm or less, a stress to be generated can be suppressed in an allowable range. The material of the insulating film 15 may be other than a silicon oxide film, and, for example, silicone, a silicon nitride film, or aluminum nitride (AlN) can be used. In the case of using silicone as the insulating film 15, silicone can be formed by application with the use of a spinner. A silicon nitride film can be formed by CVD or the like. Aluminum nitride can be formed by sputtering or the like. Aluminum nitride has an advantage of high affinity for a GaN layer constituting the n-type conductive layer 2 and aluminum constituting the conductor portion 9 and an advantage of high thermal conductivity.

Then, on the second region 2b of the n-type conductive layer 2, the n-type front surface electrode 6 is formed by, for example, a 10 nm thick Ti layer and a 100 nm thick Al layer. The n-type front surface electrode 6 is formed so as to be in contact with the conductor portion 9. On the other hand, on the principal surface 4a of the p-type conductive layer 4, the p-electrode 5 is formed by, for example, a 7 nm thick Pd layer and a 70 nm thick Pt layer.

Next, by polishing or etching, the n-type GaN substrate is removed so as to expose the insulating film 15 formed on the bottom surface of the above-mentioned hole which is to become the through hole 8. Subsequently, the insulating film 15 formed on the bottom surface of the above-mentioned hole is removed to expose the conductor portion 9. After that, by vapor deposition or the like, the n-type rear surface electrode 7 made of a transparent material, such as indium tin oxide (ITO), is formed on the rear surface 2c of the n-type conductive layer 2.

After that, heat treatment may be performed at a temperature of about 50° C. to 650° C. for about 5 minutes to 20 minutes. The heat treatment can decrease the contact resistance between the n-type conductive layer 2 and the n-type front surface electrode 6 and between the n-type conductive layer 2 and the n-type rear surface electrode 7.

The above description is merely a description of exemplary embodiments, and the present invention is not limited to the above description.

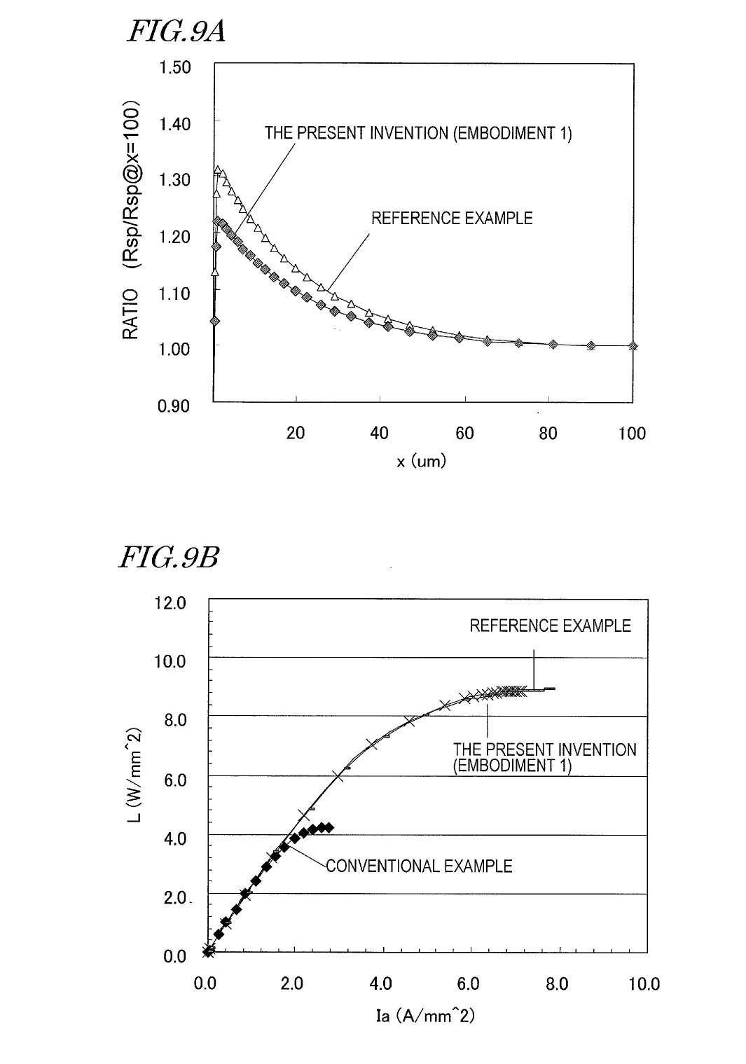

FIG. 9A is a graph showing simulation results of a light emission rate of the light-emitting diode element 31A illustrated in FIG. 8. The graph of FIG. 9A shows the light emission rate of the active layer 3 along the A-A′ cross section in FIG. 8C. Note that, FIG. 9A shows, as a reference example, a simulation result of the light-emitting diode element 14A illustrated in FIG. 6. Similarly to the simulation showing the results of FIG. 7, the simulation was performed assuming an element having an anode electrode width of 100 μm. The horizontal axis of the graph of FIG. 9A represents the position, provided that a terminal of the anode electrode on the A′ side of the A-A′ cross section is x=0 μm and a terminal of the anode electrode on the A side is x=100 μm. The vertical axis represents a value of the ratio, provided that the light emission rate for x=100 μm is 1.

As shown in FIG. 9A, it is understood that the light emission rate in the reference example is high in the vicinity of the through electrode, and a uniform light emission cannot be obtained, but in this embodiment, the uniformity in light emission is improved. From comparison with the reference example, it is confirmed that the light emission rate at the portion having the strongest light emission is improved by about 8% in this embodiment.

FIG. 9B is a graph showing an electric current dependence of a light output of the light-emitting diode device 31A illustrated in FIG. 8. FIG. 9B shows the results obtained by simulation assuming the light-emitting diode device 31A. The simulation was performed assuming an element having an anode electrode width of 100 μm. For comparison, FIG. 9B shows the simulation results of the conventional light-emitting diode element 114 illustrated in FIG. 5 and the reference example illustrated in FIG. 6. The results shown in FIG. 9B were obtained by applying the same bias to the light-emitting diode elements illustrated in FIG. 5.

As shown in FIG. 9B, it is understood that, in the conventional structure, the output starts decreasing from the point at which an anode electric current value Ia becomes 1 A or more, but, in the structure of the embodiment of the present invention, the light output compatible to that in the reference example can be obtained with substantially the same amount of electric current. In this way, according to this embodiment, a sufficient light output is obtained.

According to this embodiment, the n-type rear surface electrode 7 is provided, and the n-type rear surface electrode 7 is electrically connected to the n-type front surface electrode 6 via the conductor portion 9 provided in the through hole 8, and hence the contact area between the n-type semiconductor layer and the electrode can be increased as compared with the conventional one. This can decrease the contact resistance between the n-type semiconductor layer and the electrode as a whole. Further, the n-type rear surface electrode 7 and the p-electrode 5 are opposed to each other across the active layer 3 at substantially the same interval, and hence the voltage of the active layer 3 in a region apart from the n-type front surface electrode 6 is not decreased by the resistance of the n-type semiconductor layer. Therefore, the voltage to be applied to the active layer 3 can be maintained to a sufficient level, to thereby increase power efficiency. In addition, heat caused by the contact resistance is less likely to be generated, and the contact area between the n-type semiconductor layer and the electrode is increased, to thereby accelerate the release of heat in the chip. This suppresses the increase in temperature of the active layer 3, thus improving light emission efficiency and internal quantum efficiency.

When the through hole 8 is provided in the n-type conductive layer 2 having an m-plane principal surface, a plane which is different from the m-plane, specifically, a +c-plane or an a-plane, appears on the inner wall of the through hole 8. The contact resistance on the +c-plane or the a-plane is lower than the contact resistance on the m-plane. Therefore, in the reference example (illustrated in FIG. 6) in which the insulating film 15 is not provided on the inner wall of the through hole 8, an electric current easily flows between the n-type conductive layer 2 constituting the inner wall of the through hole 8 and the conductor portion 9. In this case, in the reference example, it is difficult to form a uniform contact resistance between the semiconductor constituting the inner wall of the through hole 8 and the conductor portion 9, and the fluctuations in contact resistance lead to the fluctuations in electric current density, with the result that the non-uniformity in light emission and the fluctuations among elements easily occur. As described above, the n-type impurity concentration of the m-plane GaN is lower than that of the c-plane GaN and the contact resistance is more likely to be larger, and hence the unevenness in light emission is more likely to be larger. Further, an electric current is more likely to concentrate on the vicinity of the through electrode having a small contact resistance, and hence the light emission intensity at the anode electrode portion in the vicinity of the through electrode becomes stronger. Thus, uniform light emission cannot be obtained easily.

In this embodiment, the insulating film 15 is provided between the through hole 8 and the conductor portion 9, and hence an electric current can be prevented from flowing from the n-type conductive layer 2 to the conductor portion 9. Therefore, almost all electric currents flow from the p-electrode 5 to the n-type rear surface electrode 7, resulting in more uniform electric current density in the active layer 3. In this way, according to this embodiment, it is possible to reduce the non-uniformity in light emission caused by strong light emission at a portion of the active layer 3 which is positioned in the vicinity of the through hole 8.

The adhesion between the m-plane GaN and the electrode is lower than the adhesion between the c-plane GaN and the electrode, and peeling-off is more likely to occur. Therefore, there has been a problem that the electrode may peel off when a light-emitting element using an m-plane GaN is mounted with the use of bumps or wires. In this embodiment, the n-type front surface electrode 6 is brought into contact with not only the n-type conductive layer 2 but also the conductor portion 9. The conductor portion 9 has higher adhesion with respect to the n-type front surface electrode 6 than that of the n-type conductive layer 2, and hence, when the n-type front surface electrode 6 is brought into contact with the conductor portion 9, the n-type front surface electrode 6 can be prevented from easily peeling off. Thus, defects of electrode peeling are less likely to occur, for example, in flip-chip mounting in which the bump 11 is brought into contact with the n-type front surface electrode 6.

The conductor portion 9 having good thermal conductivity penetrates through the n-type conductive layer 2, and hence the heat releasability is improved. Thus, the increase in temperature of the active layer 3 is suppressed, thus improving light emission efficiency and internal quantum efficiency. The carrier density of the m-plane GaN is lower than that of the c-plane GaN, and hence the m-plane GaN has a higher thermal conductivity. Therefore, in the m-plane GaN, the decrease in internal quantum efficiency caused by heat generation is small, and hence the m-plane GaN is superior in terms of high-power operation. For example, when the carrier density is 1.5×10¹⁷ cm⁻³, 1.0×10¹⁸ cm⁻³, and 3.0×10¹⁸ cm⁻³, the thermal conductivity is 1.68 W/cmK, 1.38 W/cmK, and 1.10 W/cmK, respectively, and the carrier density of the m-plane GaN is 1.0×10¹⁷ cm⁻³ to 1×10¹⁸ cm⁻³ while the carrier density of the c-plane GaN is equal to or higher than that of the en-plane GaN.

The coefficients of linear expansion of GaN and Al are 3 to 6×10⁻⁶/K and 23×10⁻⁶/K, respectively. A GaN light-emitting diode is apt to generate heat, and the chip temperature may increase to around 100 K. When heat is generated under high-power operation, the conductor portion 9 expands so that a strong stress is applied to a portion of the n-type conductive layer 2 which is positioned in the vicinity of the through hole 8, and hence cracks or peeling-off easily occur. In this embodiment, the insulating film 15 is provided between the n-type conductive layer 2, in which the through hole 8 is to be provided, and the conductor portion 9, and hence cracks or peeling-off can be prevented. For example, in the case where an insulating film composed of a SiO₂ film is provided, the SiO₂ film is less likely to expand because the coefficient of linear expansion is as small as 0.5×10⁻⁶/K. Further, the SiO₂ film has a coefficient of elasticity g of 8 GPa, which is smaller than 300 GPa of GaN and 70 GaP of Al. Therefore, the SiO₂ film can function as a buffer layer.

### Embodiment 2

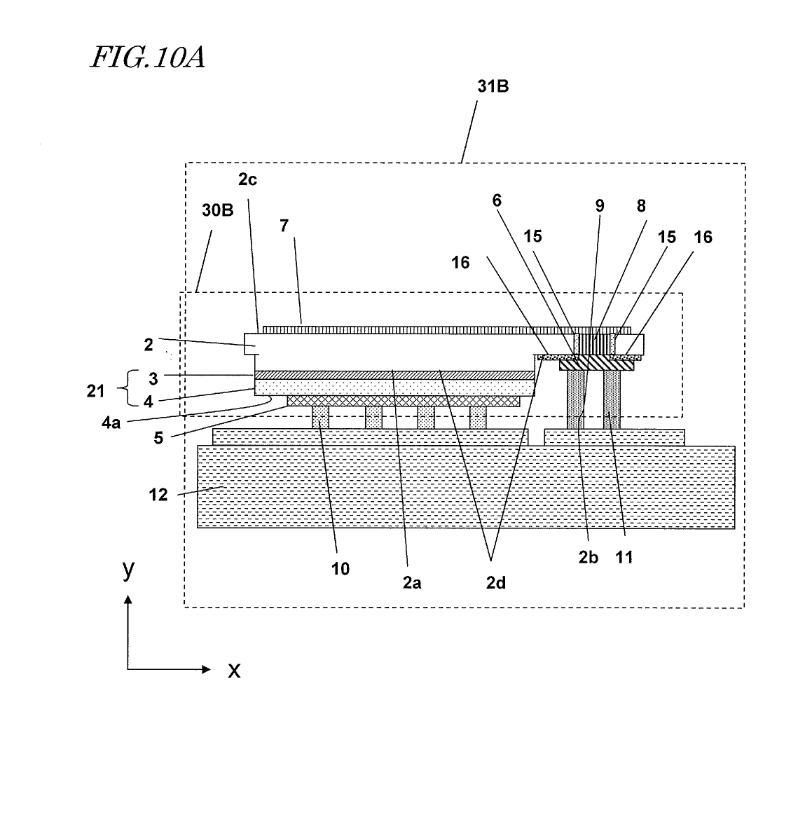

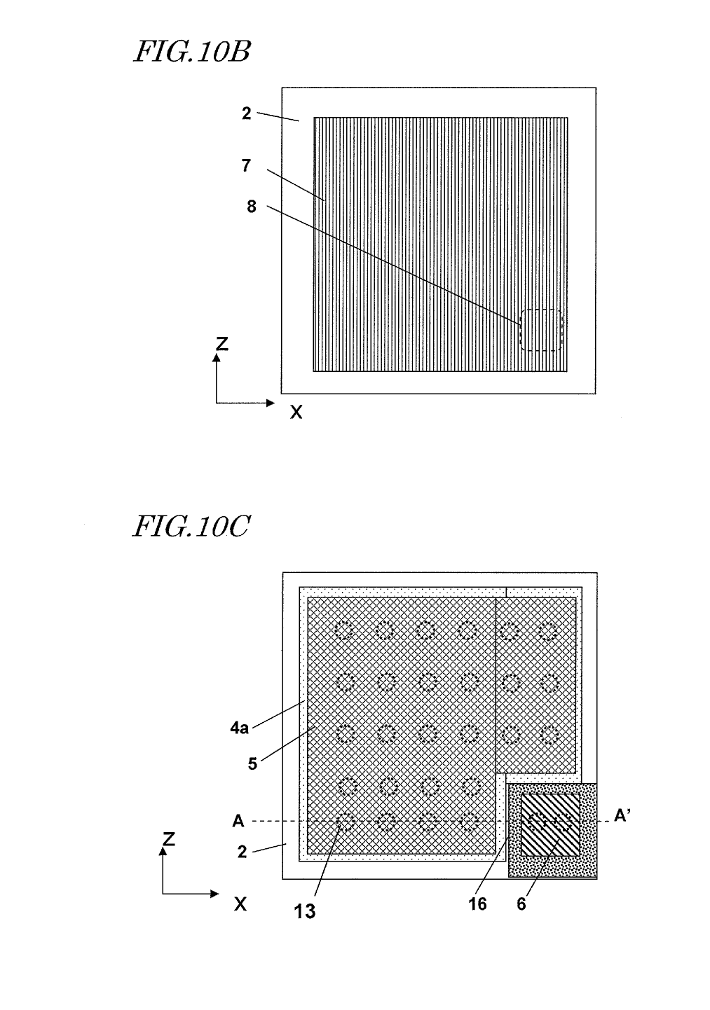

FIG. 10A is a cross-sectional view illustrating a light-emitting diode device 31B of Embodiment 2. FIG. 10B is a plan view illustrating a rear surface of a light-emitting diode element 30B illustrated in FIG. 10A. FIG. 10C is a plan view illustrating a principal surface of the light-emitting diode element 30B. Note that, FIG. 10A is a cross-sectional view taken along the line A-A′ of FIG. 10C. In FIGS. 10A to 10C, the same components as those in FIGS. 8A to 8C are denoted by the same reference symbols.

As illustrated in FIG. 10A, in the light-emitting diode device 31B of this embodiment, an insulating film 16 is provided on the second region 2b of the principal surface 2d of the n-type conductive layer 2 (at the portion of the n-type conductive layer 2 which is positioned around the through hole 8). The n-type front surface electrode 6 is disposed, through the intermediation of the insulating film 16, on the second region 2b of the principal surface 2d of the n-type conductive layer 2. The insulating film 16 may be formed in the same step for forming the insulating film 15 that covers the inner surface of the through hole 8, and may be formed in a different step. In the case where the insulating film 16 is formed in the same step, after the through hole 8 is formed, CVD or the like for forming a silicon oxide film is performed. Then, the insulating films 15 and 16 each composed of a silicon oxide film are formed in the second region 2b of the n-type conductive layer 2 and on the inner wall of the through hole 8. The insulating film may be left in a region of the principal surface 4a of the p-type conductive layer 4 other than the region in which the p-electrode 5 is to be formed.

This embodiment has the same configurations as those in Embodiment 1 except for the arrangement of the insulating film 16 and the n-type front surface electrode 6. The description of the same configurations is herein omitted. The description of the same effects as those in Embodiment 1 among the effects obtained in this embodiment is also omitted.

In Embodiment 1, an electric current flows from the p-electrode 5 toward the n-type front surface electrode 6. The distance from the p-electrode 5 to the n-type front surface electrode 6 is short, and hence an electric current component between the two electrodes increases so that a light emission output becomes larger as a whole, but the light emission intensity in a region of the active layer 3 close to the n-type front surface electrode 6 becomes stronger, resulting in a non-uniform light emission distribution. In this embodiment, the insulating film 16 is provided between the n-type conductive layer 2 and the n-type front surface electrode 6, and hence no electric current flows from the n-type conductive layer 2 to the n-type front surface electrode 6. Thus, all electric currents flow from the p-electrode 5 to the n-type rear surface electrode 7, resulting in more uniform electric current density. Therefore, a more uniform light emission distribution can be obtained. The effect of making the light emission distribution uniform by providing the insulating film 16 is large particularly in the case where the n-type front surface electrode 6 is formed close to the p-electrode 5. This embodiment is particularly suitable to the use which places a higher priority on the uniformity in light emission distribution than the light emission intensity.

Further, the n-type front surface electrode 6 is provided on the insulating film 16 and the conductor portion 9. The insulating film 16 has higher adhesion with respect to the n-type front surface electrode 6 than that of the n-type conductive layer 2, and hence the n-type front surface electrode 6 is less easily peeled off in this embodiment. In general, the formation of bumps in flip-chip mounting has a problem that an electrode is peeled off and other such problems, but this embodiment can overcome the problems.

Note that, in this embodiment, the structure having the insulating film 15 between the conductor portion 9 and the n-type conductive layer 2 has been exemplified, but the insulating film 16 may be provided in the structure without the insulating film 15.

### Embodiment 3

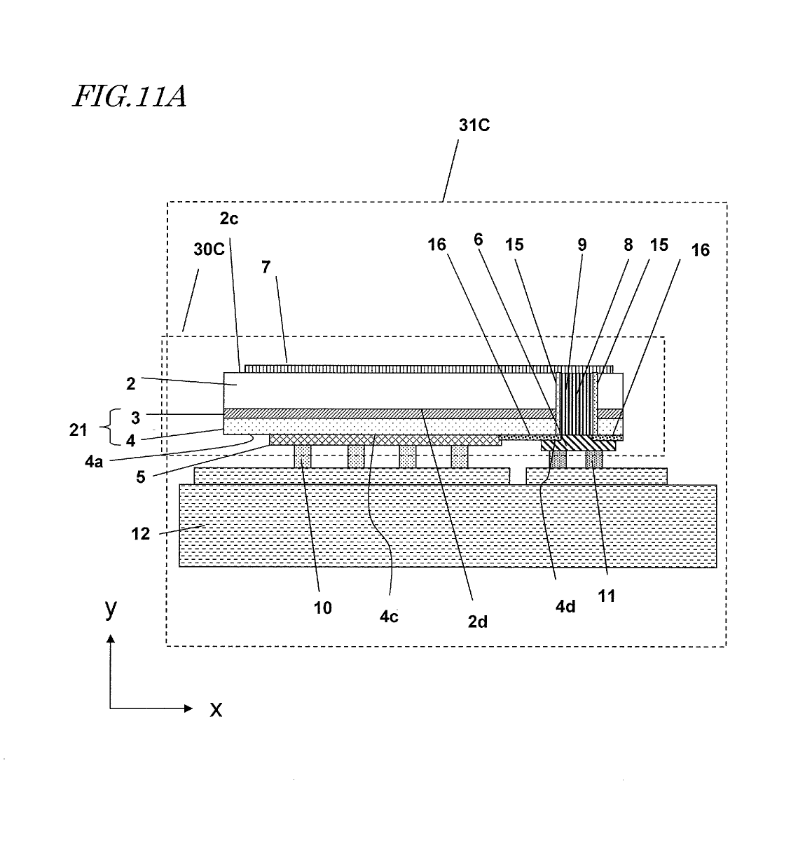

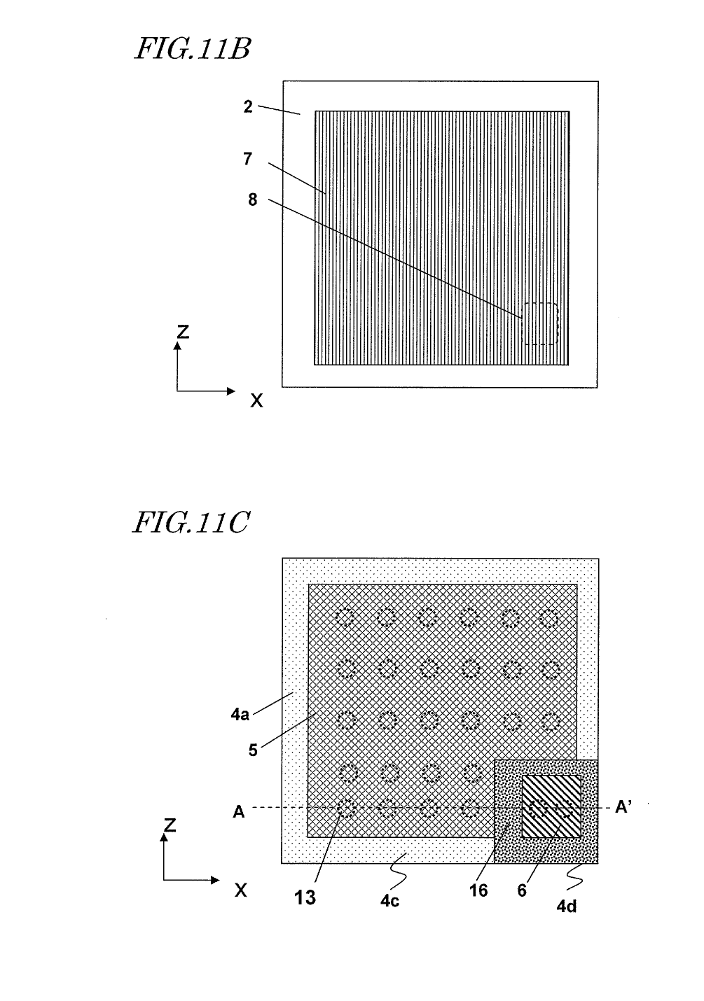

FIG. 11A is a cross-sectional view illustrating a light-emitting diode device 31C of Embodiment 3. FIG. 11B is a plan view illustrating a rear surface of a light-emitting diode element 30C illustrated in FIG. 11A. FIG. 11C is a plan view illustrating a principal surface of the light-emitting diode element 30C. Note that, FIG. 11A is a cross-sectional view taken along the line A-A′ of FIG. 11C. In FIGS. 11A to 11C, the same components as those in FIGS. 10A to 10C are denoted by the same reference symbols.

As illustrated in FIG. 11A, the recessed portion 20 (illustrated in FIG. 10A etc.) is not provided in this embodiment. The through hole 8 penetrates through not only the n-type conductive layer 2 but also the active layer 3 and the p-type conductive layer 4.

The insulating film 15 is provided on the inner walls of the n-type conductive layer 2, the active layer 3, and the p-type conductive layer 4, which constitute the inner wall of the through hole 8. Further, the conductor portion 9 is embedded in the through hole 8 on the inner side of the insulating film 15.

The insulating film 16 is provided on the principal surface of the p-type conductive layer 4 in a region (second region 4d) surrounding the through hole 8. On the other hand, the p-electrode 5 is provided in the first region 4c of the principal surface of the p-type conductive layer 4. As illustrated in FIG. 11C, the second region 4d is a region disposed at one corner of the square principal surface of the p-type conductive layer 4, and the first region 4c is a region of the principal surface of the p-type conductive layer 4 other than the second region 4d. The insulating film 16 may be made of the same material as that of the insulating film 15, and may be made of a different material. The thickness of the insulating film 16 may be 100 nm or more and 500 nm or less.

The n-type front surface electrode 6 is provided from a region on the conductor portion 9 exposed on the surface of the p-type conductive layer 4 on the principal surface side to a region on the insulating film 16 surrounding the circumference of the conductor portion 9. With the insulating films 15 and 16 provided, the n-type front surface electrode 6 and the conductor portion 9 are electrically insulated from the active layer 3 and the p-type conductive layer 4.

In this embodiment, the description of the same configurations as those in Embodiment 2 is omitted. The description of the same effects as those in Embodiment 2 among the effects obtained in this embodiment is also omitted.

According to this embodiment, the n-type front surface electrode 6 and the conductor portion 9 can be electrically insulated from the active layer 3 and the p-type conductive layer 4 by the insulating films 15 and 16, and hence it is unnecessary to form the recessed portion 20 (illustrated in FIG. 8A etc.). The process can therefore be simplified.

Further, the surface on the mounting side (principal surface of the light-emitting diode element 30C) becomes flat so as to eliminate a step, and hence, in the case of flip-chip mounting, bumps having the same height can be used for both of the n-type front surface electrode 6 and the p-electrode 5, thus simplifying the mounting.

Defects in shape and electric field concentration at a step portion can also be prevented, which eliminates defects caused by leakage electric current or breakage generated at the step portion, thus improving reliability and yields.

### Embodiment 4

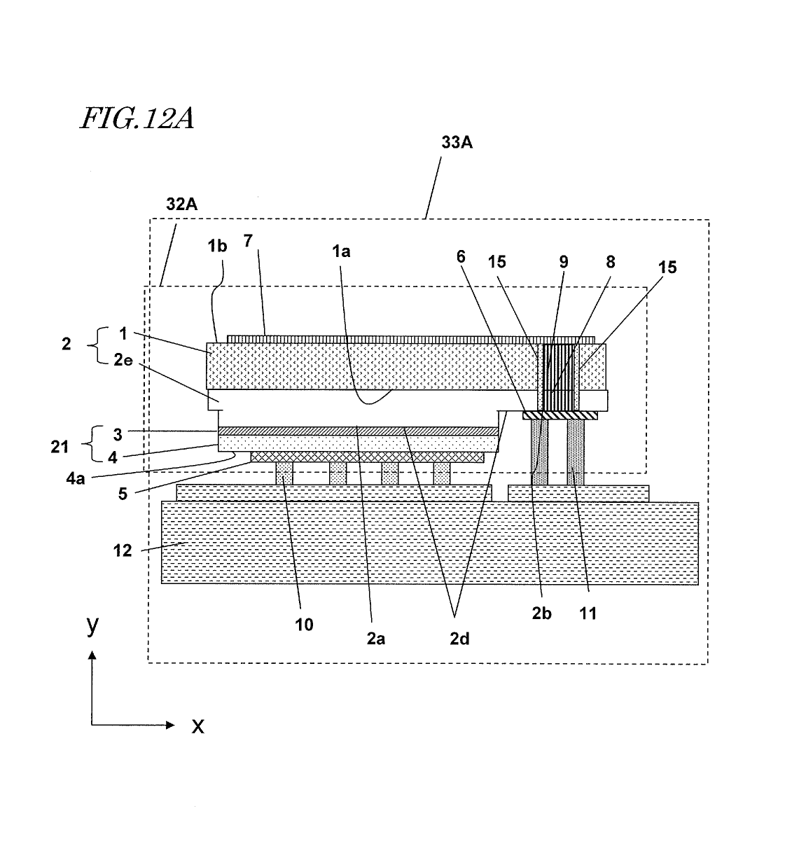

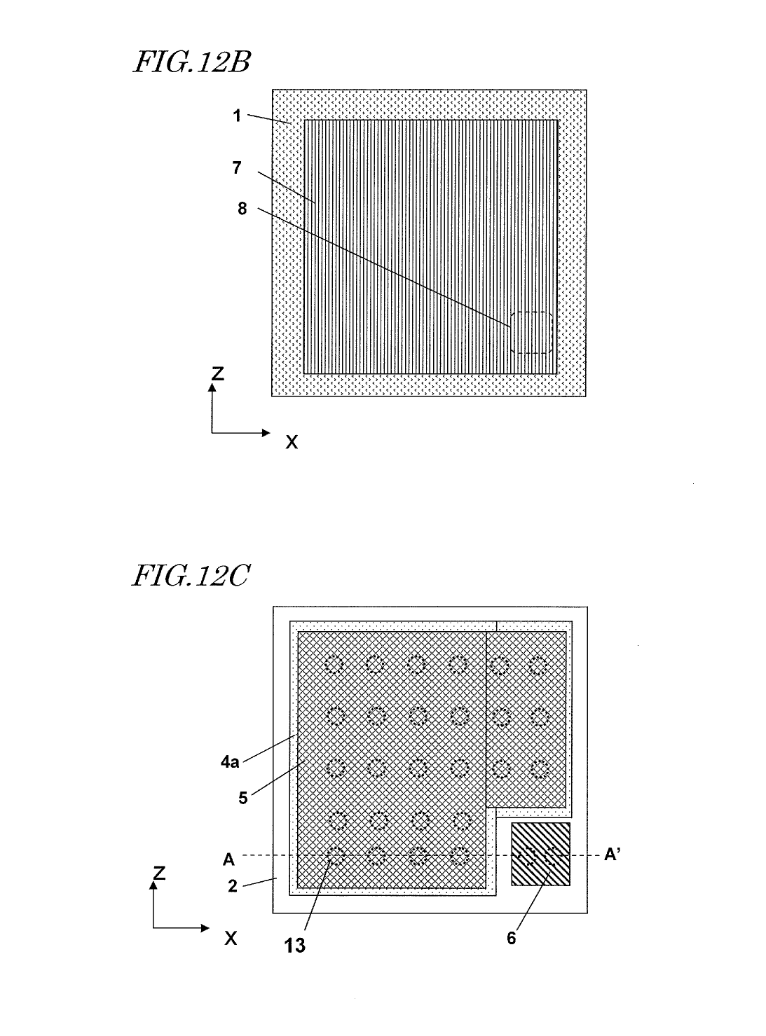

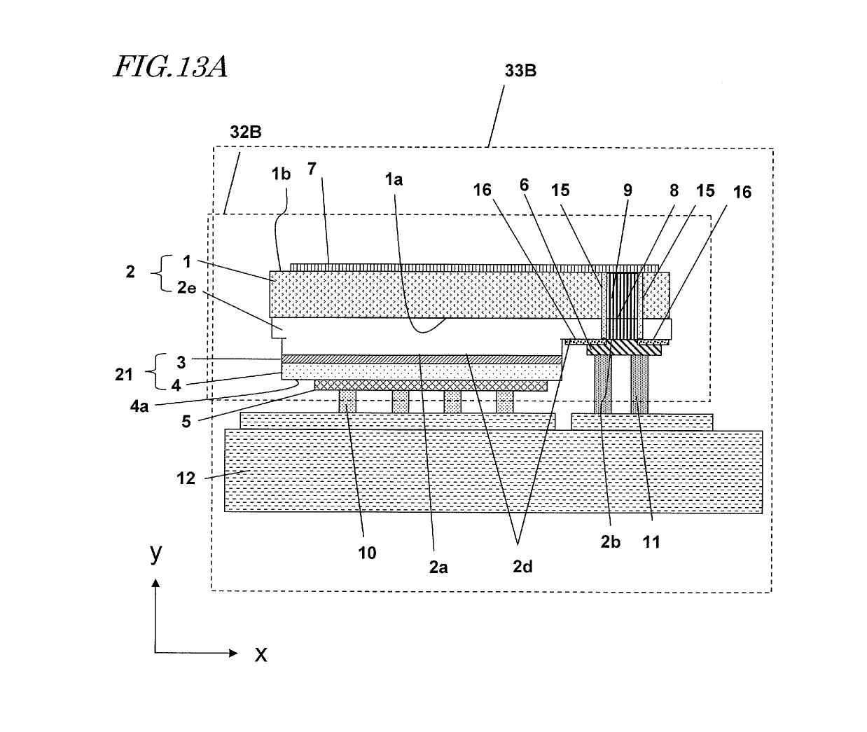

Next, a light-emitting diode device according to Embodiment 4 of the present invention is described with reference to FIGS. 12A to 14C. In Embodiments 1 to 3, after the n-type semiconductor layer 2e is formed on a substrate (not shown), the substrate is entirely removed. In this embodiment, the substrate is not entirely removed but (a part or whole of) the substrate is left so as to form the n-type conductive layer 2.

FIG. 12A is a cross-sectional view illustrating a first light-emitting diode device 33A of Embodiment 4. The first light-emitting diode device 33A is a modified example of the light-emitting diode device 31A of Embodiment 1. FIG. 12B is a plan view illustrating a rear surface of a light-emitting diode element 32A illustrated in FIG. 12A. FIG. 12C is a plan view illustrating a principal surface of the light-emitting diode element 32A. The first light-emitting diode device 33A illustrated in FIGS. 12A to 12C includes an n-type substrate 1 formed from GaN. An n-type semiconductor layer 2e is provided on a principal surface 1a of the n-type substrate 1, and an n-type rear surface electrode 7 is provided on a rear surface 1b of the n-type substrate 1. A through hole 8 penetrates through not only the n-type semiconductor layer 2e but also the n-type substrate 1. The n-type semiconductor layer 2e and the n-type substrate 1 constituting the inner wall of the through hole 8 are covered by the insulating film 15. Other configurations of the first light-emitting diode device 33A are the same as those of the light-emitting diode device 31A illustrated in FIGS. 8A to 8C. In FIGS. 12A to 12C, the same components as those in FIGS. 8A to 8C are denoted by the same reference symbols.

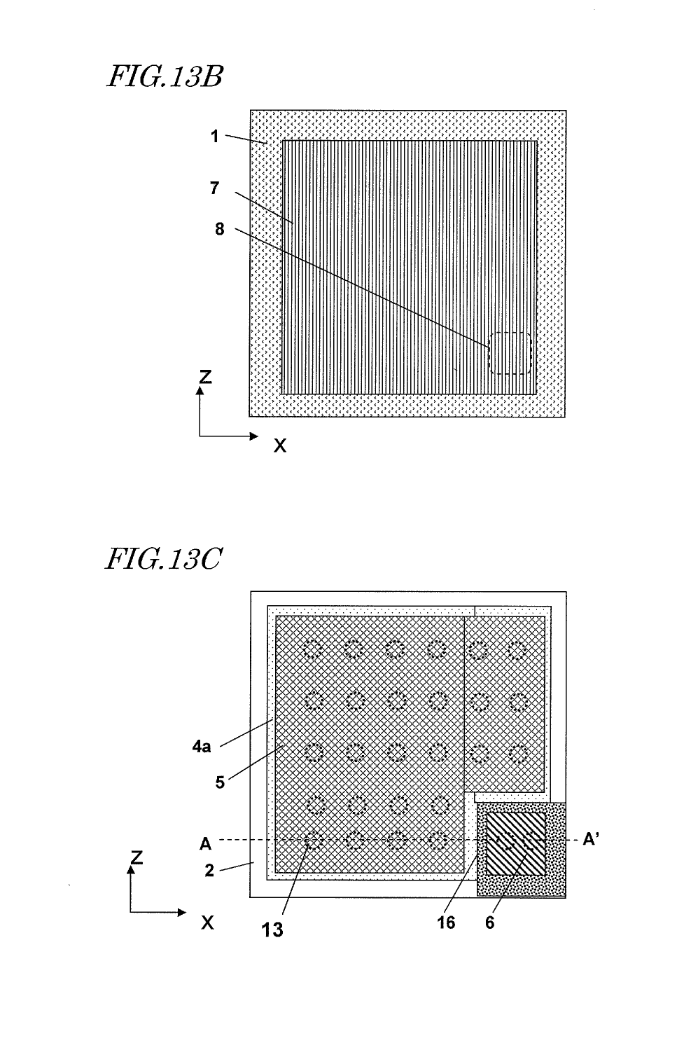

FIG. 13A is a cross-sectional view illustrating a second light-emitting diode device 33B of Embodiment 4. The second light-emitting diode device 33B is a modified example of the light-emitting diode device 31B of Embodiment 2. FIG. 13B is a plan view illustrating a rear surface of a light-emitting diode element 32B illustrated in FIG. 13A. FIG. 13C is a plan view illustrating a principal surface of the light-emitting diode element 32B. The second light-emitting diode device 33B illustrated in FIGS. 13A to 13C includes an n-type substrate 1. An n-type semiconductor layer 2e is provided on a principal surface 1a of the n-type substrate 1, and an n-type rear surface electrode 7 is provided on a rear surface 1b of the n-type substrate 1. A through hole 8 penetrates through not only the n-type semiconductor layer 2e but also the n-type substrate 1. The n-type semiconductor layer 2e and the n-type substrate 1 constituting the inner wall of the through hole 8 are covered by the insulating film 15. Other configurations of the second light-emitting diode device 33B are the same as those of the light-emitting diode device 31B illustrated in FIGS. 10A to 10C. In FIGS. 13A to 13C, the same components as those in FIGS. 10A to 10C are denoted by the same reference symbols.

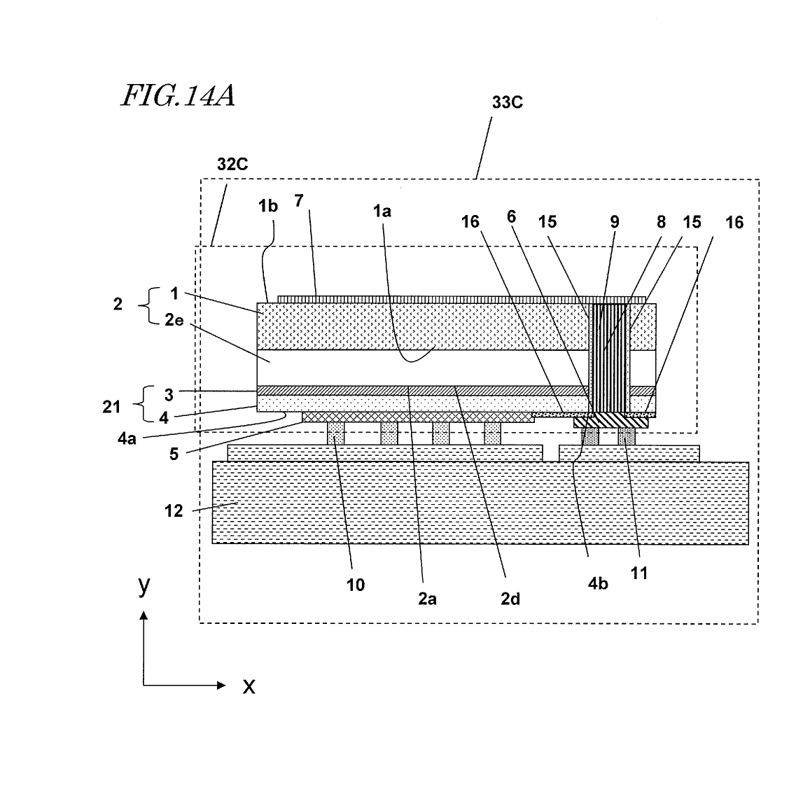

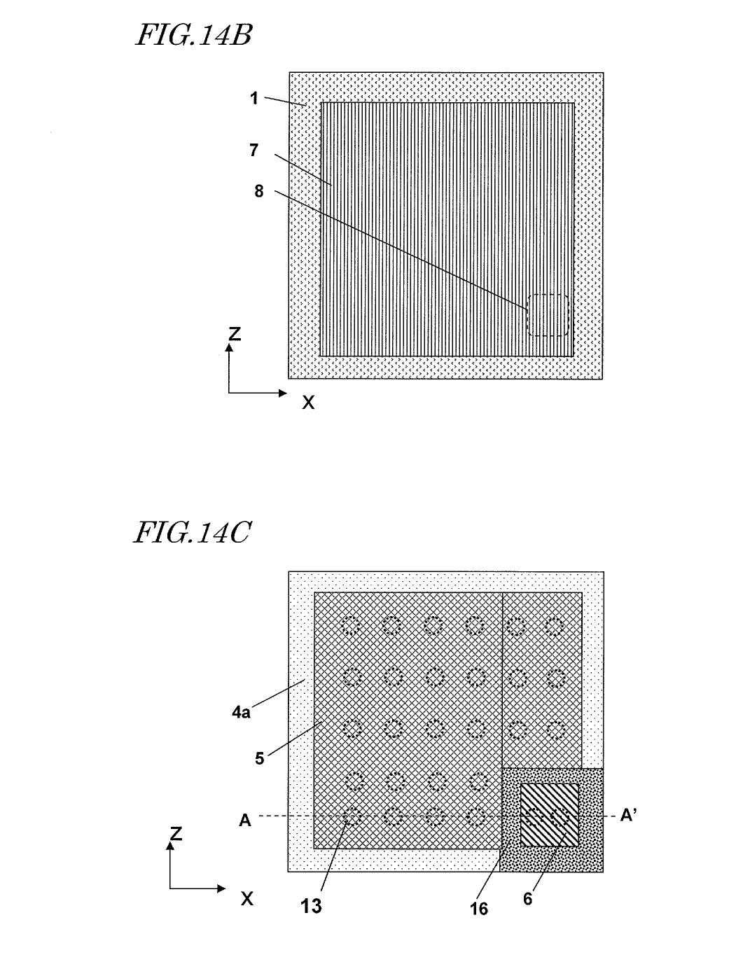

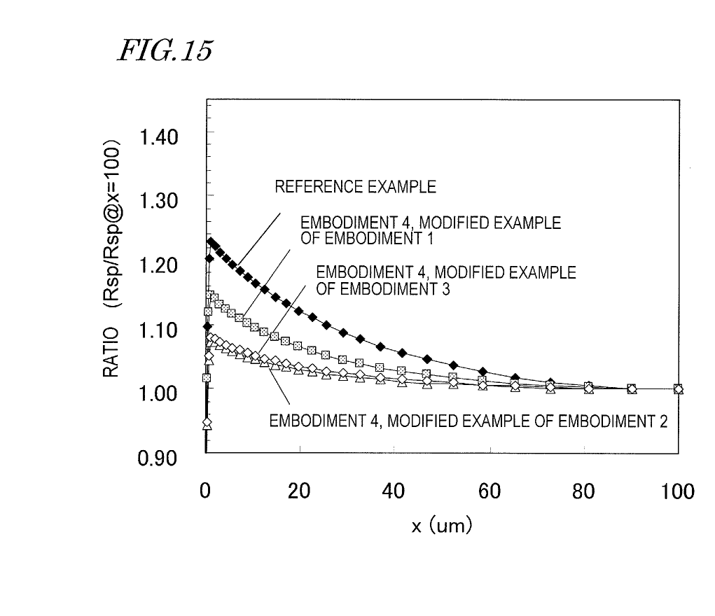

FIG. 14A is a cross-sectional view illustrating a third light-emitting diode device 33C of Embodiment 4. The third light-emitting diode device 33C is a modified example of the light-emitting diode device 31C of Embodiment 3. FIG. 14B is a plan view illustrating a light-emitting diode element 32C illustrated in FIG. 14A. FIG. 14C is a plan view illustrating a principal surface of the light-emitting diode element 32C. The third light-emitting diode device 33C illustrated in FIGS. 14A to 14C includes an n-type substrate 1. An n-type semiconductor layer 2e is provided on a principal surface 1a of the n-type substrate 1, and an n-type rear surface electrode 7 is provided on a rear surface 1b of the n-type substrate 1. A through hole 8 penetrates through not only the n-type semiconductor layer 2e, the active layer 3, and the p-type conductive layer 4 but also the n-type substrate 1. The n-type substrate 1, the n-type semiconductor layer 2e, the active layer 3, and the p-type conductive layer 4 constituting the inner wall of the through hole 8 are covered by the insulating film 15. Other configurations of the third light-emitting diode device 33C are the same as those of the light-emitting diode device 31C illustrated in FIGS. 11A to 11C. In FIGS. 14A to 14C, the same components as those in FIGS. 11A to 11C are denoted by the same reference symbols.

The impurity concentration of the n-type substrate 1 is, for example, 1×10¹⁷ cm⁻³ or more and 1×10¹⁸ cm⁻³ or less. The thickness of the n-type substrate 1 is, for example, about 50 μm or more and about 100 μm or less. In general, the n-type substrate 1 is ground to a predetermined thickness by polishing or the like. The n-type semiconductor layer 2e is formed on the n-type substrate 1 by epitaxial growth, and has a thickness of, for example, 3 μm or more and 10 μm or less.

As the total thickness of the n-type substrate 1 and the n-type semiconductor layer 2e becomes smaller, a larger amount of light can be extracted. However, it is difficult to perform the step of removing or peeling off the substrate from the n-type semiconductor layer 2e. In particular, a GaN substrate is made of the same material as that of the n-type semiconductor layer 2e made of GaN, and hence the removal or peeling-off becomes more difficult as compared with the case of using a sapphire substrate or a SiC substrate.

FIG. 15 is a graph showing simulation results of light emission rates of the first, second, and third light-emitting diode devices 33A, 33B, and 33C of this embodiment, illustrated in FIGS. 12 to 14. The graph of FIG. 15 shows the light emission rate of the active layer 3 along the A-A′ cross section in each of FIGS. 12C, 13C, and 14C. Note that, FIG. 15 shows, as a reference example, the simulation results of a light-emitting diode device which is a modification of the first light-emitting diode device 33A illustrated in FIG. 12, in which the insulating film 15 is not provided and the conductor portion 9 is in contact with the n-type conductive layer 2 and the n-type substrate 1. The simulation was performed assuming an element having an anode electrode width of 100 μm. The horizontal axis of the graph of FIG. 15 represents the position, provided that a terminal of the anode electrode on the A′ side of the A-A′ cross section is x=0 μm and a terminal of the anode electrode on the A side is x=100 μm. The vertical axis represents a value of the ratio, provided that the light emission rate for x=100 μm is 1.

It is understood that the light emission rate in the reference example is high in the vicinity of the through electrode, and a uniform light emission cannot be obtained, but in this embodiment, the uniformity in light emission is improved.

According to the first, second, and third light-emitting diode devices 33A, 33B, and 33C of this embodiment, the same effects as those in Embodiments 1 to 3 can be obtained, respectively. Descriptions thereof are omitted. In addition, in this embodiment, the step of removing or peeling off the substrate can be omitted to simplify the process. GaN has high thermal conductivity, and hence, when the n-type substrate 1 is disposed between the active layer 3 and the n-type rear surface electrode 7, heat of the active layer 3 can be dissipated to the rear surface side quickly. Thus, the increase in temperature of the active layer 3 can be suppressed.

### Embodiment 5

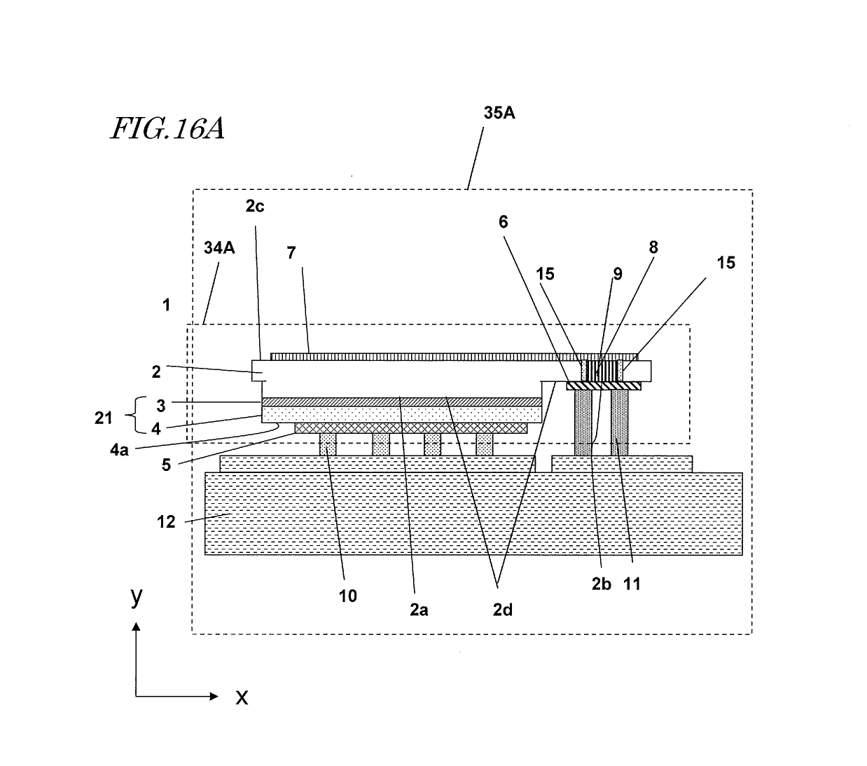

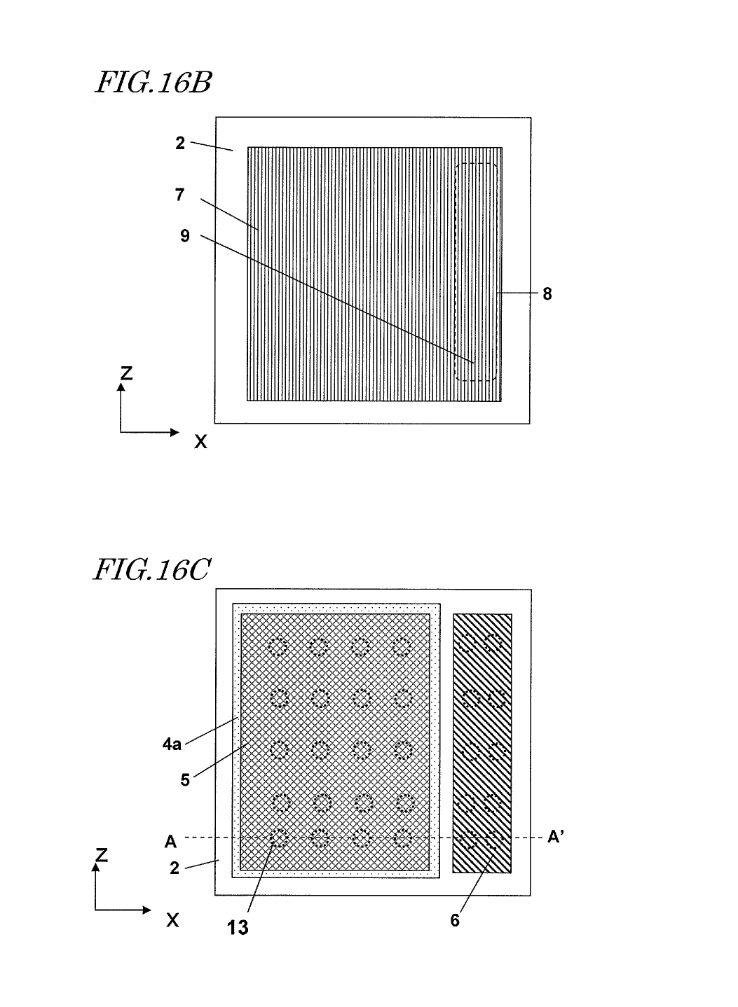

Next, a light-emitting diode device according to Embodiment 5 of the present invention is described with reference to FIGS. 16A to 18C. In Embodiments 1 to 3, the through hole 8 is provided at the corner of the n-type conductive layer 2 having a square planar shape (planar shape in the direction parallel to the principal surface 2d of the n-type conductive layer 2). In this embodiment, however, the through hole 8 is formed along one side of the square.

FIG. 16A is a cross-sectional view illustrating a first light-emitting diode device 35A of Embodiment 5. The first light-emitting diode device 35A is a modified example of the light-emitting diode device 31A of Embodiment 1. FIG. 16B is a plan view illustrating a rear surface of a light-emitting diode element 34A illustrated in FIG. 16A. FIG. 16C is a plan view illustrating a principal surface of the light-emitting diode element 34A.

In this embodiment, the through hole 8 and the n-type front surface electrode 6 are disposed at an end (end in the x direction) of the n-type conductive layer 2 having a square planar shape. The through hole 8 and the n-type front surface electrode 6 each have the sides along the x direction and the sides along the z direction. The sides of the through hole 8 and the n-type front surface electrode 6 along the z direction are longer than the sides thereof in the x direction, and hence the through hole 8 and the n-type front surface electrode 6 each have a rectangular planar shape.

In Embodiment 1, the n-type front surface electrode (illustrated in FIG. 8C etc.) is provided at the corner of the light-emitting diode element 30A having a square planar shape (at the corner seen in the direction perpendicular to the principal surface 2d of the n-type conductive layer 2), and the active layer 3, the p-type conductive layer 4, and the p-electrode 5 are provided so as to surround the periphery of the n-type front surface electrode 6. In this embodiment, on the other hand, the n-type front surface electrode 6 is formed along one side of the n-type conductive layer 2 (side along the z direction) so as to have a rectangular planar shape, and the active layer 3, the p-type conductive layer 4, and the p-electrode 5 each having a square planar shape are provided adjacent to the n-type front surface electrode 6.

The four corners of each of the through hole 8 and the n-type front surface electrode 6 may be round or substantially circular. That is, the shapes of the through hole 8 and the n-type front surface electrode 6 may be determined so that a desired light distribution pattern can be obtained.

Other configurations of the first light-emitting diode device 35A are the same as those of the light-emitting diode device 31A illustrated in FIGS. 8A to 8C. In FIGS. 16A to 16C, the same components as those in FIGS. 8A to 8C are denoted by the same reference symbols.

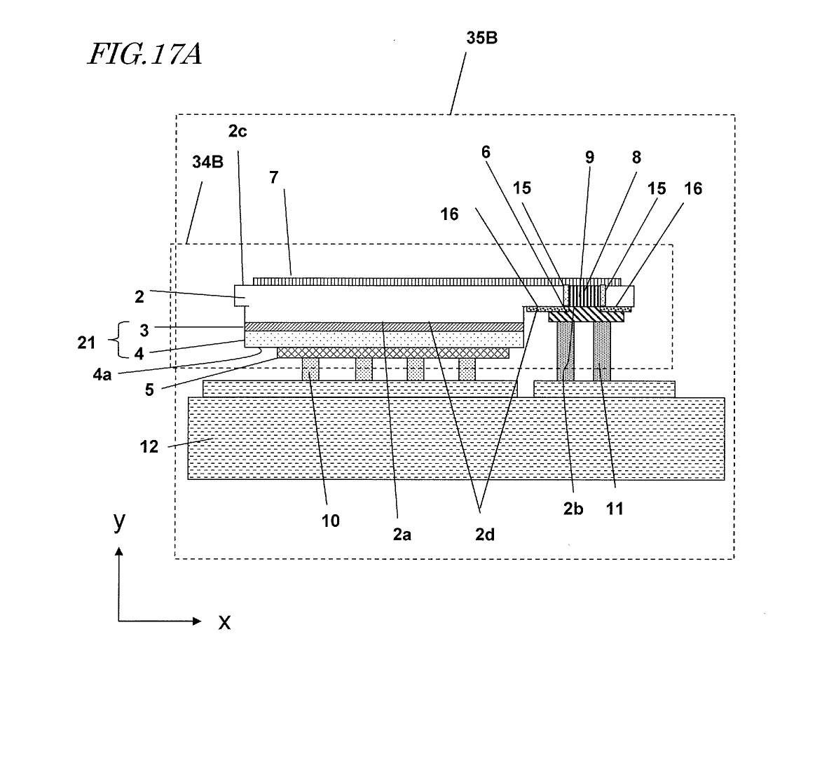

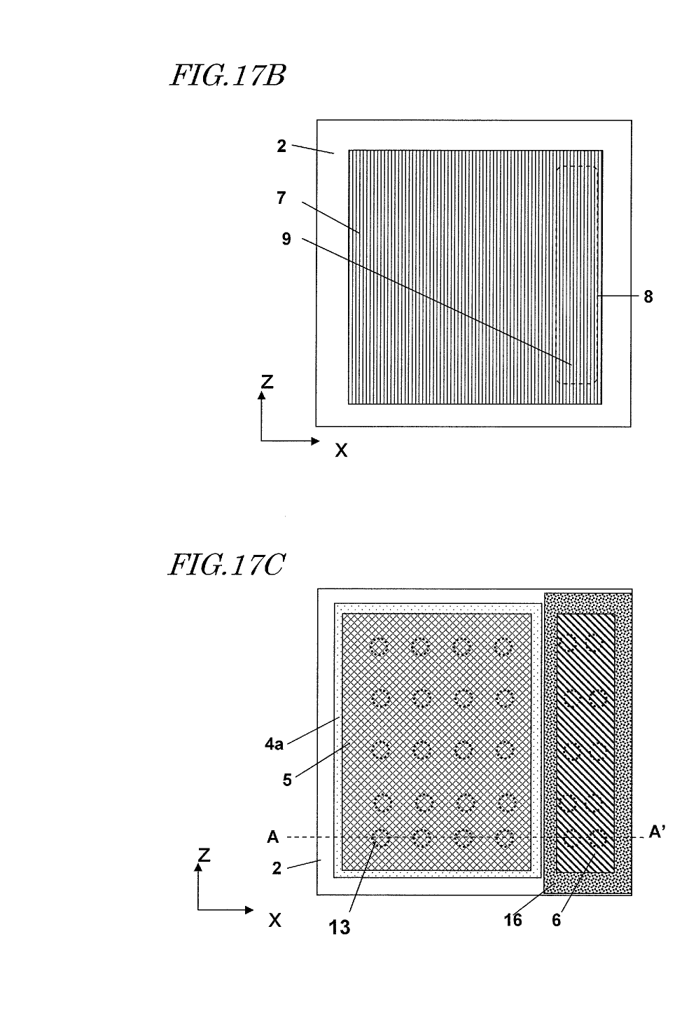

FIG. 17A is a cross-sectional view illustrating a second light-emitting diode device 35B of Embodiment 5. The second light-emitting diode device 35B is a modified example of the light-emitting diode device 31B of Embodiment 2. FIG. 17B is a plan view illustrating a rear surface of a light-emitting diode element 34B illustrated in FIG. 17A. FIG. 17C is a plan view illustrating a principal surface of the light-emitting diode element 34B.

The through hole 8 and the n-type front surface electrode 6 are disposed at an end (end in the x direction) of the n-type conductive layer 2 having a square planar shape. The through hole 8 and the n-type front surface electrode 6 each have the sides along the x direction and the sides along the z direction. The sides of the through hole 8 and the n-type front surface electrode 6 along the z direction are longer than the sides thereof in the x direction, and hence the through hole 8 and the n-type front surface electrode 6 each have a rectangular planar shape.

In Embodiment 2, the n-type front surface electrode 6 (illustrated in FIG. 10C etc.) is provided at the corner of the light-emitting diode element 30B having a square planar shape (at the corner seen in the direction perpendicular to the principal surface 2d of the n-type conductive layer 2), and the active layer 3, the p-type conductive layer 4, and the p-electrode 5 are provided so as to surround the periphery of the n-type front surface electrode 6. In this embodiment, on the other hand, the n-type front surface electrode 6 is formed along one side of the n-type conductive layer 2 (side along the z direction) so as to have a rectangular planar shape, and the active layer 3, the p-type conductive layer 4, and the p-electrode 5 each having a square planar shape are provided adjacent to the n-type front surface electrode 6.

The four corners of each of the through hole 8 and the n-type front surface electrode 6 may be round or substantially circular. That is, the shapes of the through hole 8 and the n-type front surface electrode 6 may be determined so that a desired light distribution pattern can be obtained.

Other configurations of the second light-emitting diode device 35B are the same as those of the light-emitting diode device 31B illustrated in FIGS. 10A to 10C. In FIGS. 17A to 17C, the same components as those in FIGS. 10A to 10C are denoted by the same reference symbols.

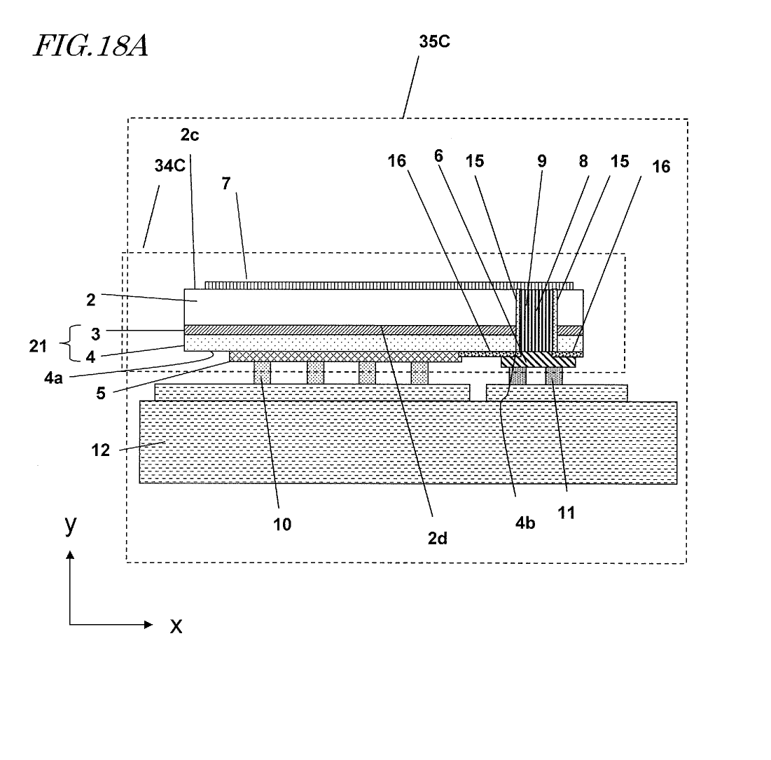

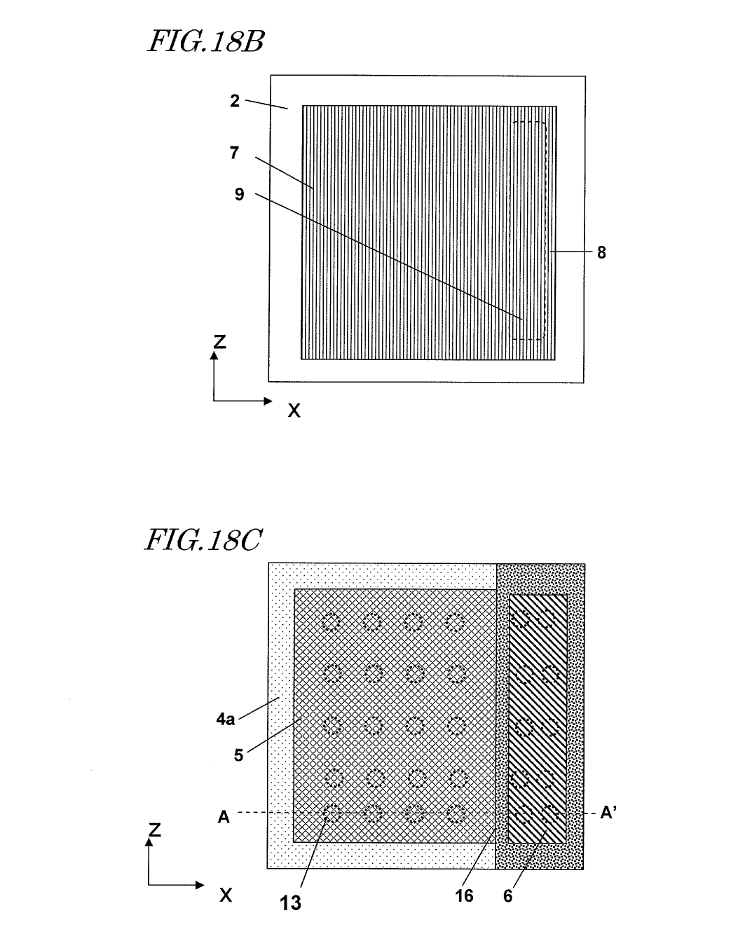

FIG. 18A is a cross-sectional view illustrating a third light-emitting diode device 35C of Embodiment 5. The third light-emitting diode device 35C is a modified example of the light-emitting diode device 31C of Embodiment 3. FIG. 18B is a plan view illustrating a rear surface of a light-emitting diode element 34C illustrated in FIG. 18A. FIG. 18C is a plan view illustrating a principal surface of the light-emitting diode element 34C.

The through hole 8 and the n-type front surface electrode 6 are disposed at an end (end in the x direction) of the n-type conductive layer 2 having a square planar shape. The through hole 8 and the n-type front surface electrode 6 each have the sides along the x direction and the sides along the z direction. The sides of the through hole 8 and the n-type front surface electrode 6 along the z direction are longer than the sides thereof in the x direction, and hence the through hole 8 and the n-type front surface electrode 6 each have a rectangular planar shape.

In Embodiment 3, the n-type front surface electrode (illustrated in FIG. 8C etc.) is provided at the corner of the principal surface of the p-type conductive lager 4 having a square planar shape. In this embodiment, on the other hand, the n-type front surface electrode 6 is formed along one side of the p-type conductive layer 4 (side along the z direction) so as to have a rectangular planar shape. The four corners of each of the through hole 8 and the n-type front surface electrode 6 may be round or substantially circular. That is, the shapes of the through hole 8 and the n-type front surface electrode 6 may be determined so that a desired light distribution pattern can be obtained.

Other configurations of the third light-emitting diode device 35C are the same as those of the light-emitting diode device 31C illustrated in FIGS. 11A to 11C. In FIGS. 18A to 18C, the same components as those in FIGS. 11A to 11C are denoted by the same reference symbols.

According to the first, second, and third light-emitting diode devices 35A, 35B, and 35C of this embodiment, the same effects as those in Embodiments 1 to 3 can be obtained, respectively.

In addition, in this embodiment, the p-electrode 5, the p-type conductive layer 4, and the active layer 3 each having a square planar shape are provided. Thus, as compared with Embodiment 2, a light emission distribution having no asymmetric part can be obtained. The planar shape of the active layer 3 may be any shape that can provide a desired light distribution pattern, such as a circle. According to this embodiment, a balanced configuration of light emission can be obtained.

Note that, this embodiment is a modified example of Embodiments 1, 2, and 3, but the through hole 8 may have a rectangular planar shape in the structure of Embodiment 4 etc.

### Embodiment 6

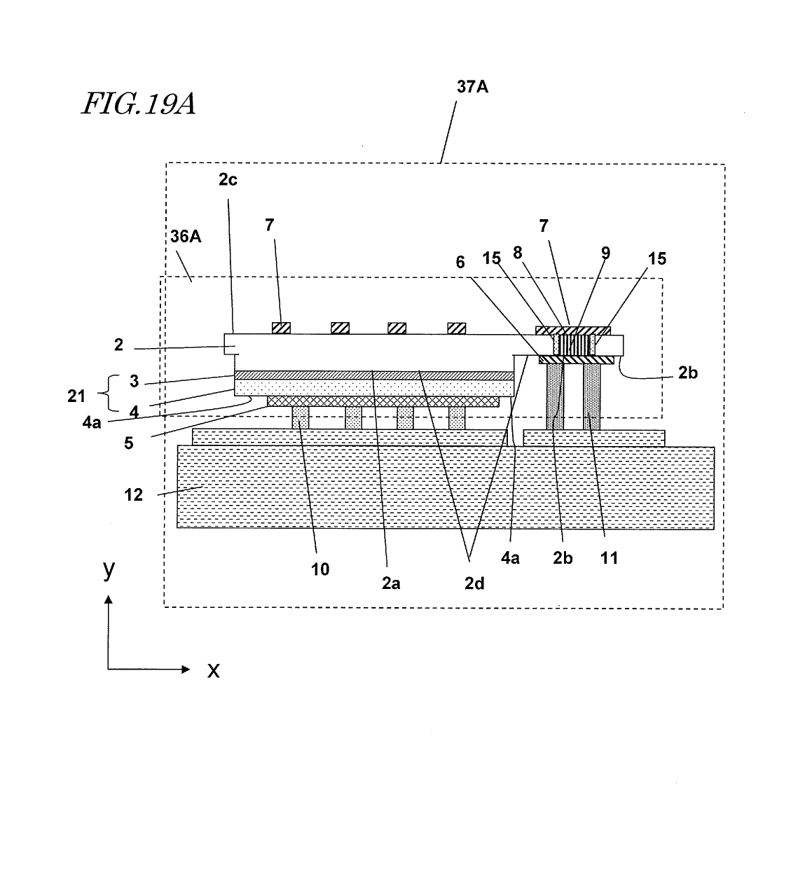

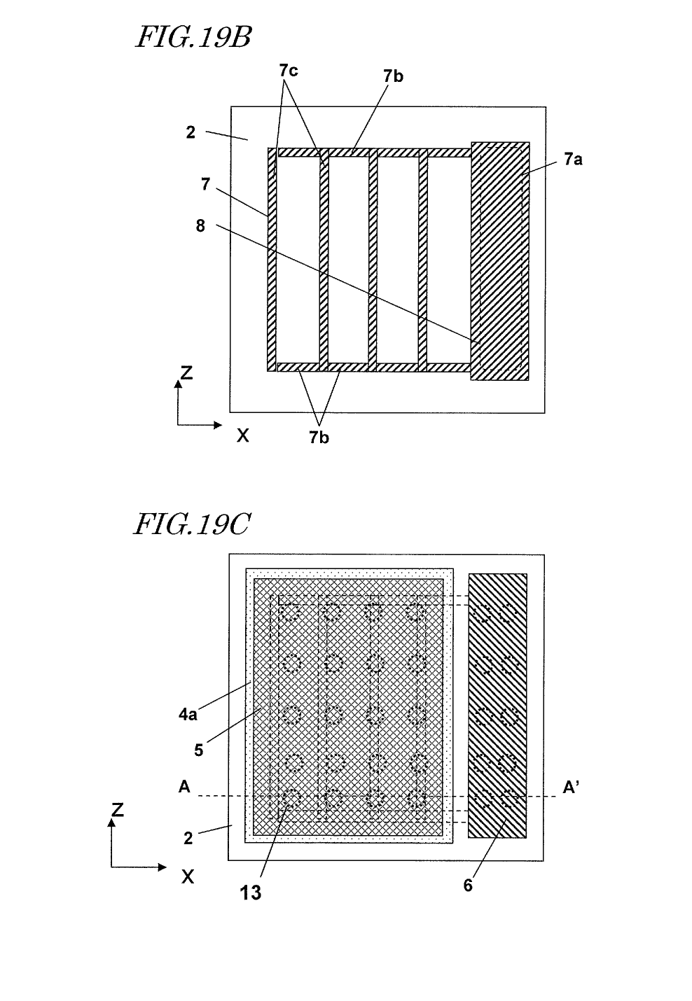

Next, a light-emitting diode device according to Embodiment 6 of the present invention is described with reference to FIGS. 19A to 22. Although the n-type rear surface electrode 7 in Embodiments 1 to 3 is provided on the entire rear surface of the n-type conductive layer 2, the n-type rear surface electrodes 7 in this embodiment are provided so as to be spaced apart from one another.

FIG. 19A is a cross-sectional view illustrating a first light-emitting diode device 37A of Embodiment 6. The first light-emitting diode device 37A is a modified example of the first light-emitting diode device 35A of Embodiment 5. FIG. 19B is a plan view illustrating a rear surface of a light-emitting diode element 36A illustrated in FIG. 19A. FIG. 19C is a view illustrating a surface of the light-emitting diode element 36A on the principal surface side.

In the first light-emitting diode device 37A of this embodiment, the n-type rear surface electrodes 7 are formed on the rear surface 2c of the n-type conductive layer 2. When seen in the direction perpendicular to the principal surface 2d of the n-type conductive layer 2 (y direction), the n-type rear surface electrode 7 is provided not only at the portion that overlaps the n-type front surface electrode 6 but also at the portion that overlaps the p-electrode 5 with the active layer 3 sandwiched therebetween. As illustrated in FIG. 19B, the n-type rear surface electrode 7 includes a main portion 7a covering the conductor portion 9, linear x-direction extended portions 7b extending from the main portion 7a in the x direction, and a plurality of linear z-direction extended portions 7c extending in the z direction. The opposite ends of each of the z-direction extended portions 7c are connected to the x-direction extended portions 7b. With this, the main portion 7a, the x-direction extended portions 7b, and the z-direction extended portions 7c are all electrically connected together. In this way, the n-type rear surface electrode 7 is provided on the rear surface 2c at approximately uniform density so that the voltage can be uniformly applied to the active layer 3. Light generated in the active layer 3 is extracted at the rear surface of the n-type conductive layer 2, through the gaps between the x-direction extended portions 7b and the z-direction extended portions 7c.

Other configurations of the first light-emitting diode device 37A are the same as those of the first light-emitting diode device 35A illustrated in FIGS. 16A to 16C. In FIGS. 19A to 19C, the same components as those in FIGS. 16A to 16C are denoted by the same reference symbols.

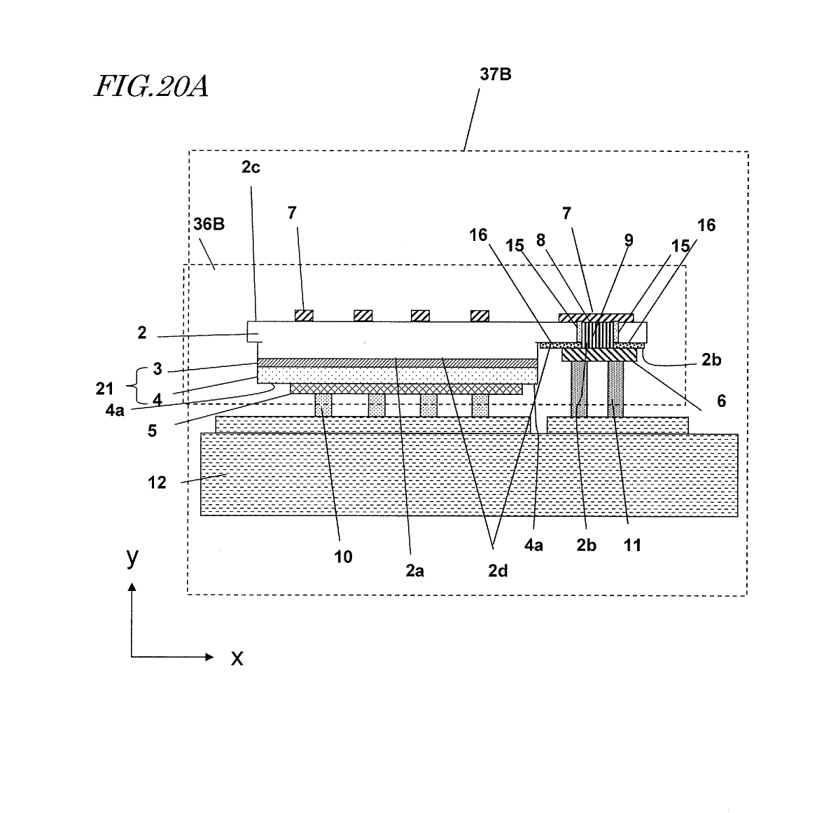

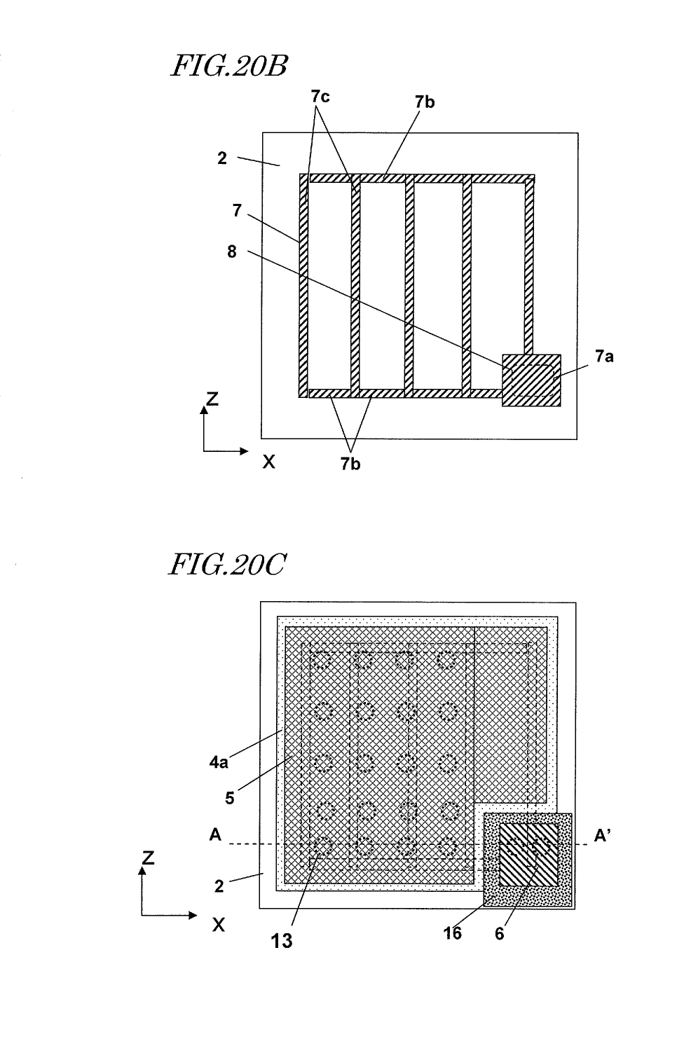

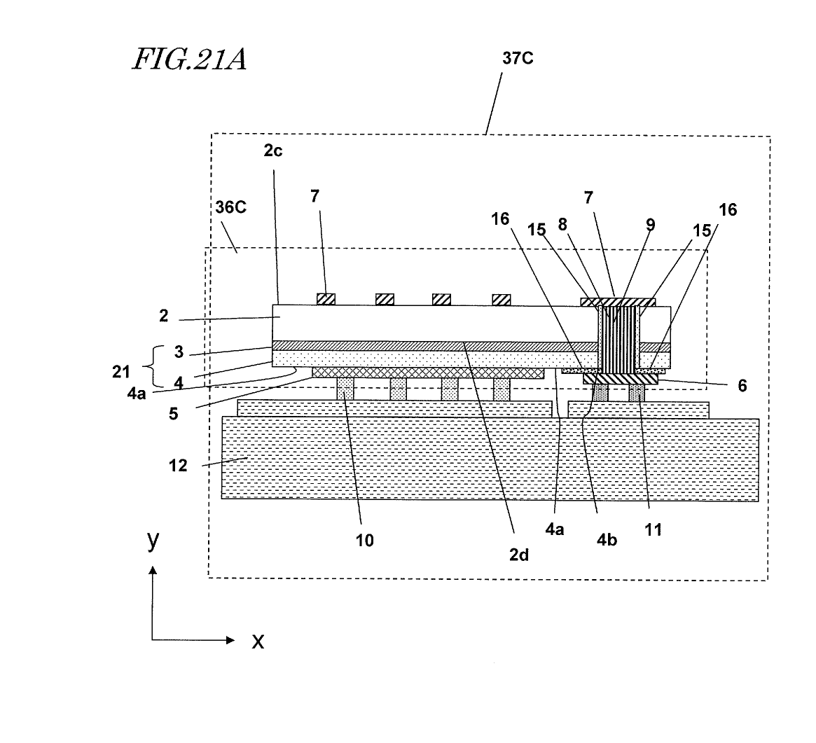

FIG. 20A is a cross-sectional view illustrating a second light-emitting diode device 37B of Embodiment 6. The second light-emitting diode device 37B is a modified example of the light-emitting diode device 31B of Embodiment 2. FIG. 20B is a plan view illustrating a rear surface of a light-emitting diode element 36B illustrated in FIG. 20A. FIG. 20C is a plan view illustrating a principal surface of the light-emitting diode element 36B.

In the second light-emitting diode device 37B of this embodiment, the n-type rear surface electrodes 7 are formed on the rear surface 2c of the n-type conductive layer 2. When seen in the direction perpendicular to the principal surface 2d of the n-type conductive layer 2 (y direction), the n-type rear surface electrode 7 is provided not only at the portion that overlaps the n-type front surface electrode 6 but also at the portion that overlaps the p-electrode 5 with the active layer 3 sandwiched therebetween. The n-type rear surface electrode 7 includes a main portion 7a covering the conductor portion 9, linear x-direction extended portions 7b extending from the main portion 7a in the x direction, and a plurality of linear z-direction extended portions 7c extending in the z direction. The opposite ends of each of the z-direction extended portions 7c are connected to the x-direction extended portions 7b. With this, the main portion 7a, the x-direction extended portions 7b, and the z-direction extended portions 7c are all electrically connected together. In this way, the n-type rear surface electrode 7 is provided on the rear surface 2c at approximately uniform density so that the voltage can be uniformly applied to the active layer 3. Light generated in the active layer 3 is extracted at the rear surface of the n-type conductive layer 2, through the gaps between the x-direction extended portions 7b and the z-direction extended portions 7c.

Other configurations of the second light-emitting diode device 37B are the same as those of the second light-emitting diode device 35B illustrated in FIGS. 17A to 17C. In FIGS. 20A to 20C, the same components as those in FIGS. 17A to 17C are denoted by the same reference symbols.

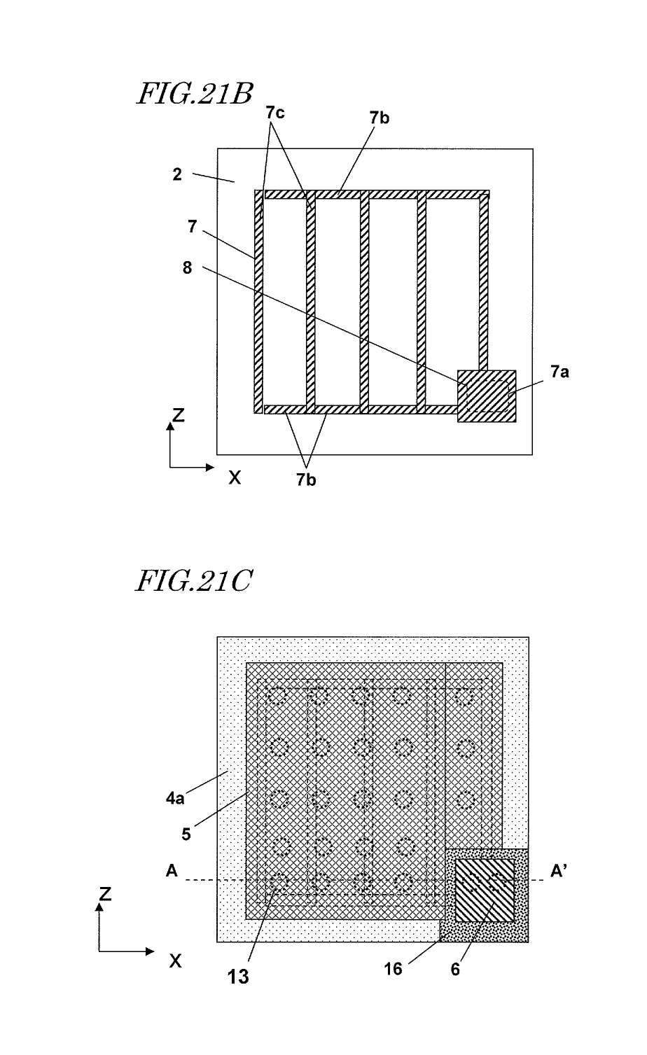

FIG. 21A is a cross-sectional view illustrating a third light-emitting diode device 37C of Embodiment 6. The third light-emitting diode device 37C is a modified example of the light-emitting diode device 31C of Embodiment 3. FIG. 21B is a plan view illustrating a rear surface of a light-emitting diode element 36C illustrated in FIG. 21A. FIG. 21C is a plan view illustrating a principal surface of the light-emitting diode element 36C.

In the third light-emitting diode device 37C of this embodiment, the n-type rear surface electrodes 7 are formed on the rear surface 2c of the n-type conductive layer 2. When seen in the direction perpendicular to the principal surface 2d of the n-type conductive layer 2 (y direction), the n-type rear surface electrode 7 is provided not only at the portion that overlaps the n-type front surface electrode 6 but also at the portion that overlaps the p-electrode 5 with the active layer 3 sandwiched therebetween. The n-type rear surface electrode 7 includes a main portion 7a covering the conductor portion 9, linear x-direction extended portions 7b extending from the main portion 7a in the x direction, and a plurality of linear z-direction extended portions 7c extending in the z direction. The opposite ends of each of the z-direction extended portions 7c are connected to the x-direction extended portions 7b. With this, the main portion 7a, the x-direction extended portions 7b, and the z-direction extended portions 7c are all electrically connected together. In this way, the n-type rear surface electrode 7 is provided on the rear surface 2c at approximately uniform density so that the voltage can be uniformly applied to the active layer 3. Light generated in the active layer 3 is extracted at the rear surface of the n-type conductive layer 2, through the gaps between the x-direction extended portions 7b and the z-direction extended portions 7c.

Other configurations of the third light-emitting diode device 37C are the same as those of the light-emitting diode device 31C illustrated in FIGS. 11A to 11C. In FIGS. 21A to 21C, the same components as those in FIGS. 11A to 11C are denoted by the same reference symbols.

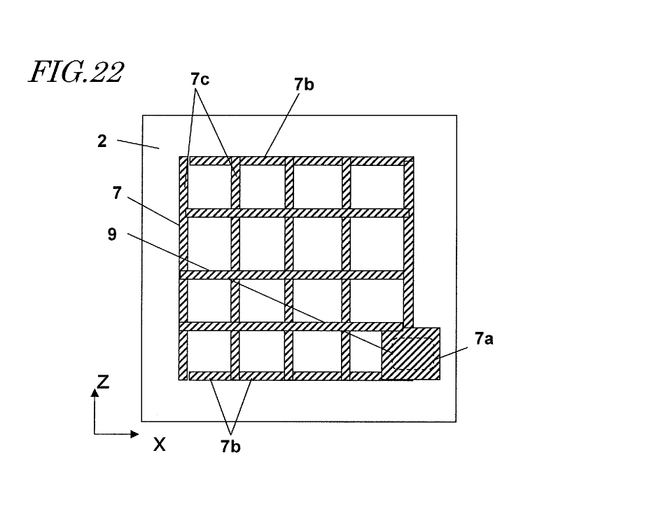

Note that, the n-type rear surface electrode 7 in this embodiment may not have the shape as illustrated in FIG. 19B, 20B, or 21B. The n-type rear surface electrode 7 may have another shape, such as a lattice shape, as long as the n-type rear surface electrode 7 is disposed on the rear surface 2c at approximately uniform density and the gaps for extracting light from the rear surface 2c are provided. FIG. 22 is a plan view illustrating an n-type rear surface electrode 7 having a lattice shape.

This embodiment has the same configurations as those of Embodiments 5, 2, and 3 except for the configuration of the n-type rear surface electrode 7. The description of the same configurations is omitted.

According to the first, second, and third light-emitting diode devices 37A, 37B, and 37C of this embodiment, the same effects as those in Embodiments 5, 2, and 3 can be obtained, respectively. In addition, in this embodiment, the gaps for extracting light are provided in the n-type rear surface electrode 7, and hence a non-transparent material can be used as the material of the n-type rear surface electrode 7. For example, metal such as Ti/Al, which has a low contact resistance and is inexpensive, can be used as the n-type rear surface electrode 7.

Note that, this embodiment is a modified example of Embodiments 5, 2, and 3, but the n-type rear surface electrodes 7 may be provided so as to be spaced apart from one another in the structure of Embodiment 1 or 4, etc.

### Embodiment 7

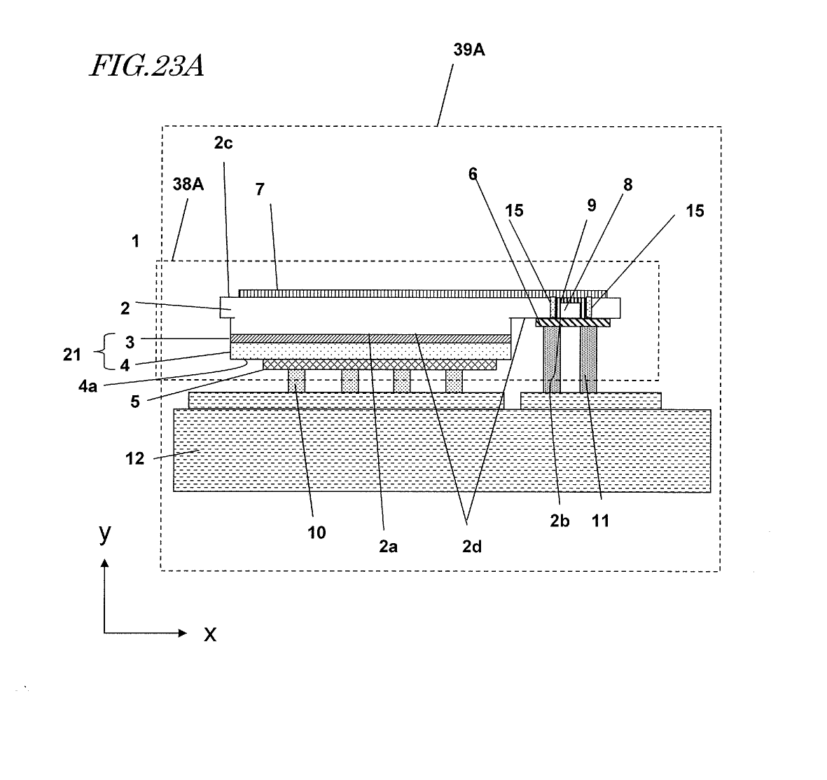

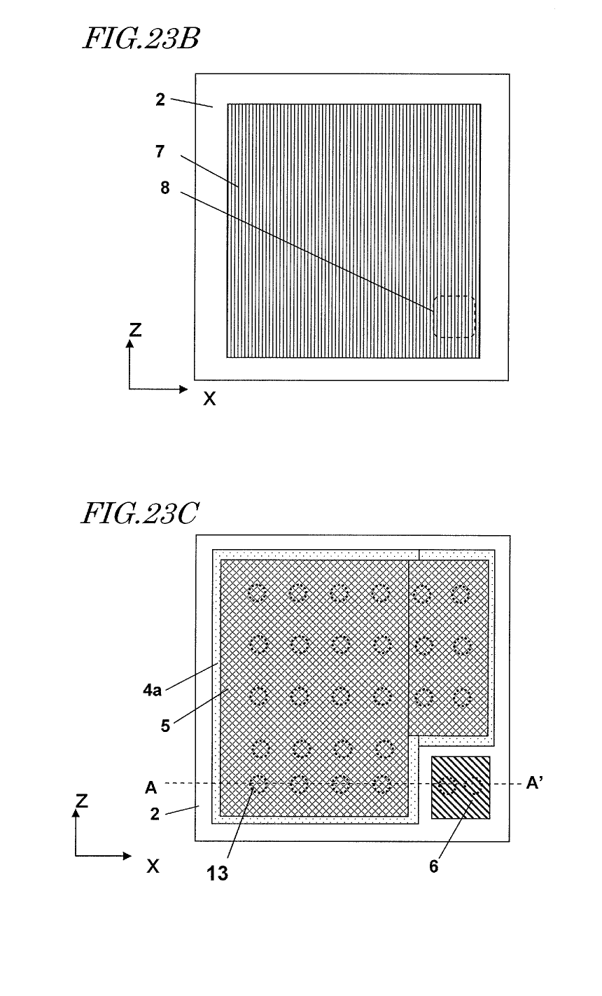

Next, a light-emitting diode device according to Embodiment 7 of the present invention is described with reference to FIGS. 23A to 25C. In this embodiment, a cavity is formed inside the through hole 8.

FIG. 23A is a cross-sectional view illustrating a first light-emitting diode device 39A of Embodiment 7. The first light-emitting diode device 39A is a modified example of the light-emitting diode device 31A of Embodiment 1. FIG. 23B is a plan view illustrating a rear surface of a light-emitting diode element 38A illustrated in FIG. 23A. FIG. 23C is a plan view illustrating a principal surface of the light-emitting diode element 38A.

In the first light-emitting diode device 39A, the insulating film 15 covers the inner wall of the through hole 8, and the conductor portion 9 is formed on the inner side of the insulating film 15. The conductor portion 9 is not filled in the through hole 8, but a cavity is formed inside the through hole 8.

Other configurations of the first light-emitting diode device 39A are the same as those of the light-emitting diode device 31A illustrated in FIGS. 8A to 8C. In FIGS. 23A to 23C, the same components as those in FIGS. 8A to 8C are denoted by the same reference symbols.

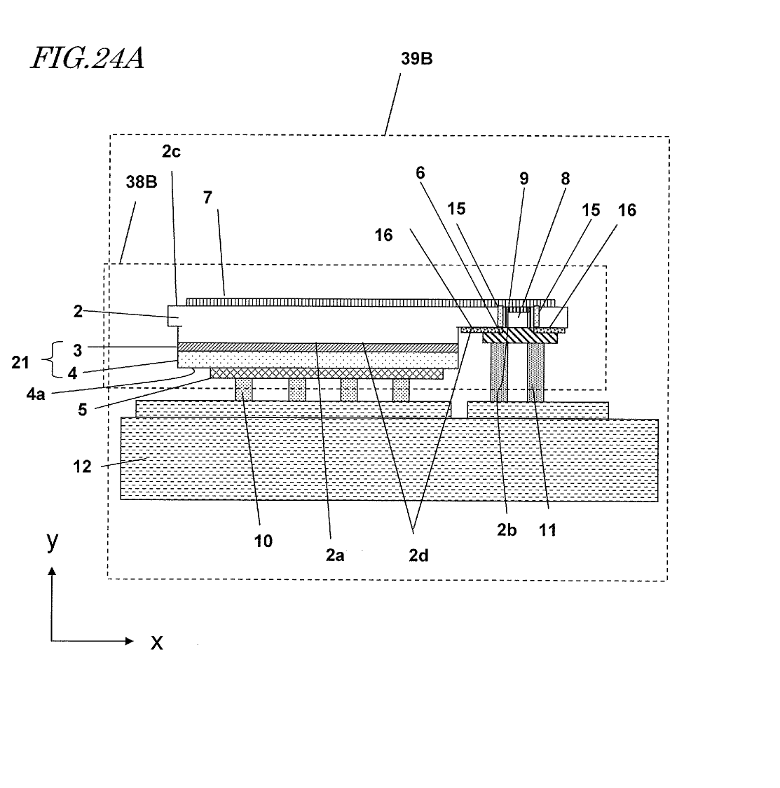

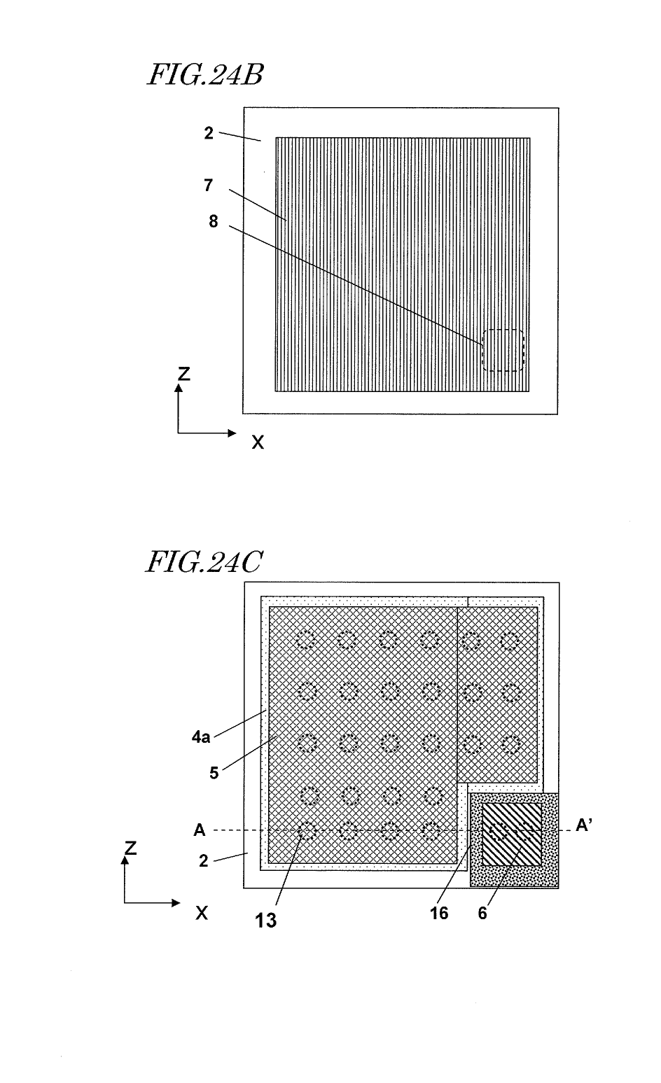

FIG. 24A is a cross-sectional view illustrating a second light-emitting diode device 39B of Embodiment 7. The second light-emitting diode device 39B is a modified example of the light-emitting diode device 31B of Embodiment 2. FIG. 24B is a plan view illustrating a rear surface of a light-emitting diode element 38B illustrated in FIG. 24A. FIG. 24C is a plan view illustrating a principal surface of the light-emitting diode element 38B.

In the second light-emitting diode device 39B, the insulating film 15 covers the inner wall of the through hole 8, and the conductor portion 9 is formed on the inner side of the insulating film 15. The conductor portion 9 is not filled in the through hole 8, but a cavity is formed inside the through hole 8.

Other configurations of the second light-emitting diode device 39B are the same as those of the light-emitting diode device 31B illustrated in FIGS. 10A to 10C. In FIGS. 24A to 24C, the same components as those in FIGS. 10A to 10C are denoted by the same reference symbols.

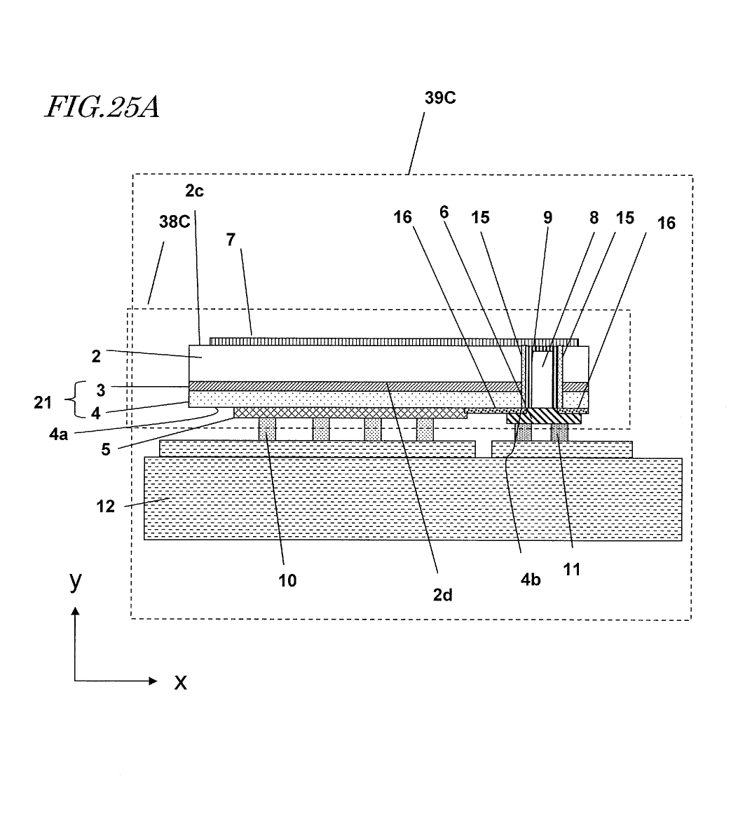

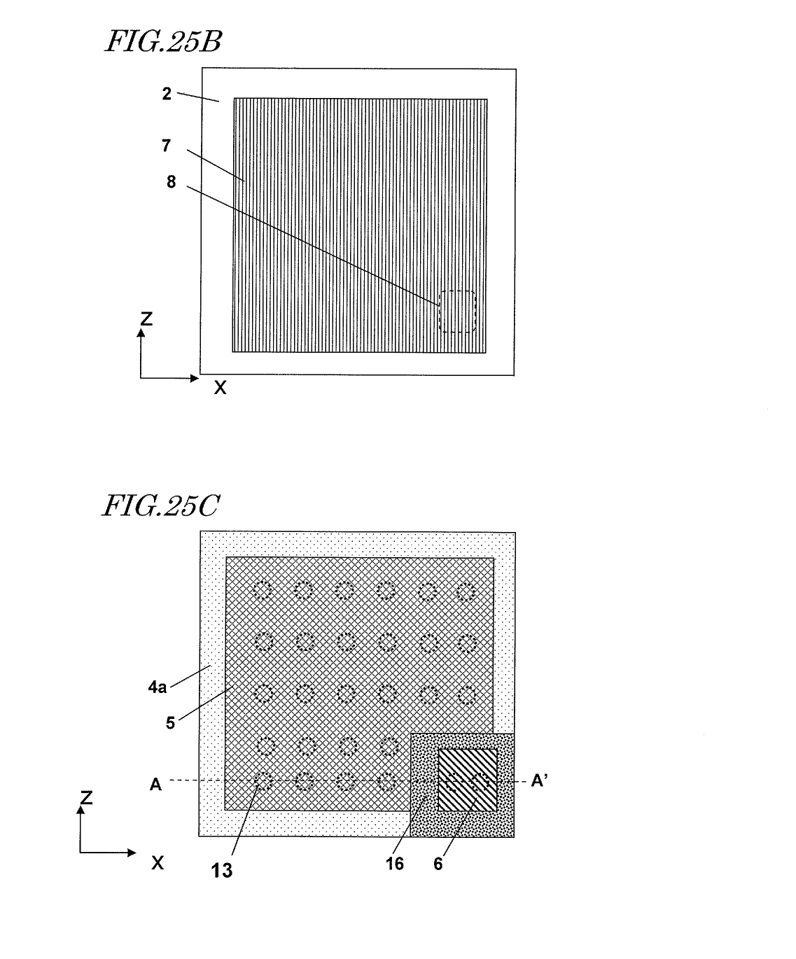

FIG. 25A is a cross-sectional view illustrating a third light-emitting diode device 39C of Embodiment 7. The third light-emitting diode device 39C is a modified example of the light-emitting diode device 31C of Embodiment 3. FIG. 25B is a plan view illustrating a rear surface of a light-emitting diode element 38C illustrated in FIG. 25A. FIG. 25C is a plan view illustrating a principal surface of the light-emitting diode element 38C.

In the third light-emitting diode device 39C, the insulating film 15 covers the inner wall of the through hole 8, and the conductor portion 9 is formed on the inner side of the insulating film 15. The conductor portion 9 is not filled in the through hole 8, but a cavity is formed inside the through hole 8.

Other configurations of the third light-emitting diode device 39C are the same as those of the light-emitting diode device 31C illustrated in FIGS. 11A to 11C. In FIGS. 25A to 25C, the same components as those in FIGS. 11A to 11C are denoted by the same reference symbols.

According to the first, second, and third light-emitting diode devices 39A, 39B, and 39C of this embodiment, the same effects as those in Embodiments 1 to 3 can be obtained, respectively.

In addition, this embodiment can provide the following effects. A GaN light-emitting diode is apt to generate heat, and the chip temperature may increase to around 100 K. There is a large difference in coefficient of linear expansion between GaN and Al used as the conductor portion 9, and GaN and Al have coefficients of linear expansion of 3×10⁻⁶/K to 6×10⁻⁶/K and 23×10⁻⁶/K, respectively. The cavity provided in the through hole 8 as in this embodiment can prevent a strong stress from being applied to the portion of the n-type conductive layer 2 which is positioned in the vicinity of the through hole 8 even when the conductor portion expands along with the increase in element temperature. This can prevent the generation of cracks and peeling-off in the vicinity of the through hole 8.

Note that, this embodiment is a modified example of Embodiments 1, 2, and 3, but a cavity may be provided inside the through hole 8 in the structures of Embodiments 4 to 6, etc.

### Embodiment 8

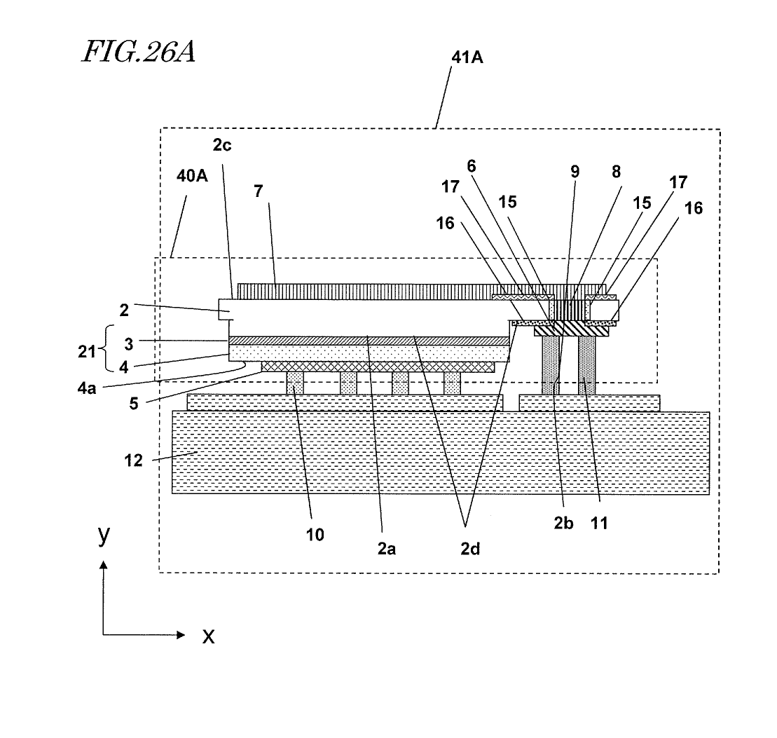

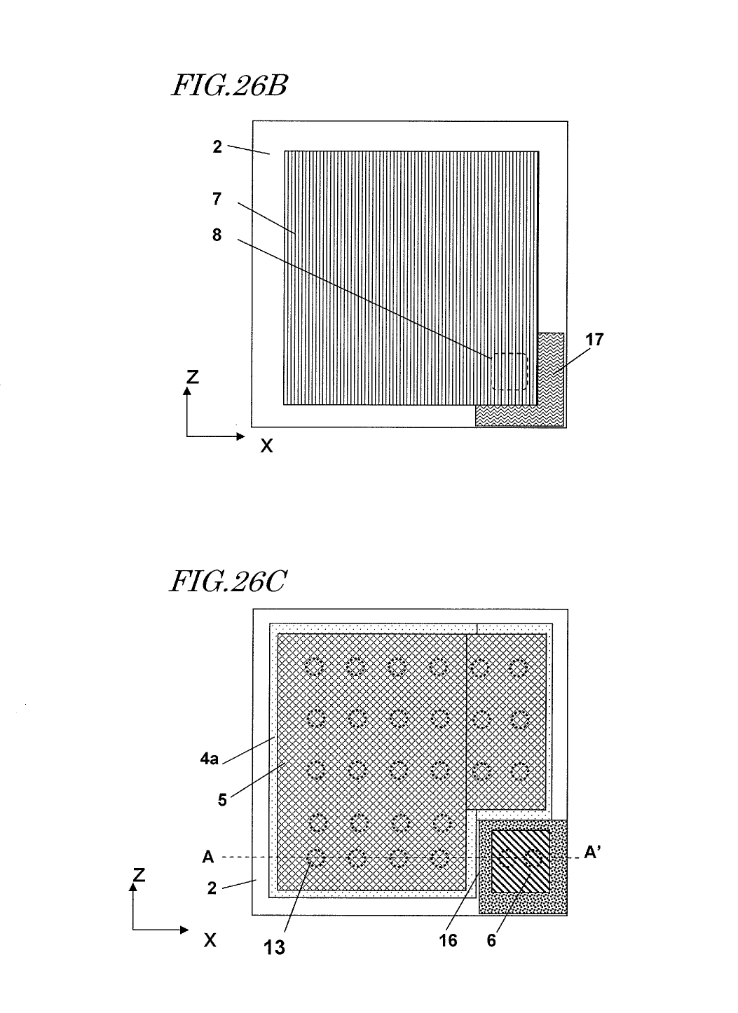

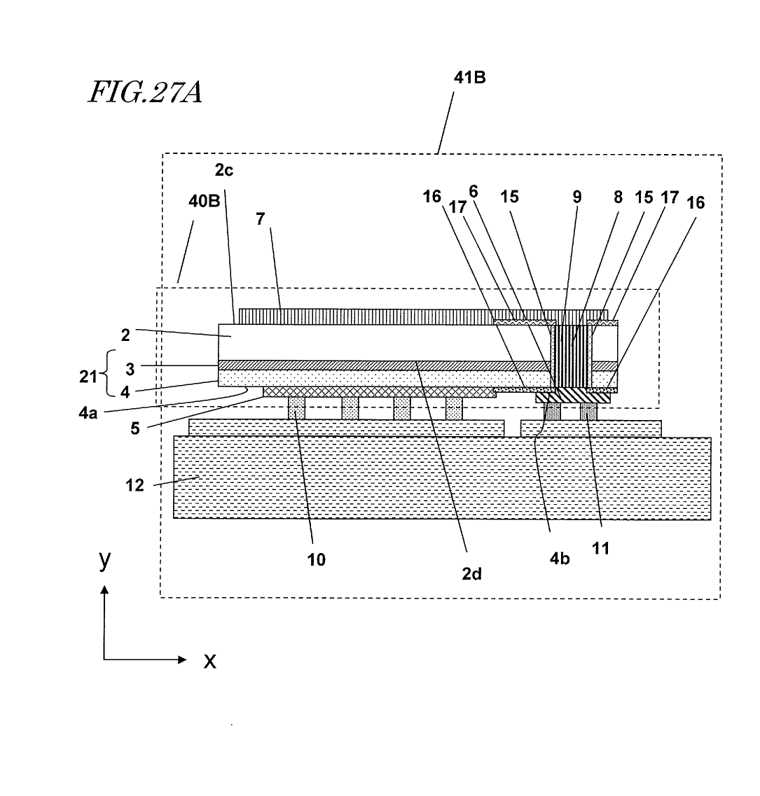

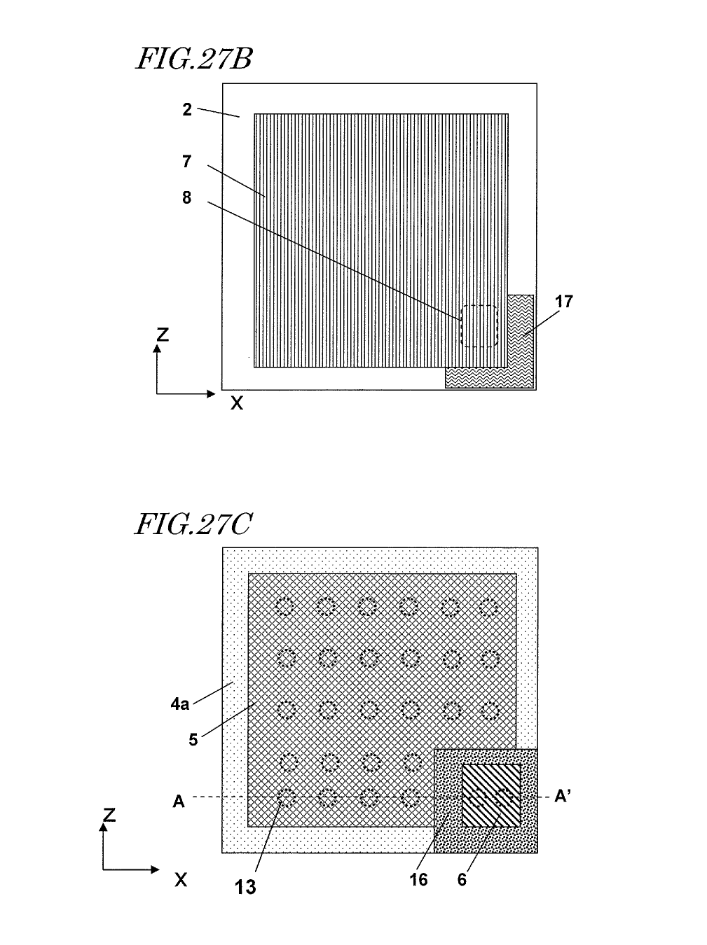

Next, a light-emitting diode device according to Embodiment 8 of the present invention is described with reference to FIGS. 26A to 27C. In this embodiment, an insulating film is also provided on the rear surface side of the light-emitting diode element.

FIG. 26A is a cross-sectional view illustrating a first light-emitting diode device 41A of Embodiment 8. The first light-emitting diode device 41A is a modified example of the light-emitting diode device 31B of Embodiment 2. FIG. 26B is a plan view illustrating a rear surface of a light-emitting diode element 40A illustrated in FIG. 26A. FIG. 26C is a plan view illustrating a principal surface of the light-emitting diode element 40A illustrated in FIG. 26A. In FIGS. 26A to 26C, the same components as those in FIGS. 8A to 8C are denoted by the same reference symbols.

As illustrated in FIG. 26, in the light-emitting diode element 40A of this embodiment, an insulating film 17 is provided on the rear surface 2c of the n-type conductive layer 2. The insulating film 17 is provided on the rear surface 2c of the n-type conductive layer 2 at a portion positioned in the vicinity of the through hole 8 (portion opposing the insulating film 16).

The n-type rear surface electrode 7 is provided on the rear surface 2c of the n-type conductive layer 2. The n-type rear surface electrode 7 is provided on the rear surface side of the insulating film 17 at a portion of the rear surface 2c of the n-type conductive layer 2 on which the insulating film 17 is provided. The n-type rear surface electrode 7 is provided to be in direct contact with the n-type conductive layer 2 at a portion of the rear surface 2c of the n-type conductive layer 2 on which the insulating film 17 is not provided. The n-type rear surface electrode 7 is in contact with the conductor portion 9 provided inside the through hole 8.

The insulating film 17 may be made of the same material as that of the insulating film 15, or may be made of a different material. The thickness of the insulating film 16 may be 100 nm or more and 500 nm or less. The insulating film 17 can be formed by performing CVD or the like for forming a silicon oxide film on the rear surface 2c side of the n-type conductive layer 2 after the formation of the through hole 8. After that, the n-type rear surface electrode 7 is provided on the rear surface side of the insulating film 17 and on an exposed portion of the rear surface 2c of the n-type conductive layer 2.

The insulating film may be left in a region of the principal surface of the p-type conductive layer 4 other than the region in which the p-electrode 5 is to be formed. Other configurations of the first light-emitting diode device 41A are the same as those of the light-emitting diode device 31B illustrated in FIGS. 8A to 8C.

FIG. 27A is a cross-sectional view illustrating a second light-emitting diode device 41B of Embodiment 8. The second light-emitting diode device 41B is a modified example of the light-emitting diode device 31C of Embodiment 3. FIG. 27B is a plan view illustrating a rear surface of a light-emitting diode element 40B illustrated in FIG. 27A. FIG. 27C is a plan view illustrating a principal surface of the light-emitting diode element 40B illustrated in FIG. 27A. In FIGS. 27A to 27C, the same components as those in FIGS. 11A to 11C are denoted by the same reference symbols.

As illustrated in FIG. 27, in the light-emitting diode element 40B of this embodiment, an insulating film 17 is provided on the rear surface 2c of the n-type conductive layer 2. The insulating film 17 is provided on the rear surface 2c of the n-type conductive layer 2 at a portion positioned in the vicinity of the through hole 8 (portion opposing the insulating film 16).

The n-type rear surface electrode 7 is provided on the rear surface 2c of the n-type conductive layer 2. The n-type rear surface electrode 7 is provided on the rear surface side of the insulating film 17 at a portion of the rear surface 2c of the n-type conductive layer 2 on which the insulating film 17 is provided. The n-type rear surface electrode 7 is provided to be in direct contact with the n-type conductive layer 2 at a portion of the rear surface 2c of the n-type conductive layer 2 on which the insulating film 17 is not provided. The n-type rear surface electrode 7 is in contact with the conductor portion 9 at an opening portion of the through hole 8.

The insulating film 17 may be made of the same material as that of the insulating film 15, or may be made of a different material. The thickness of the insulating film 16 may be 100 nm or more and 500 nm or less. The insulating film 17 can be formed by performing CVD or the like for forming a silicon oxide film on the rear surface 2c side of the n-type conductive layer 2 after the formation of the through hole 8. At this time, the insulating film 17 is formed all over the rear surface 2c of the n-type conductive layer 2, and hence an unnecessary portion is removed by etching or the like. After that, the n-type rear surface electrode 7 is provided on the rear surface side of the insulating film 17 and on an exposed portion of the rear surface 2c of the n-type conductive layer 2.

The insulating film may be left in a region of the principal surface of the p-type conductive layer 4 other than the regions in which the p-electrode 5 and the n-type front surface electrode 6 are to be formed. Other configurations of the second light-emitting diode device 41B are the same as those of the light-emitting diode device 31C illustrated in FIGS. 8A to 8C.

According to the first and second light-emitting diode devices 41A and 41B of this embodiment, the same effects as those in Embodiments 2 and 3 can be obtained, respectively.

In addition, according to this embodiment, the insulating film 17 is provided, and hence the portion of the n-type rear surface electrode 7 which is positioned in the vicinity of the through hole 8 can be prevented from being brought into contact with the n-type conductive layer 2. This suppresses the increase in light emission intensity in the vicinity of the through hole 8, thus obtaining a uniform light emission pattern. This effect is particularly large in the case where the thickness of the n-type conductive layer 2 has a small value such as 5 μm because the amount of electric current flowing to the n-type rear surface electrode 7 side is large.

Note that, this embodiment is a modified example of Embodiment 2, but the insulating film 17 may be provided in the structures of Embodiments 1, and 3 to 7.

According to Embodiments 1 to 8, a wire portion and a bonding portion does not make a shadow, and hence a good radiation pattern can be realized.

### Embodiment 9

FIG. 28A is a cross-sectional view illustrating a light-emitting diode device 51A of Embodiment 9. FIG. 28B is a plan view illustrating a rear surface of a light-emitting diode element 50A illustrated in FIG. 28A. FIG. 28C is a plan view illustrating a principal surface of the light-emitting diode element 50A. Note that, FIG. 28A is a cross-sectional view taken along the line A-A′ of FIG. 28C. In FIGS. 28A to 28C, the same components as those in FIGS. 5A to 5C are denoted by the same reference symbols.

As illustrated in FIG. 28A, the light-emitting diode device 51A of this embodiment has a configuration in which the light-emitting diode element (chip) 50A is mounted on a mounting base 12. The light-emitting diode element 50A is mounted on the mounting base 12 via bumps 10 and 11. The bump 10 connects a p-electrode (anode electrode) 5 of the light-emitting diode element 50A and the mounting base 12 to each other. The bump 11 connects an n-type front surface electrode 6 of the light-emitting diode element 50A and the mounting base 12 to each other.

The light-emitting diode element 50A includes an n-type conductive layer 2 made of n-type GaN, and a semiconductor multilayer structure 21 provided in a first region 2a of a principal surface 2d of the n-type conductive layer 2. For convenience of description, the principal surface 2d of the n-type conductive layer 2 is divided into a first region (first front surface region) 2a and a second region (second front surface region) 2b. In the principal surface 2d of the n-type conductive layer 2, a portion constituting the bottom surface of a recessed portion 20 is referred to as second region 2b. In the principal surface 2d of the n-type conductive layer 2, the outside of the recessed portion 20 is referred to as first region 2a. The semiconductor multilayer structure 21 includes an active layer 3 provided on the principal surface of the n-type conductive layer 2, and a p-type conductive layer 4 made of p-type GaN and provided on a principal surface of the active layer 3. The active layer 3 has a quantum well structure which is formed by stacked layers of, for example, InGaN and GaN. All parts of the n-type conductive layer 2 or a surface layer of the n-type conductive layer 2, and the active layer 3 and the p-type conductive layer 4 are each an epitaxially grown layer whose principal surface has another plane orientation than the m-plane. Specifically, the other plane orientations than the m-plane include a c-plane, an a-plane, a +r-plane, a −r-plane, a (11-22) plane, a (11-2-2) plane, a (10-11) plane, a (10-1-1) plane, a (20-21) plane, and a (20-2-1) plane. WO 2011/010436 A1 describes a light-emitting diode device in which an n-type conductive layer 2, an active layer 3, and a p-type conductive layer 4 each have an m-plane principal surface. As used herein, “the other plane orientations than the m-plane” also include a plane not completely parallel to each plane, that is, a plane may be inclined from each plane in a predetermined direction in the range of ±5°. The inclination angle is defined by an angle formed between the normal to an actual principal surface of a nitride semiconductor layer and the normal to each plane (each plane which is not inclined). In other words, the “c-plane” in this embodiment also includes a plane which is inclined from a c-plane (c-plane which is not inclined) in a predetermined direction in the range of ±5°. The same applies to the other planes (a-plane, +r-plane, −r-plane, (11-22) plane, (11-2-2) plane, (10-11) plane, (10-1-1) plane, (20-21) plane, and (20-2-1) plane).

As illustrated in FIG. 28C, the p-electrode 5 is provided on a principal surface 4a of the p-type conductive layer 4. On the other hand, the n-type front surface electrode 6 is provided in the second region 2b of the principal surface of the n-type conductive layer 2. In this embodiment, the p-electrode 5 is composed of, for example, a Pd/Pt layer, and the n-type front surface electrode 6 is composed of, for example, a Ti/Al layer. However, the configurations of the p-electrode 5 and the n-type front surface electrode 6 are not limited thereto.

The n-type conductive layer 2 is provided with a through hole 8 that penetrates through the n-type conductive layer 2. A conductor portion (n-type through electrode) made of, for example, Al is embedded in the through hole 8. The conductor portion 9 is in contact with the n-type front surface electrode 6 in the second region 2b of the principal surface 2d of the n-type conductive layer 2. On the other hand, an n-type rear surface electrode 7 made from indium tin oxide (ITO) is formed on the rear surface 2c of the n-type conductive layer 2 so as to be in contact with the conductor portion 9. As illustrated in FIG. 28B, the n-type rear surface electrode 7 covers the conductor portion 9 on the rear surface 2c of the n-type conductive layer 2.

In the case where the principal surface 2d of the n-type conductive layer 2 is a c-plane, the inner wall of the through hole 8 can have the plane orientation of an m-plane or an a-plane, for example. In the case where the principal surface 2d of the n-type conductive layer 2 is an a-plane, the inner wall of the through hole 8 can have the plane orientation of a c-plane or an m-plane, for example. In the case where the principal surface 2d of the n-type conductive layer 2 has an r-plane, the inner wall of the through hole 8 can have the plane orientation of an a-plane, for example.

The n-type conductive layer 2 made of GaN is formed on, for example, an n-type GaN substrate (not shown) by using epitaxial growth. After the manufacturing step on the principal surface side of the light-emitting diode element 50A is completed, polishing or etching is performed from the rear surface side, to thereby peel off the substrate. The light-emitting diode element 50A illustrated in FIG. 28A is formed by removing the n-type GaN substrate entirely, but the n-type GaN substrate may be thinned by polishing or etching so that a part of the n-type GaN substrate may be left. Alternatively, the n-type conductive layer 2 made of GaN may be formed by epitaxial growth on a substrate made of a material different from that of the n-type conductive layer 2, such as a sapphire substrate, and then the substrate may be peeled off. The thickness of the n-type conductive layer is in the range of, for example, from 3 μm to 50 μm. Light generated in the active layer 3 is extracted through the rear surface 2c of the n-type conductive layer 2. In this case, in order to improve light extraction efficiency, the n-type conductive layer 2 may be thinned as much as possible so as to reduce an absorption loss caused by the n-type conductive layer 2. Considering the mechanical strength of the light-emitting diode element 50A, some structural measures may be taken, such as bonding a Si support substrate on which p-electrode wirings to be connected to the p-electrode and n-electrode wirings to be connected to the n-electrode are patterned onto a chip to prevent cracks in the chip. As an example of the steps in this case, after the completion of the process on the element front surface side, the patterned Si support substrate is bonded on the element front surface side, and after that, the step of thinning, such as peeling off the substrate, is performed. Then, the process on the element rear surface is performed, and the chip which is manufactured by being separated from the substrate is mounted on the mounting base.

An overflow stopper layer, which has the effect of preventing overflow of carriers so as to improve light emission efficiency, may be interposed between the active layer 3 and the p-type conductive layer 4 in the light-emitting diode element 50A. The overflow stopper layer may be composed of, for example, an AlGaN layer. In this embodiment, these measures may be incorporated into the structure, although these measures are not illustrated in the drawings and the detailed descriptions thereof are herein omitted.

Hereinafter, an example of a method of fabricating a light-emitting diode element 50A of this embodiment is described with reference to FIG. 28.

Firstly, an n-type GaN substrate (not shown) is provided whose principal surface is the c-plane.

In this embodiment, crystalline layers are sequentially formed on a substrate by metal organic chemical vapor deposition (MOCVD). Firstly, on the n-type GaN substrate, a GaN layer having a thickness of 3 μm to 50 μm is formed as the n-type conductive layer 2. Specifically, a GaN layer is deposited on the n-type GaN substrate by supplying TMG (Ga(CH₃)₃), TMA (Al(CH₃)₃), and NH₃ at 1,100° C., for example. In this step, an AlᵤGaᵥIn_{w}N layer (u≧0, v≧0, w≧0) may be formed as the n-type conductive layer 2, instead of the GaN layer. Note that, another substrate instead of the n-type GaN substrate may be used.

Then, the active layer 3 is formed on the n-type conductive layer 2. The active layer 3 has a 81 nm thick GaInN/GaN multi-quantum well (MQW) structure which is realized by, for example, alternately stacking 9 nm thick Ga_{0.9}In_{0.1}N well layers and 9 nm thick GaN barrier layers. In forming the Ga_{0.9}In_{0.1}N well layers, the growth temperature may be decrease to 800° C. in order to enhance incorporation of In.

Next, on the active layer 3, the 70 nm thick p-type conductive layer 4 of GaN is formed by supplying TMG, TMA, NH₃, and Cp₂Mg (cyclopentadienyl magnesium) as the p-type impurities. The p-type conductive layer 4 may have a p-GaN contact layer (not shown) at the surface. As the p-type conductive layer 4, for example, a p-AlGaN layer may be formed instead of the GaN layer.

After the end of the above-mentioned epitaxial growth step by means of MOCVD, chlorine dry etching is performed to partially remove the p-type conductive layer 4 and the active layer 3 so that the recessed portion 20 is formed, and hence the second region 2b of the n-type conductive layer 2 is exposed.

Then, the through hole 8 is formed using a dry etching process, for example. Specifically, a resist mask is formed over the p-type conductive layer 4 and the principal surface 2d of the n-type conductive layer 2, and thereafter, an opening is formed in part of the resist mask which is assigned for formation of the through hole 8. By performing dry etching using the resultant resist mask, a hole can be formed through the n-type conductive layer 2 and the n-type GaN substrate, which serves as the through hole 8. In this case, the dry etching is stopped before the hole penetrates through the n-type GaN substrate. As illustrated in FIG. 28B, the through hole 8 is formed so as to have a square shape when seen in the direction perpendicular to the principal surface 2d of the n-type conductive layer 2. The dimensions of the through hole 8 (the dimensions in a plane which is parallel to the principal surface) may be 100 μm×100 μm, for example. The corners of the through hole 8 may be round.

Next, by vapor deposition or sputtering, an Al layer having a thickness of 100 nm is formed on the insulating film 15 along the inner wall and the bottom surface of the above-mentioned hole which is to become the through hole 8, and another Al layer is formed thereon by plating. In this way, the conductor portion 9 composed of an Al layer is formed. In order to prevent the disconnection of the conductor portion 9, it is desired that the dimensions of the through hole 8 in a plane which is parallel to the principal surface be set to be equal to or larger than the dimensions of the through hole 8 in a plane perpendicular thereto.

Then, on the second region 2b of the n-type conductive layer 2, the n-type front surface electrode 6 is formed by, for example, a 10 nm thick Ti layer and a 100 nm thick Al layer. The n-type front surface electrode 6 is formed so as to be in contact with the conductor portion 9. On the other hand, on the principal surface 4a of the p-type conductive layer 4, the p-electrode 5 is formed by, for example, a 7 nm thick Pd layer and a 70 nm thick Pt layer.

Next, by polishing or etching, the n-type substrate 1 is removed so as to expose the Al film formed on the bottom surface of the above-mentioned hole which is to become the through hole 8. After that, by vapor deposition or the like, the n-type rear surface electrode 7 made of a transparent material, such as ITO, is formed on the rear surface 2c of the n-type conductive layer 2.

After that, heat treatment may be performed at a temperature of about 50° C. to 650° C. for about 5 minutes to 20 minutes. The heat treatment can decrease the contact resistance between the n-type conductive layer 2 and the n-type front surface electrode 6, between the n-type conductive layer 2 and the n-type rear surface electrode 7, and between the n-type conductive layer 2 and the conductor portion 9.

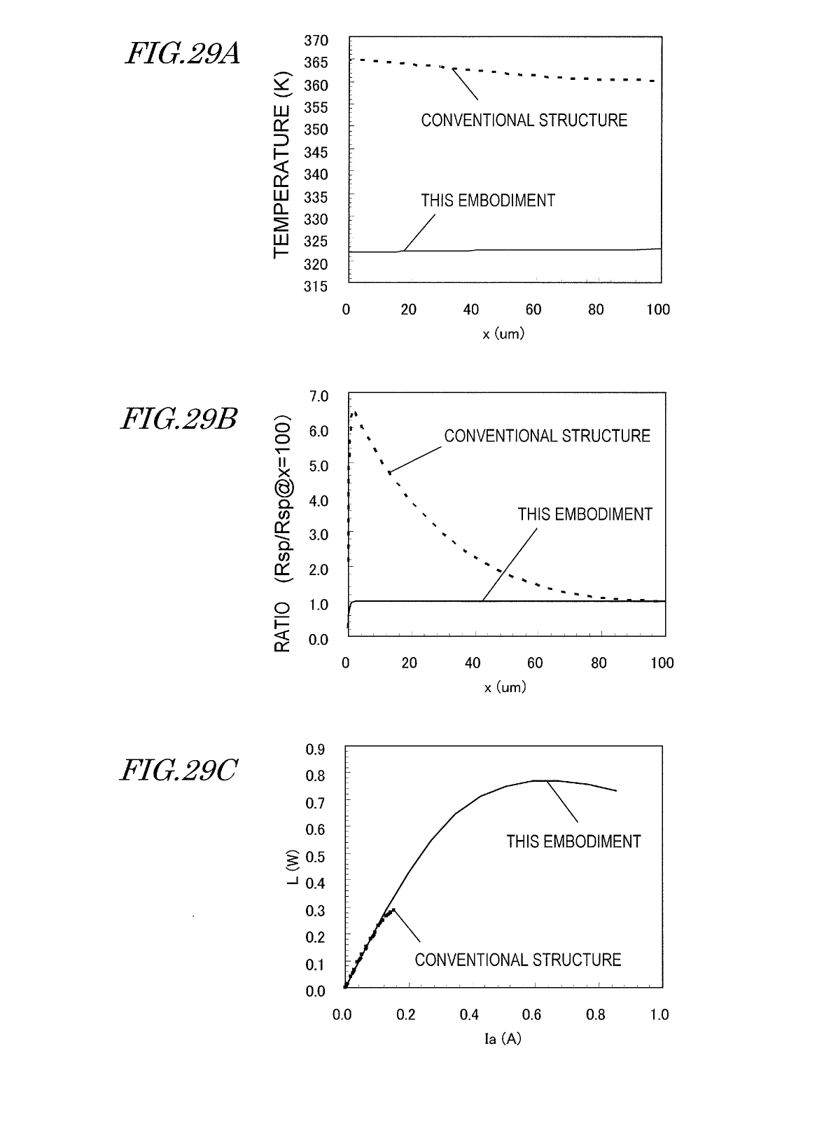

FIGS. 29A and 29B are graphs showing a temperature distribution and a light emission rate, respectively, in the active layer 3 along the A-A′ cross section of the light-emitting diode device 51A illustrated in FIG. 28. FIG. 29C is a graph showing an electric current dependence of a light output of the light-emitting diode device 51A illustrated in FIG. 28. FIGS. 29A to 29C each show the results calculated by a simulation assuming the light-emitting diode device 51A having a c-plane principal surface. The simulation was performed assuming an element having an anode electrode width of 100 μm. The horizontal axis of the graphs of FIGS. 29A and 29B represents the position, provided that a terminal of the anode electrode on the A′ side is x=0 μm and a terminal of the anode electrode on the A side is x=100 μm. The vertical axis of FIG. 29C represents a value of the ratio, provided that the light emission rate for x=100 μm is 1. FIGS. 29A to 29C show the simulation results of the conventional light-emitting diode element 114 illustrated in FIG. 5 for comparison. FIGS. 29A and 29B show the results obtained by setting the electric current value of the conventional light-emitting diode element 114 illustrated in FIG. 5 and the electric current value of the light-emitting diode element 50A illustrated in FIG. 29 to be the same value of 0.13 A. The result shown in FIG. 29C was obtained by applying the same bias to the conventional light-emitting diode element 114 illustrated in FIG. 5 and the light-emitting diode element 50A illustrated in FIG. 28.

As shown in FIG. 29A, the conventional front-surface electrode structure has a temperature of around 365 K as a whole, peaking at the vicinity of the n-type front surface electrode 6. On the other hand, it is understood that a uniform temperature of about 322 K is obtained as a whole in this embodiment. This is because the heat releasability is high and the temperature is less likely to increase in this embodiment as compared with the conventional case.

As shown in FIG. 29B, in the conventional case, the light emission rate is decreased, peaking at the anode electrode terminal on the A′ side. In the conventional structure illustrated in FIG. 5A, the p-electrode 105 and the n-type front surface electrode 106 are both positioned on the principal surface side, and hence an electric current flows through the n-type conductive layer 102 along the x-axis direction. It is considered that, due to the resistance of the n-type conductive layer 102, an electric current is less likely to flow through the active layer 103 positioned far from the n-type front surface electrode 106, and only the region of the active layer 103 close to the n-type front surface electrode 106 emits strong light.

In this embodiment, on the other hand, an approximately uniform light emission rate is obtained. The reason is considered that an electric current flows from the p-electrode 5 toward the n-type rear surface electrode 7 along the y-axis direction approximately uniformly in this embodiment.

Further, as shown in FIG. 29C, it is understood that, in the conventional structure, the output starts decreasing from the point at which an anode electric current value Ia becomes 0.1 A or more, but, in the structure of this embodiment, a large amount of electric current flows with the same bias and a sufficiency light output is obtained.

According to this embodiment, the conductor portion 9 and the n-type rear surface electrode 7 are provided, and hence an electric current can be allowed to flow uniformly from the p-electrode 5 to the n-type rear surface electrode 7. As compared with the conventional front-surface electrode type light-emitting diode (FIG. 5), the concentration of electric current on the vicinity of the cathode is alleviated, and hence a uniform light emission rate can be obtained.

Further, local heat generation is less likely to occur because an electric current can be allowed to flow uniformly from the p-electrode 5 to the n-type rear surface electrode 7. In addition, the thermal conductivities of the conductor portion 9 and the n-type rear surface electrode 7 are high, and hence the release of heat is more likely to proceed as a whole. This suppresses the increase in temperature of the active layer 3, thus suppressing the decrease in light emission efficiency and internal quantum efficiency.

In this embodiment, the conductor portion 9 is provided on the inner wall of the through hole 8, and hence an electrical contact can be established between the inner wall of the through hole 8 and the conductor portion 9. In this case, a larger electric current can be allowed to flow, and hence a stronger light emission can be obtained.

In general, the adhesion between a GaN-based compound semiconductor layer and metal is poor. According to this embodiment, the n-type front surface electrode 6 is provided so as to cover the conductor portion 9, and hence the adhesion can be enhanced as compared with the case of forming the n-type front surface electrode 6 on the n-type conductive layer 2 (FIG. 5). This prevents the electrode from being easily peeled off. This is effective for defects of electrode peeling in the case of, for example, flip-chip mounting in which the bump 11 is brought into contact with the n-type front surface electrode 6.

According to this embodiment, the mounting base 12 and the n-type rear surface electrode 7 can be connected to each other without using wire bonding. Thus, unlike the conventional opposite-surface electrode type, there is no problem such as the disconnection of wire bonding, and hence high reliability can be ensured.

### Embodiment 10

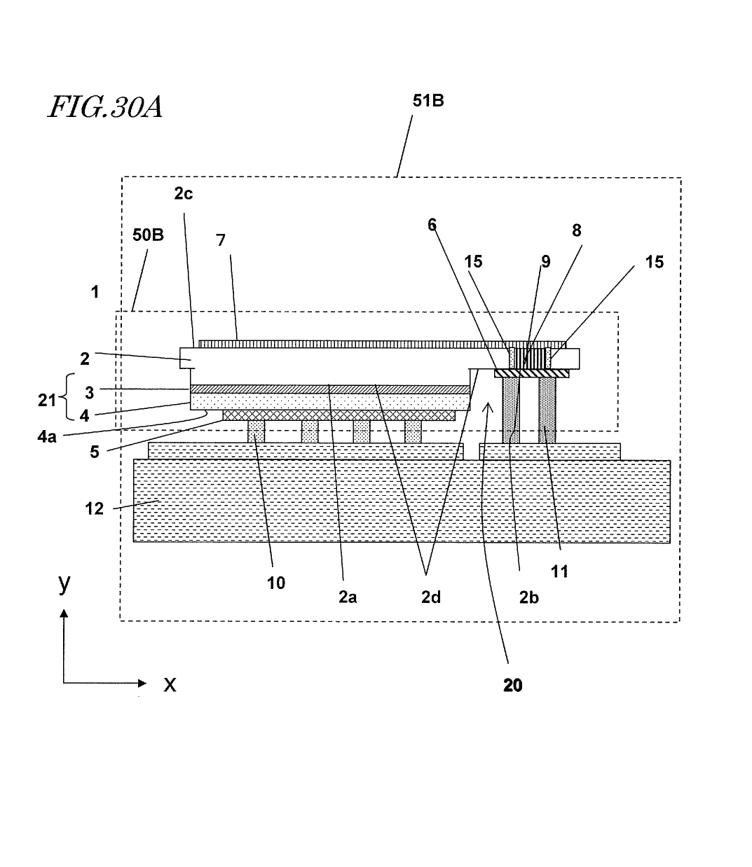

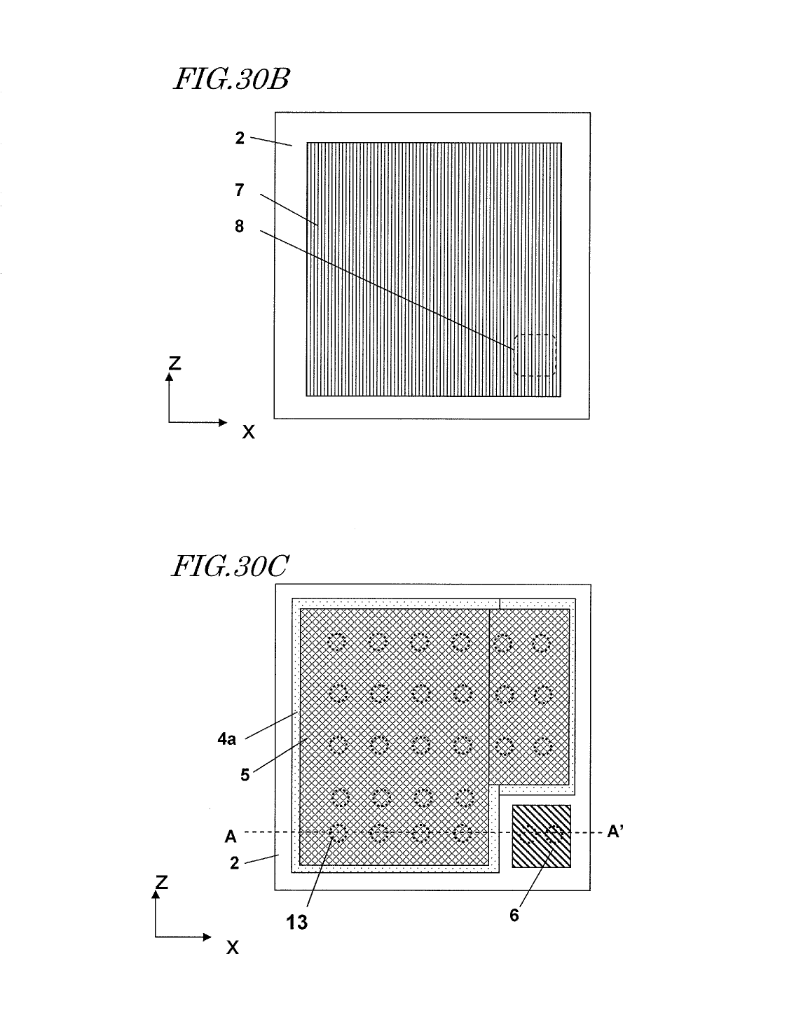

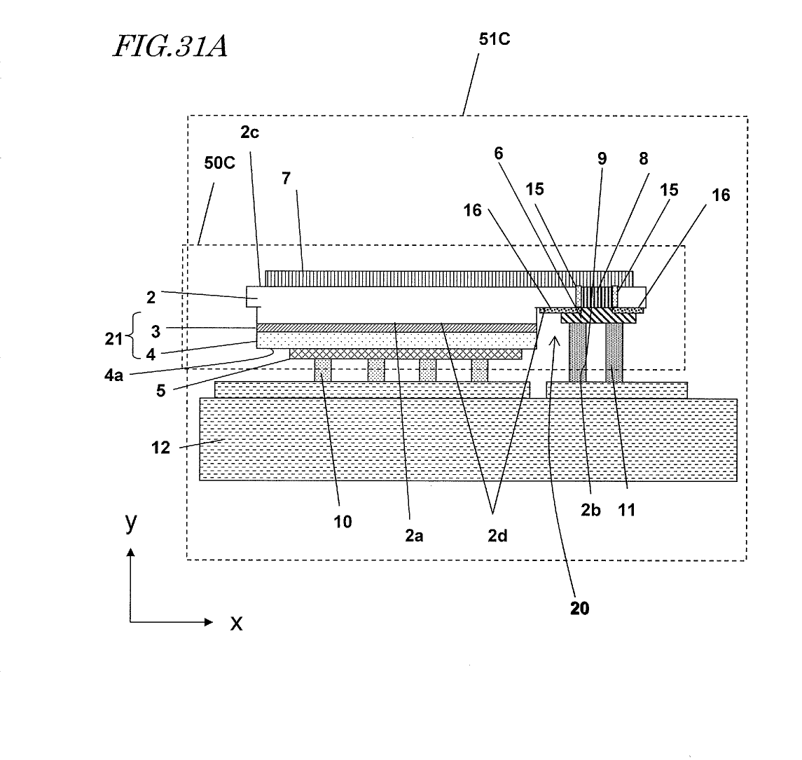

FIG. 30A is a cross-sectional view illustrating a light-emitting diode device 51B of Embodiment 10. FIG. 30B is a plan view illustrating a rear surface of a light-emitting diode element 50B illustrated in FIG. 30A. FIG. 30C is a plan view illustrating a principal surface of the light-emitting diode element 50B illustrated in FIG. 30A. In FIGS. 30A to 30C, the same components as those in FIGS. 29A to 29C are denoted by the same reference symbols.

As illustrated in FIG. 30A, in this embodiment, the insulating film 15 is provided between the conductor portion 9 and the n-type conductive layer 2 constituting the inner wall of the through hole 8. The insulating film 15 is composed of a SiO₂ film, for example.

In the case of using a SiO₂ film as the insulating film 15, after a recessed portion to become the through hole 8 is formed, a SiO₂ film is formed by CVD along the inner wall and the bottom surface of the through hole 8 so as to have a thickness of 100 nm to 1 μm. Subsequently, by vapor deposition or sputtering, an Al layer having a thickness of 100 nm is formed on the insulating film 15, and another Al layer is formed thereon by plating. In this way, the conductor portion 9 composed of an Al layer is formed. The insulating film 15 is formed also on the bottom surface of the recessed portion which is to become the through hole 8. When the substrate is removed and the through hole 8 is formed from the recessed portion, the insulating film 15 formed on the bottom surface of the recessed portion is also removed simultaneously.

The insulating film 15 may not cover the entire inner wall of the through hole 8. However, in order to insulate the n-type conductive layer 2 constituting the inner wall of the through hole 8 from the conductor portion 9, The insulating film 15 may be a continuous film which is uniform to some extent. The thickness of the insulating film 15 may be 100 nm or more and 1 μm or less. When the thickness of the insulating film 15 is 100 nm or more, the n-type conductive layer 2 and the conductor portion 9 can be reliably insulated from each other. Further, when the thickness of the insulating film 15 is 1 μm or less, a stress to be generated can be suppressed in an allowable range. The material of the insulating film 15 may be other than a silicon oxide film, and, for example, silicone, a silicon nitride film, or aluminum nitride (AlN) can be used. In the case of using silicone as the insulating film 15, silicone can be formed by application with the use of a spinner. A silicon nitride film can be formed by CVD or the like. Aluminum nitride can be formed by sputtering or the like. Aluminum nitride has an advantage of high affinity for a GaN layer constituting the n-type conductive layer 2 and aluminum constituting the conductor portion 9 and an advantage of high thermal conductivity.

This embodiment has the same configurations as those in Embodiment 9 except for the insulating film 15. The description of the same configurations is omitted. The description of the same effects as those in Embodiment 9 among the effects obtained in this embodiment is also omitted.

In this embodiment, the insulating film 15 is provided between the through hole 8 and the conductor portion 9, and hence an electric current can be prevented from flowing from the n-type conductive layer 2 to the conductor portion 9. Therefore, almost all electric currents flow from the p-electrode 5 to the n-type rear surface electrode 7, resulting in more uniform electric current density in the active layer 3. In the case where the distance between the conductor portion 9 and the p-electrode 5 is short, a larger electric current flows from the n-type conductive layer 2 to the conductor portion 9, and hence the effect of preventing the flow of electric current becomes larger. In the case where a metal of the conductor portion 9 is brought into direct contact with the inner wall of the through hole 8, it is sometimes difficult to form an ohmic contact having a uniform contact resistance. Therefore, the use of the configuration of this embodiment enables the manufacture of light-emitting diodes at good yields while suppressing fluctuations in characteristics.

The coefficients of linear expansion of GaN and Al are 3 to 6×10⁻⁶/K and 23×10⁻⁶/K, respectively. When heat is generated under high-power operation, the conductor portion 9 expands so that a strong stress is applied to a portion of the n-type conductive layer 2 which is positioned in the vicinity of the through hole 8, and hence cracks or peeling-off easily occur. In this embodiment, the insulating film 15 is provided between the n-type conductive layer 2, in which the through hole 8 is to be provided, and the conductor portion 9, and hence cracks or peeling-off can be prevented. For example, in the case where an insulating film composed of a SiO₂ film is provided, the SiO₂ film is less likely to expand because the coefficient of linear expansion is as small as 0.5×10⁻⁶/K. Further, the SiO₂ film has a coefficient of elasticity of 8 GPa, which is smaller than 300 GPa of GaN and 70 GaP of Al. Therefore, the SiO₂ film functions as a buffer layer.

### Embodiment 11

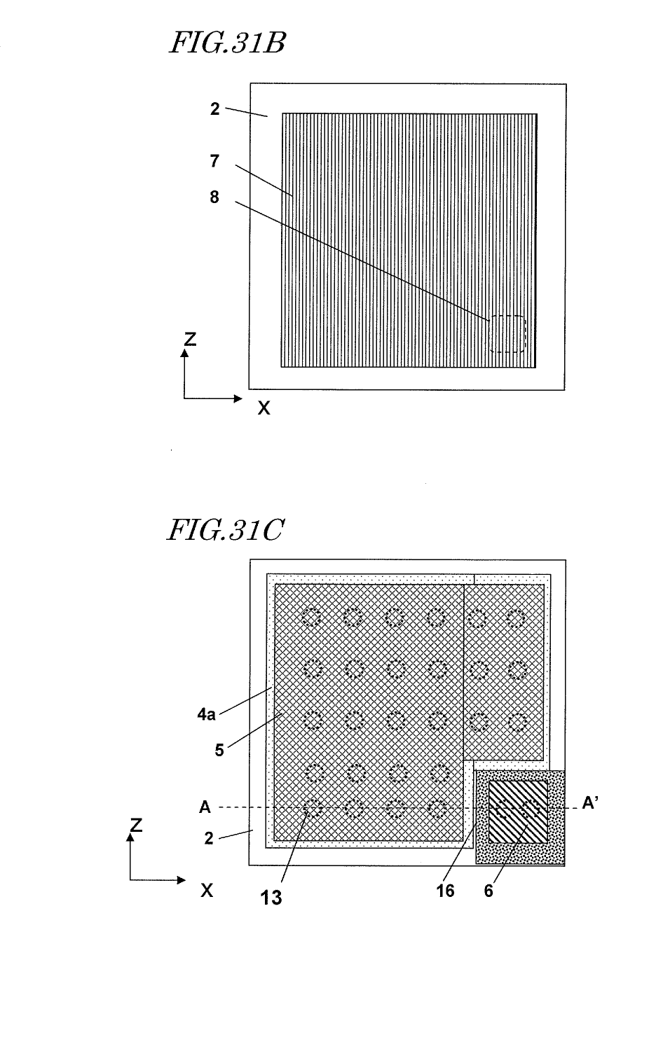

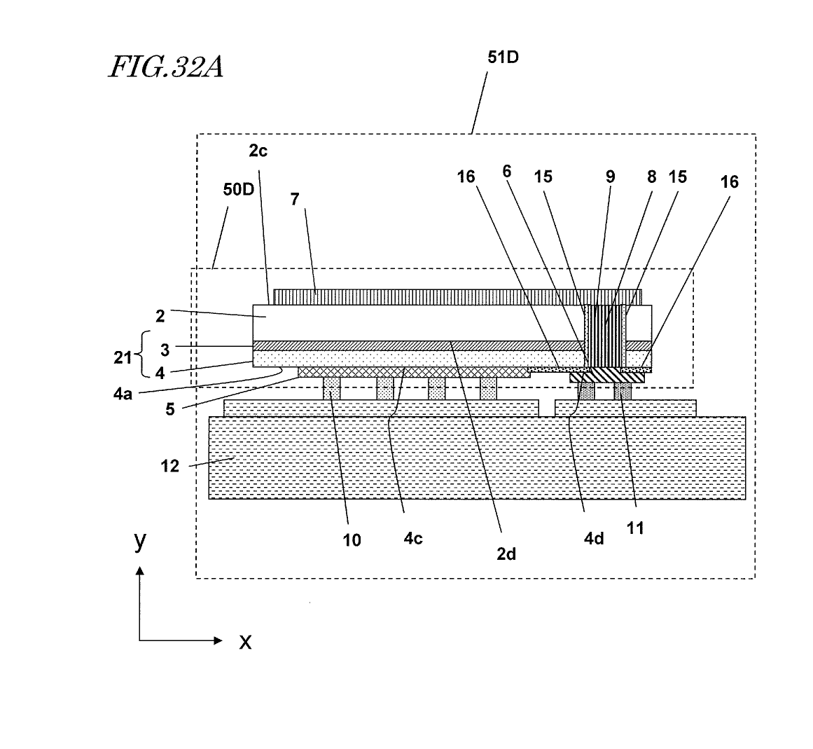

FIG. 31A is a cross-sectional view illustrating a light-emitting diode device 51C of Embodiment 11. FIG. 28B is a plan view illustrating a rear surface of a light-emitting diode element 50C illustrated in FIG. 31A. FIG. 31C is a plan view illustrating a principal surface of the light-emitting diode element 50C illustrated in FIG. 31A. In FIGS. 31A to 31C, the same components as those in FIGS. 30A to 30C are denoted by the same reference symbols.

As illustrated in FIG. 31A, in this embodiment, the insulating film 16 is provided in the second region 2b of the principal surface 2d of the n-type conductive layer 2 (at a portion of the n-type conductive layer 2 which is positioned around the through hole 8). The n-type front surface electrode 6 is disposed, through the intermediation of the insulating film 16, on the second region 2b of the principal surface 2d of the n-type conductive layer 2. The insulating film 16 may be made of the same material as that of the insulating film 15, and may be made of a different material. The thickness of the insulating film 16 may be 100 nm or more and 500 nm or less.

In the case where the insulating film 15 and the insulating film 16 are made of the same material, the insulating film 16 may be formed in the same step of forming the insulating film 15 that covers the inner surface of the through hole 8. For example, after the through hole 8 is formed, CVD for forming a silicon oxide film is performed. Then, the insulating films 15 and 16 each composed of a silicon oxide film are formed in the second region 2b of the n-type conductive layer 2 and on the inner wall of the through hole 8. The insulating film may be left in a region of the principal surface 4a of the p-type conductive layer 4 other than the region in which the p-electrode 5 is to be formed.

This embodiment has the same configurations as those in Embodiment 10 except for the arrangement of the insulating film 16 and the n-type front surface electrode 6. The description of the same configurations is herein omitted. The description of the same effects as those in Embodiment 10 among the effects obtained in this embodiment is also omitted.

In Embodiment 9, an electric current flows from the p-electrode 5 toward the n-type front surface electrode 6. In order to ensure a large area of the active layer 3, it is desired to reduce the area of the second region 2b as much as possible. If the p-electrode 5 and the n-type front surface electrode 6 are formed so as to have a small distance therebetween, an electric current component between the two electrodes increases to enhance a light emission output as a whole, but a region of the active layer 3 near the n-type front surface electrode 6 has strong light emission intensity, resulting in a non-uniform light emission distribution. In this embodiment, the insulating film 16 is provided between the n-type conductive layer 2 and the n-type front surface electrode 6, and hence no electric current flows from the n-type conductive layer 2 to the n-type front surface electrode 6. Therefore, all electric currents flow from the p-electrode 5 to the n-type rear surface electrode 7 so that the electric current density becomes more uniform, and hence a more uniform light emission distribution is obtained. The effect of making the light emission distribution more uniform obtained by providing the insulating film 16 is particularly large in the case where the n-type front surface electrode 6 is formed near the p-electrode 5. This embodiment is particularly suitable to the use which places a higher priority on the uniformity in light emission distribution than the light emission intensity.

The n-type front surface electrode 6 is provided on the insulating film 16 and the conductor portion 9. The insulating film 16 has higher adhesion with respect to the n-type front surface electrode 6 than that of the n-type conductive layer 2, and hence the n-type front surface electrode 6 is less easily peeled off in this embodiment. In general, the formation of bumps in flip-chip mounting has a problem that an electrode is peeled off and other such problems, but this embodiment can overcome the problem.

Note that, in this embodiment, the structure having the insulating film 15 between the conductor portion 9 and the n-type conductive layer 2 has been exemplified, but the effects can be obtained also in the structure without the insulating film 15.

### Embodiment 12

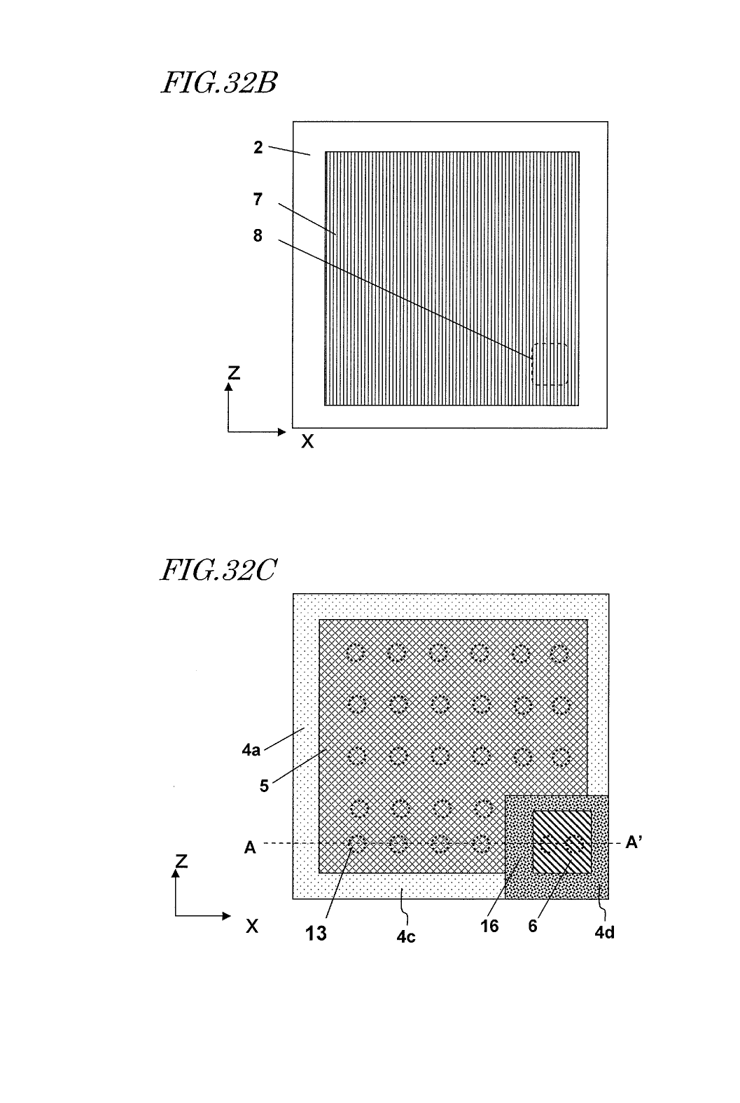

FIG. 32A is a cross-sectional view illustrating a light-emitting diode device 51D of Embodiment 12. FIG. 32B is a plan view illustrating a rear surface of a light-emitting diode element 50D illustrated in FIG. 32A. FIG. 32C is a plan view illustrating a principal surface of the light-emitting diode element 50D illustrated in FIG. 32A. In FIGS. 32A to 32C, the same components as those in FIGS. 31A to 31C are denoted by the same reference symbols.

As illustrated in FIG. 32A, the recessed portion 20 (illustrated in FIG. 31A etc.) is not provided in this embodiment. The through hole 8 penetrates through not only the n-type conductive layer 2 but also the active layer 3 and the p-type conductive layer 4.

The insulating film 15 is provided on the inner walls of the n-type conductive layer 2, the active layer 3, and the p-type conductive layer 4, which constitute the inner wall of the through hole 8. Further, the conductor portion 9 is embedded in the through hole 8 on the inner side of the insulating film 15.

The insulating film 16 is provided on the principal surface of the p-type conductive layer 4 in a region (second region 4d) surrounding the circumference of the through hole 8. On the other hand, the p-electrode 5 is provided in a first region 4c of the principal surface of the p-type conductive layer 4. As illustrated in FIG. 32C, the second region 4d is a region disposed at one corner of the square principal surface of the p-type conductive layer 4, and the first region 4c is a region of the principal surface of the p-type conductive layer 4 other than the second region 4d.

The n-type front surface electrode 6 is provided from a region on the conductor portion 9 exposed on the surface of the p-type conductive layer 4 on the principal surface side to a region on the insulating film 16 surrounding the circumference of the conductor portion 9. With the insulating films 15 and 16 provided, the n-type front surface electrode 6 and the conductor portion 9 are electrically insulated from the active layer 3 and the p-type conductive layer 4.

In this embodiment, the description of the same configurations as those in Embodiment 11 is omitted. The description of the same effects as those in Embodiment 11 among the effects obtained in this embodiment is also omitted.

According to this embodiment, the n-type front surface electrode 6 and the conductor portion 9 can be electrically insulated from the active layer 3 and the p-type conductive layer 4 by the insulating films 15 and 16, and hence it is unnecessary to form the recessed portion 20 (illustrated in FIG. 31A etc.). The process can therefore be simplified.

Further, the surface on the mounting side (principal surface of the light-emitting diode element 50D) becomes flat so as to eliminate a step, and hence, in the case of flip-chip mounting, bumps having the same height can be used for both of the n-type front surface electrode 6 and the p-electrode 5, thus simplifying the mounting.

Defects in shape and electric field concentration at a step portion can also be prevented, which eliminates defects caused by leakage electric current or breakage generated at the step portion, thus improving reliability and yields.

### Embodiment 13

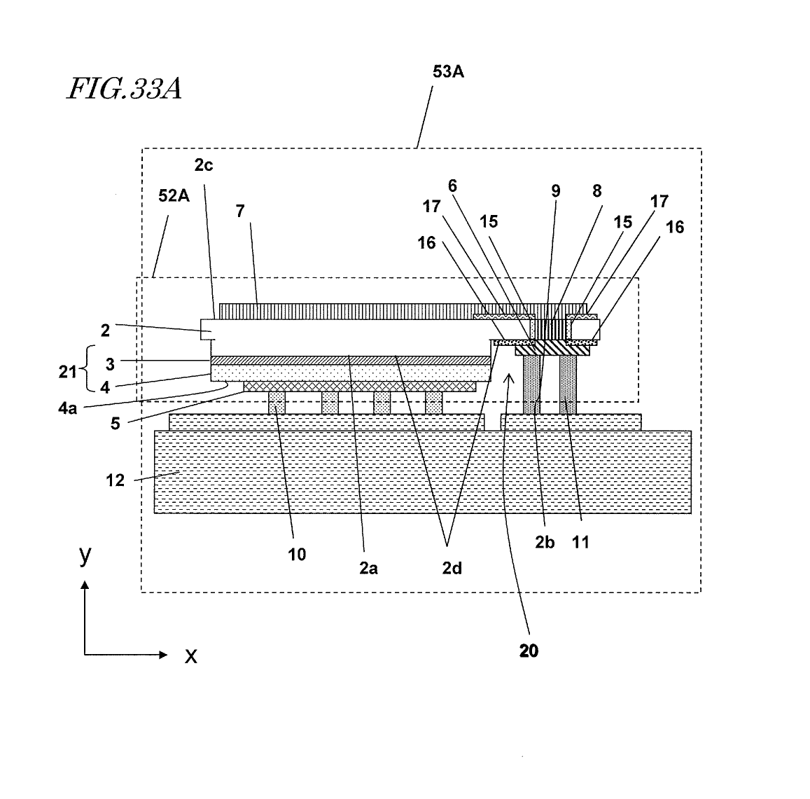

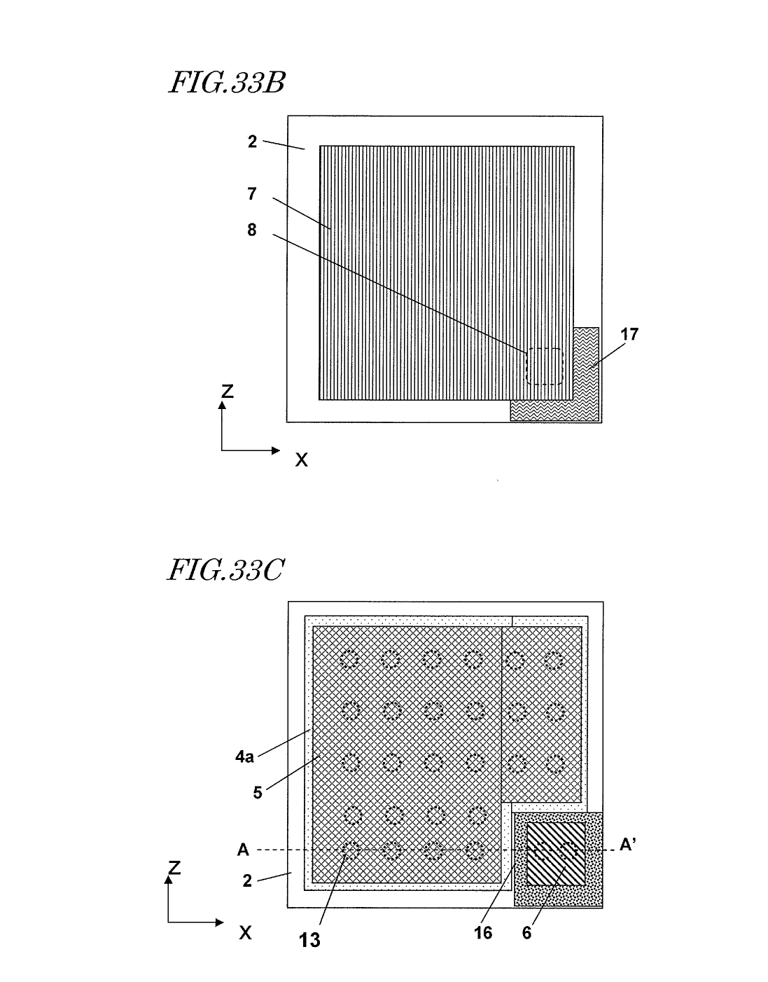

Next, a light-emitting diode device according to Embodiment 13 of the present invention is described with reference to FIGS. 33A to 35. In this embodiment, an insulating film is also provided on the rear surface side of the light-emitting diode element.

FIG. 33A is a cross-sectional view illustrating a first light-emitting diode device 53A of Embodiment 13. The first light-emitting diode device 53A is a modified example of the light-emitting diode device 51C of Embodiment 11. FIG. 33B is a plan view illustrating a rear surface of a light-emitting diode element 52A illustrated in FIG. 33A. FIG. 33C is a plan view illustrating a principal surface of the light-emitting diode element 52A illustrated in FIG. 33A. In FIGS. 33A to 33C, the same components as those in FIGS. 31A to 31C are denoted by the same reference symbols.

As illustrated in FIG. 33, in the light-emitting diode element 52A of this embodiment, the insulating film 17 is provided on the rear surface 2c of the n-type conductive layer 2. The insulating film 17 is provided on the rear surface 2c of the n-type conductive layer 2 at a portion positioned in the vicinity of the through hole 8 (portion opposing the insulating film 16).

The n-type rear surface electrode 7 is provided on the rear surface 2c of the n-type conductive layer 2. The n-type rear surface electrode 7 is provided on the rear surface side of the insulating film 17 at a portion of the rear surface 2c of the n-type conductive layer 2 on which the insulating film 17 is provided. The n-type rear surface electrode 7 is provided to be in direct contact with the n-type conductive layer 2 at a portion of the rear surface 2c of the n-type conductive layer 2 on which the insulating film 17 is not provided. The n-type rear surface electrode 7 is in contact with the conductor portion 9 provided inside the through hole 8.

The insulating film 17 may be made of the same material as that of the insulating film 15, and may be made of a different material. The thickness of the insulating film 16 may be 100 nm or more and 500 nm or less. The insulating film 17 can be formed by performing CVD or the like for forming a silicon oxide film on the rear surface 2c side of the n-type conductive layer 2 after the formation of the through hole 8. After that, the n-type rear surface electrode 7 is provided on the rear surface side of the insulating film 17 and on an exposed portion of the rear surface 2c of the n-type conductive layer 2.

The insulating film may be left in a region of the principal surface of the p-type conductive layer 4 other than the region in which the p-electrode 5 is to be formed.

Other configurations of the first light-emitting diode device 53A are the same as those of the light-emitting diode device 51C illustrated in FIGS. 31A to 31C.

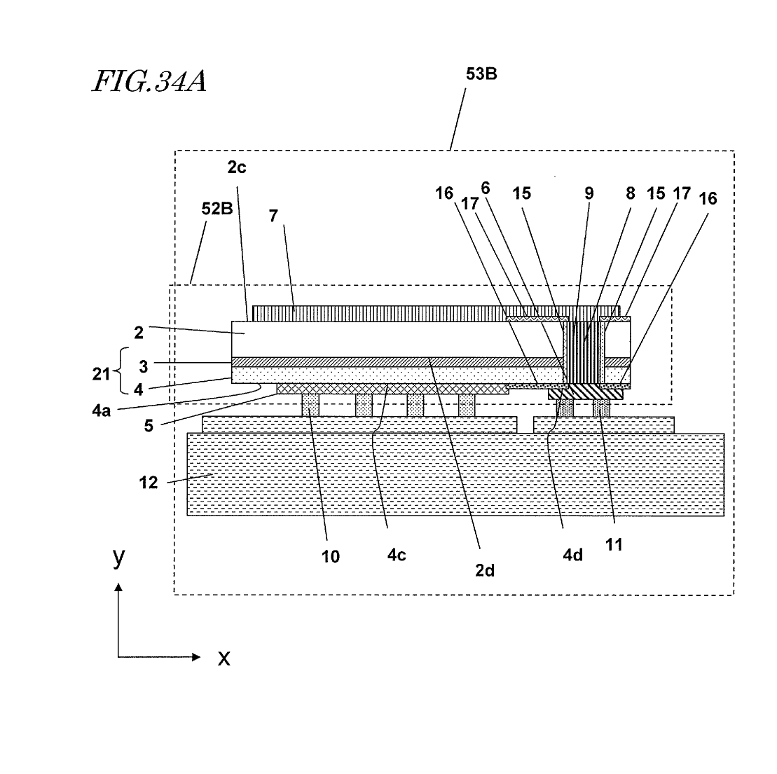

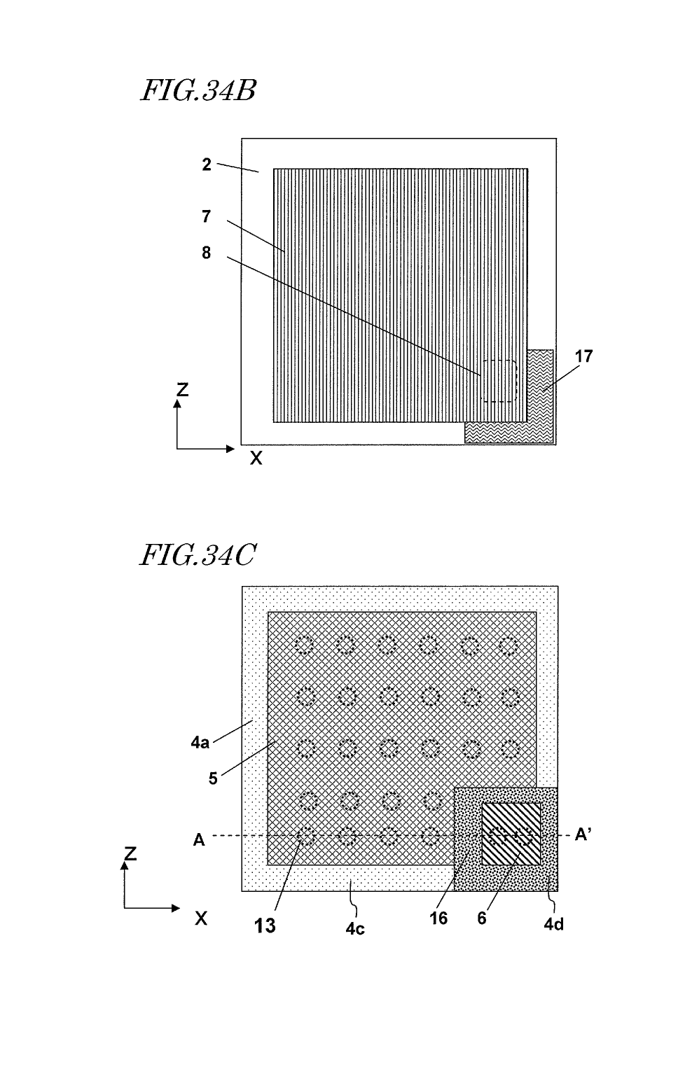

FIG. 34A is a cross-sectional view illustrating a second light-emitting diode device 53B of Embodiment 13. The second light-emitting diode device 53B is a modified example of the light-emitting diode device 51D of Embodiment 12. FIG. 34B is a plan view illustrating a rear surface of a light-emitting diode element 52B illustrated in FIG. 34A. FIG. 34C is a plan view illustrating a principal surface of the light-emitting diode element 52B illustrated in FIG. 34A. In FIGS. 34A to 34C, the same components as those in FIGS. 32A to 32C are denoted by the same reference symbols.

As illustrated in FIG. 34, in the light-emitting diode element 52B of this embodiment, the insulating film 17 is provided on the rear surface 2c of the n-type conductive layer 2. The insulating film 17 is provided on the rear surface 2c of the n-type conductive layer 2 at a portion positioned in the vicinity of the through hole 8 (portion opposing the insulating film 16).

The n-type rear surface electrode 7 is provided on the rear surface 2c of the n-type conductive layer 2. The n-type rear surface electrode 7 is provided on the rear surface side of the insulating film 17 at a portion of the rear surface 2c of the n-type conductive layer 2 on which the insulating film 17 is provided. The n-type rear surface electrode 7 is provided to be in direct contact with the n-type conductive layer 2 at a portion of the rear surface 2c of the n-type conductive layer 2 on which the insulating film 17 is not provided. The n-type rear surface electrode 7 is in contact with the conductor portion 9 provided inside the through hole 8.

Other configurations of the second light-emitting diode device 53B are the same as those of the light-emitting diode device 51D illustrated in FIGS. 32A to 32C.

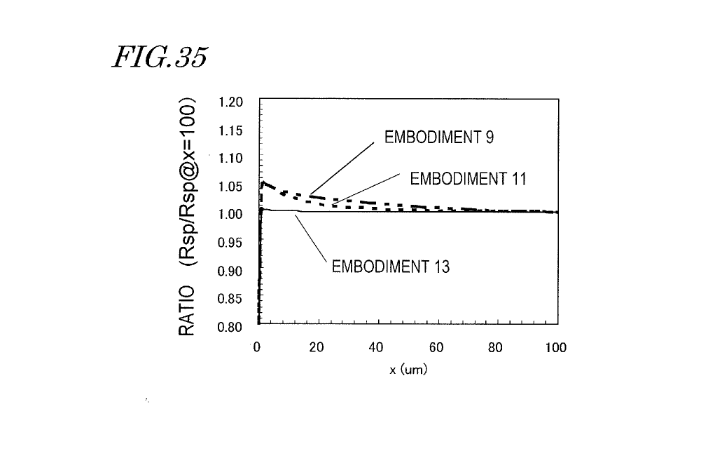

FIG. 35 is a graph showing simulation results of a light emission rate of the second light-emitting diode device 53B illustrated in FIG. 33. The graph of FIG. 35 shows the light emission rate of the active layer 3 along the A-A′ cross section in FIG. 33C. The simulation was performed assuming an element having an anode electrode width of 100 μm. The horizontal axis of the graph of FIG. 35 represents the position, provided that a terminal of the anode electrode on the A′ side is x=0 μm and a terminal of the anode electrode on the A side is x=100 μm. The vertical axis represents a value of the ratio, provided that the light emission rate for x=100 is 1. For comparison, FIG. 35 shows the simulation results of Embodiment 9 (illustrated in FIG. 28) and Embodiment 11 (illustrated in FIG. 31). Comparison was made on the distributions in light emission rate at an electric current of 0.8 A under the assumption of the element having a c-plane principal surface as each of the structure of this embodiment and the structures of Embodiments 9 and 11. The element of this embodiment has the structure which is more flexible to high power than that in Embodiment 1, and hence the simulation of FIG. 35 was carried out under the operation condition of supplying a larger electric current than that in the simulation of FIG. 29B. As a result, the light emission rate of Embodiment 9 is almost uniform in FIG. 29B, for example, but the light emission rate of Embodiment 9 in FIG. 35 becomes smaller as the x value becomes larger.

It is found from the results shown in FIG. 35 that, according to this embodiment, the light emission rate in the vicinity of the through hole 8 is decreased so as to obtain uniform light emission. More uniform light emission is obtained in the structure of Embodiment 11 (illustrated in FIG. 31) than in the structure of Embodiment 9 (illustrated in FIG. 28), and more uniform light emission is obtained in the structure of Embodiment 13 (illustrated in FIG. 33) than in the structure of Embodiment 11 (illustrated in FIG. 31).

According to the first and second light-emitting diode devices 53A and 53B of this embodiment, the same effects as those in Embodiments 11 and 12 can be obtained, respectively.

In addition, according to this embodiment, the insulating film 17 is provided, and hence the portion of the n-type rear surface electrode 7 which is positioned in the vicinity of the through hole 8 can be prevented from being brought into contact with the n-type conductive layer 2. This suppresses the increase in light emission intensity in the vicinity of the through hole 8, thus obtaining a uniform light emission pattern. This effect is particularly large in the case of the thickness of the n-type conductive layer 2 having a small value such as 5 μm because the amount of electric current flowing to the n-type rear surface electrode 7 side is large.

Note that, this embodiment is a modified example of Embodiments 11 and 12, but the insulating film 17 may be provided in the structures of Embodiments 9 and 10.

### Embodiment 14

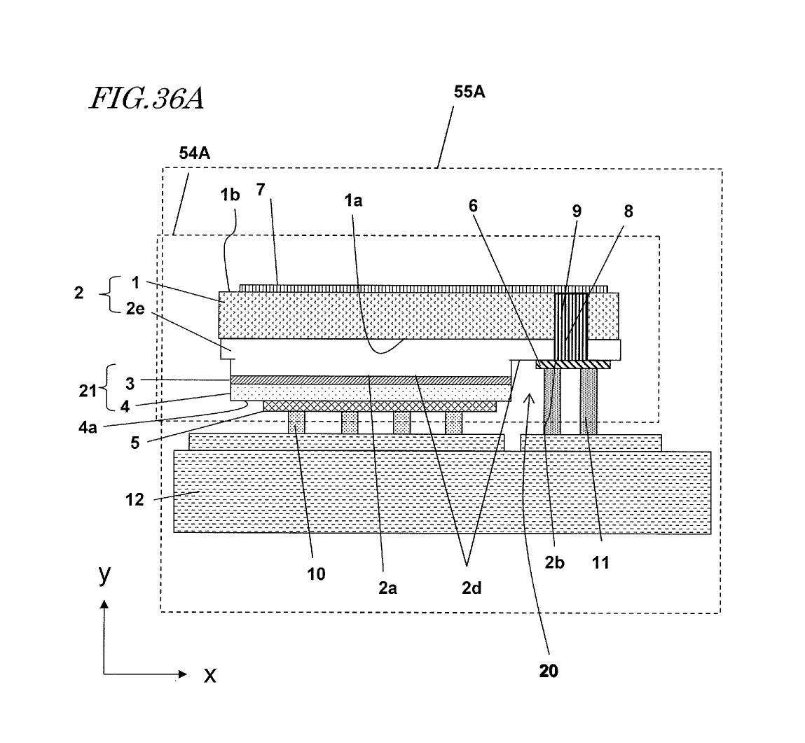

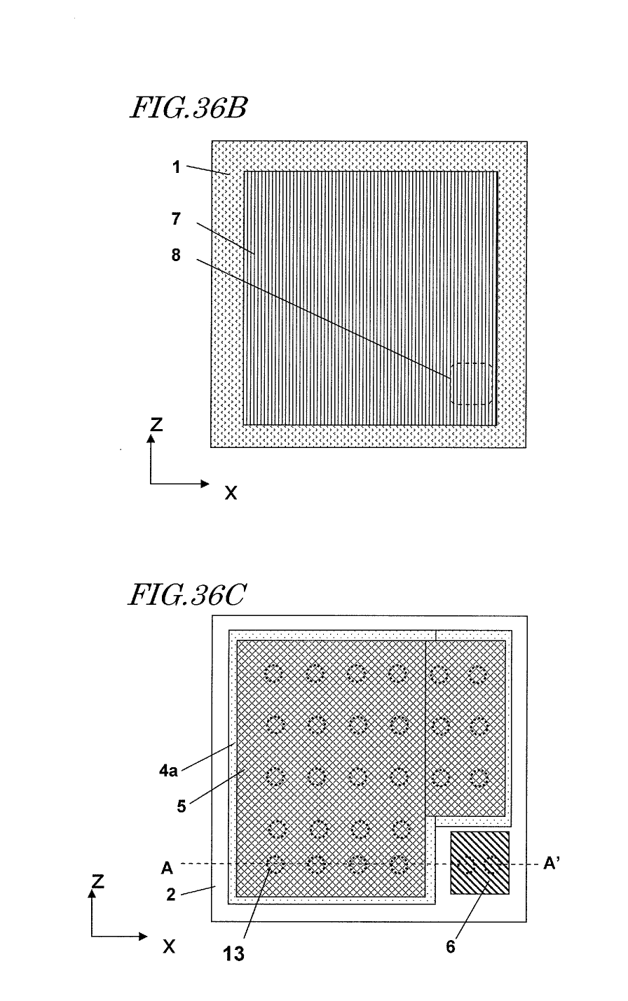

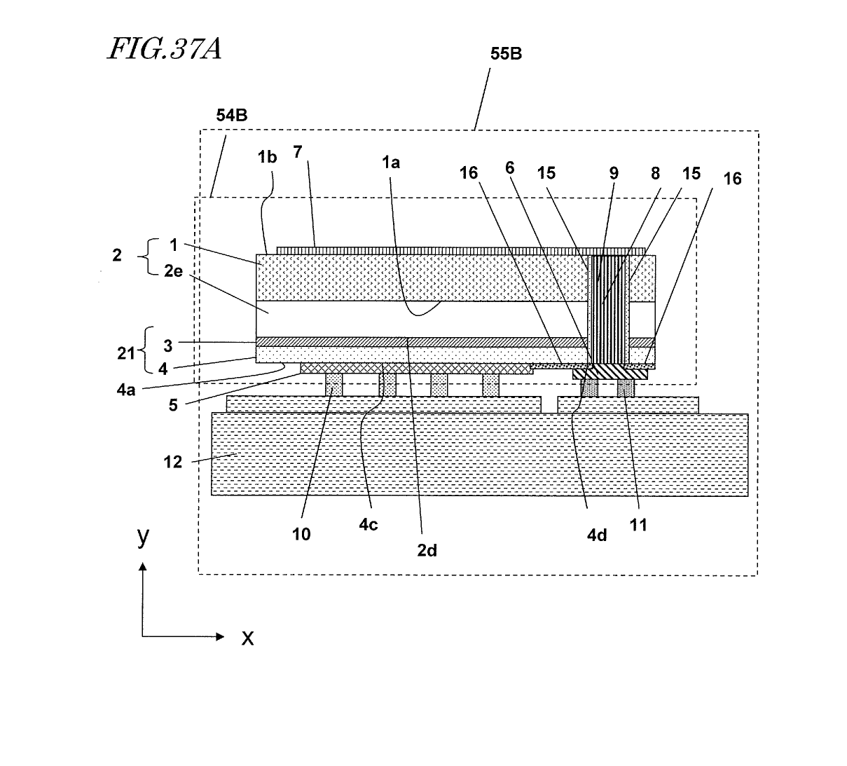

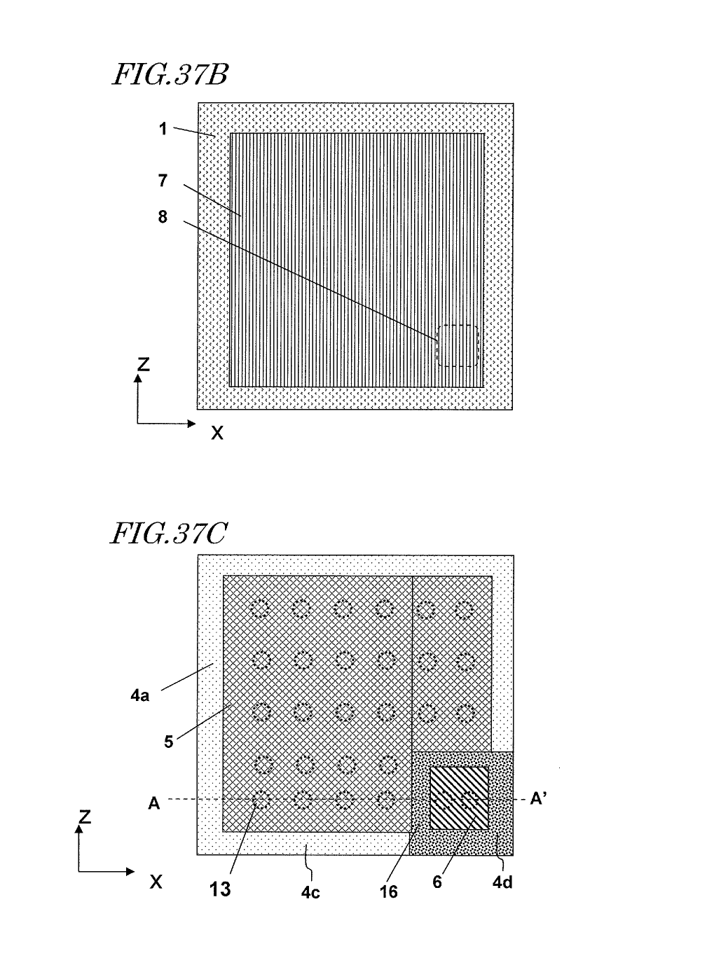

Next, a light-emitting diode device according to Embodiment 14 of the present invention is described with reference to FIGS. 36A to 37C. In this embodiment, after the n-type semiconductor layer 2e is formed on the n-type substrate 1, the substrate is not entirely removed but (a part or whole of) the substrate is left so as to form the n-type conductive layer 2.

FIG. 36A is a cross-sectional view illustrating a first light-emitting diode device 55A of Embodiment 14. The first light-emitting diode device 55A is a modified example of the light-emitting diode device 51A of Embodiment 9. FIG. 36B is a plan view illustrating a rear surface of a light-emitting diode element 54A illustrated in FIG. 36A. FIG. 36C is a plan view illustrating a principal surface of the light-emitting diode element 54A illustrated in FIG. 36A.

As illustrated in FIG. 36, the first light-emitting diode device 55A of this embodiment includes the n-type substrate 1. The n-type semiconductor layer 2e is provided on the principal surface 1a of the n-type substrate 1, and the n-type rear surface electrode 7 made of a transparent material such as indium tin oxide (ITO) is provided on the rear surface 1b of the n-type substrate 1. The through hole 8 penetrates through not only the n-type semiconductor layer 2e but also the n-type substrate 1. The n-type semiconductor layer 2e and the n-type substrate 1 constituting the inner wall of the through hole 8 are covered by the insulating film 15. Other configurations of the first light-emitting diode device 55A are the same as those of the light-emitting diode device 51A illustrated in FIGS. 28A to 28C. In FIGS. 36A to 36C, the same components as those in FIGS. 28A to 28C are denoted by the same reference symbols.

FIG. 37A is a cross-sectional view illustrating a second light-emitting diode device 55B of Embodiment 14. The second light-emitting diode device 55B is a modified example of the light-emitting diode device 51D of Embodiment 12. FIG. 37B is a plan view illustrating a rear surface of a light-emitting diode element 54B illustrated in FIG. 37A. FIG. 37C is a plan view illustrating a principal surface of the light-emitting diode element 54B illustrated in FIG. 37A.

As illustrated in FIG. 37, the second light-emitting diode device 55B of this embodiment includes the n-type substrate 1. The n-type semiconductor layer 2e is provided on the principal surface 1a of the n-type substrate 1, and the n-type rear surface electrode 7 made of a transparent material such as indium tin oxide (ITO) is provided on the rear surface 1b of the n-type substrate 1. The through hole 8 penetrates through not only the n-type semiconductor layer 2e, the active layer 3, and the p-type conductive layer 4, but also the n-type substrate 1. The n-type semiconductor layer 2e, the active layer 3, the p-type conductive layer 4, and the n-type substrate 1 constituting the inner wall of the through hole 8 are covered by the insulating film 15. Other configurations of the second light-emitting diode device 55B are the same as those of the light-emitting diode device 51D illustrated in FIGS. 32A to 32C. In FIGS. 37A to 37C, the same components as those in FIGS. 32A to 32C are denoted by the same reference symbols.

The impurity concentration of the n-type substrate 1 is, for example, 1×10¹⁷ cm⁻³ or more and 1×10¹⁸ cm⁻³ or less. The thickness of the n-type substrate 1 is, for example, about 50 μm or more and about 100 μm or less. In general, the n-type substrate 1 is ground to a predetermined thickness by polishing or the like. The n-type semiconductor layer 2e is formed on the n-type substrate 1 by epitaxial growth, and has a thickness of, for example, 3 μm or more and 10 μm or less.

As the total thickness of the n-type substrate 1 and the n-type semiconductor layer 2e becomes smaller, a larger amount of light can be extracted. However, it is difficult to perform the step of removing or peeling off the substrate from the n-type semiconductor layer 2. In particular, a GaN substrate is made of the same material as that of the n-type semiconductor layer 2e made of GaN, and hence the removal or peeling-off becomes more difficult as compared with the case of using a sapphire substrate or a SiC substrate.

According to the first and second light-emitting diode devices 55A and 55B of this embodiment, the same effects as those in Embodiments 9 and 12 can be obtained, respectively. Descriptions thereof are omitted. In addition, in this embodiment, the step of removing or peeling off the substrate can be omitted to simplify the process. GaN has high thermal conductivity, and hence, when the n-type substrate 1 is disposed between the active layer 3 and the n-type rear surface electrode 7, heat of the active layer 3 can be dissipated to the rear surface side quickly. Thus, the increase in temperature of the active layer 3 can be suppressed.

Note that, this embodiment shows the modified examples of Embodiments 9 and 12, but the substrate may be provided in the structure of Embodiment 10, 11, or 13.

### Embodiment 15

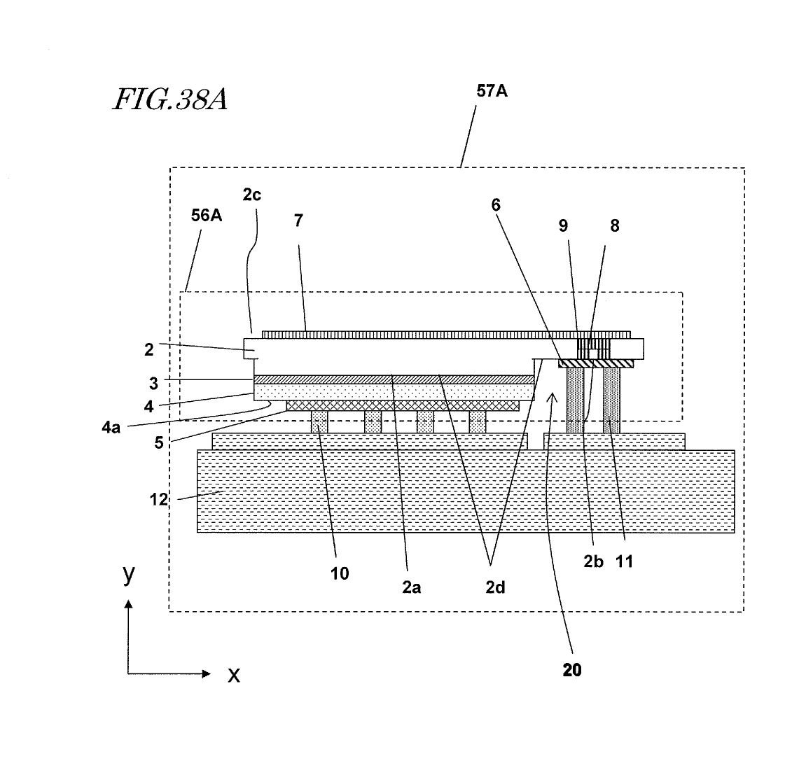

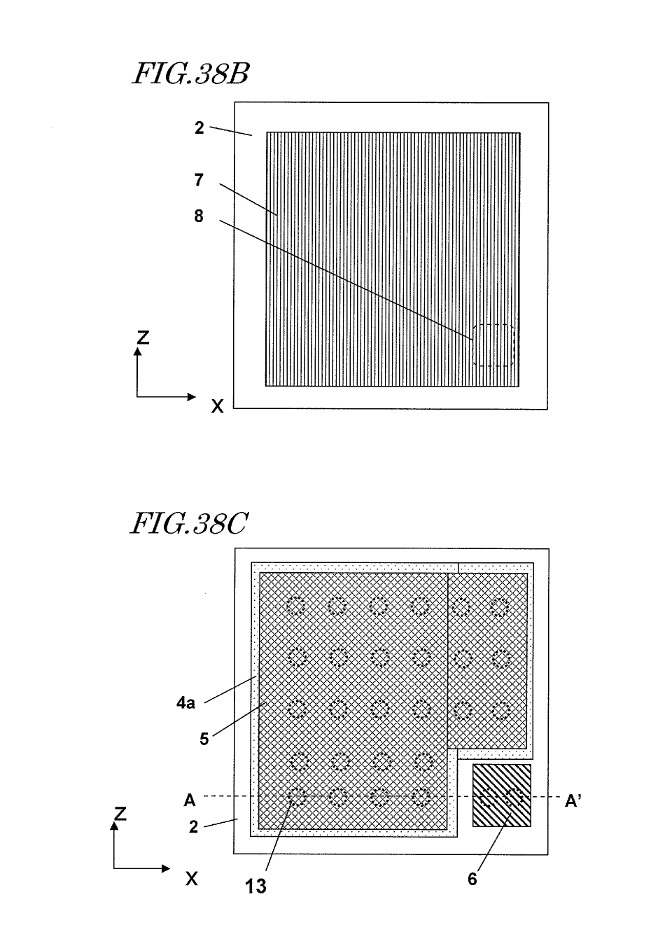

Next, a light-emitting diode device according to Embodiment 15 of the present invention is described with reference to FIGS. 38A to 41C. In this embodiment, a cavity is formed inside the through hole 8.

FIG. 38A is a cross-sectional view illustrating a first light-emitting diode device 57A of Embodiment 15. The first light-emitting diode device 57A is a modified example of the light-emitting diode device 51A of Embodiment 9. FIG. 38B is a plan view illustrating a rear surface of a light-emitting diode element 56A illustrated in FIG. 38A. FIG. 38C is a plan view illustrating a principal surface of the light-emitting diode element 56A illustrated in FIG. 38A.

In the first light-emitting diode device 57A, the conductor portion 9 is formed on the inner wall of the through hole 8. The conductor portion 9 is not filled in the through hole 8 but a cavity is formed inside the through hole 8.

Other configurations of the first light-emitting diode device 57A are the same as those of the light-emitting diode device 51A illustrated in FIGS. 28A to 28C. In FIGS. 38A to 38C, the same components as those in FIGS. 28A to 28C are denoted by the same reference symbols.

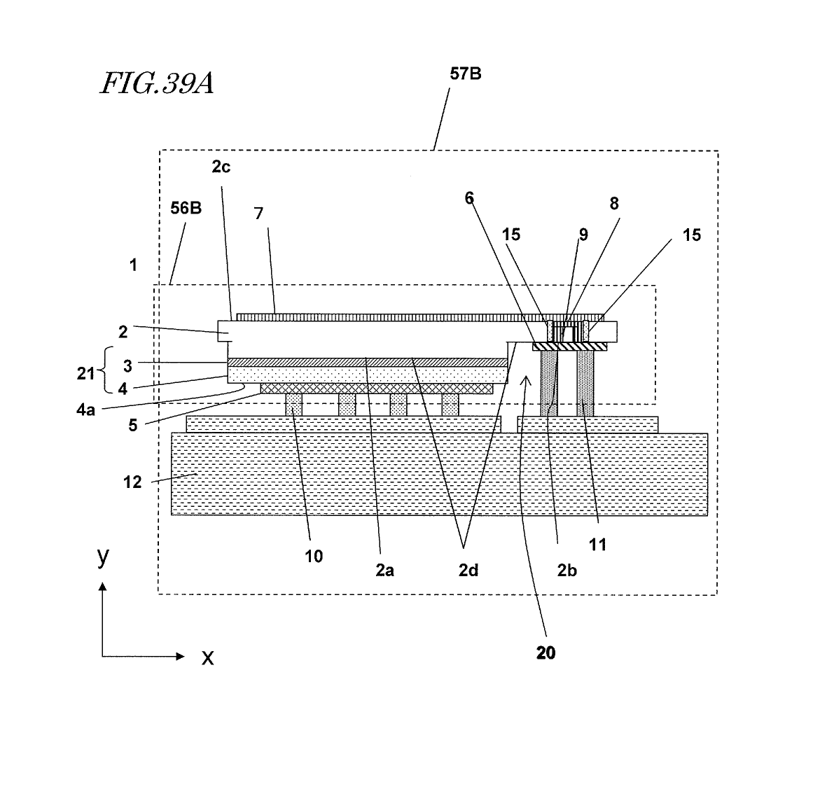

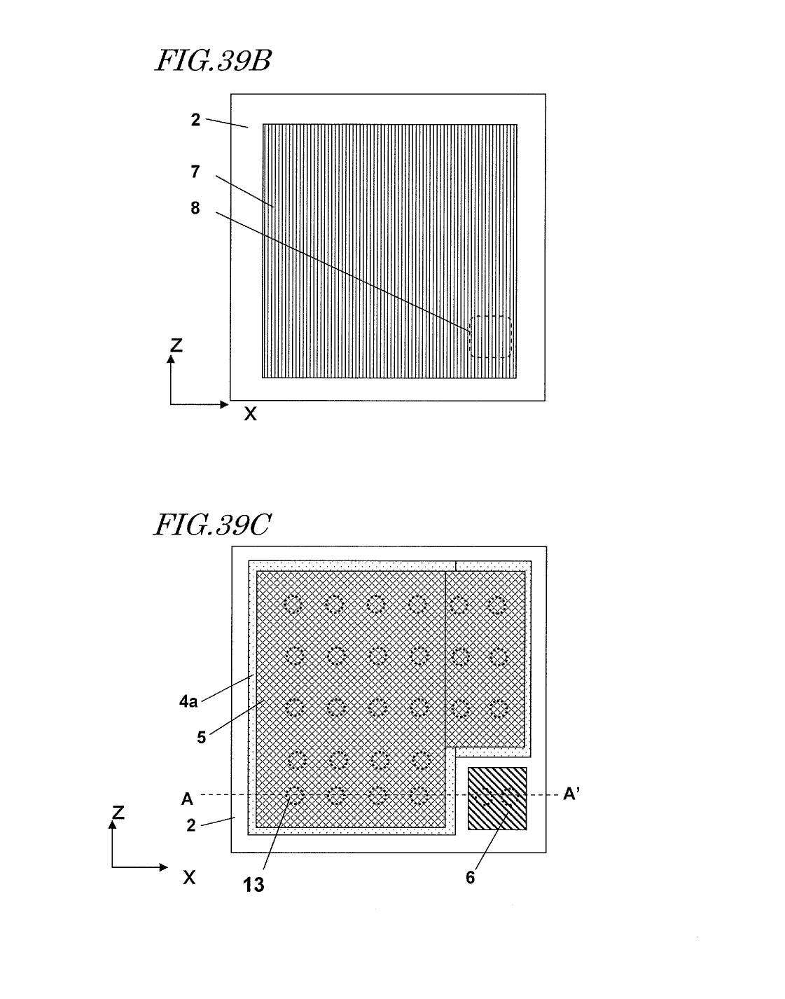

FIG. 39A is a cross-sectional view illustrating a second light-emitting diode device 57B of Embodiment 15. The second light-emitting diode device 57B is a modified example of the light-emitting diode device 51B of Embodiment 10. FIG. 39B is a plan view illustrating a rear surface of a light-emitting diode element 56B illustrated in FIG. 39A. FIG. 39C is a plan view illustrating a principal surface of the light-emitting diode element 56B illustrated in FIG. 39A.

In the second light-emitting diode device 57B, the insulating film 15 covers the inner wall of the through hole 8, and the conductor portion 9 is formed on the inner side of the insulating film 15. The conductor portion 9 is not filled in the through hole 8 but a cavity is formed inside the through hole 8.

Other configurations of the second light-emitting diode device 57B are the same as those of the light-emitting diode device 51B illustrated in FIGS. 30A to 30C. In FIGS. 39A to 39C, the same components as those in FIGS. 30A to 30C are denoted by the same reference symbols.

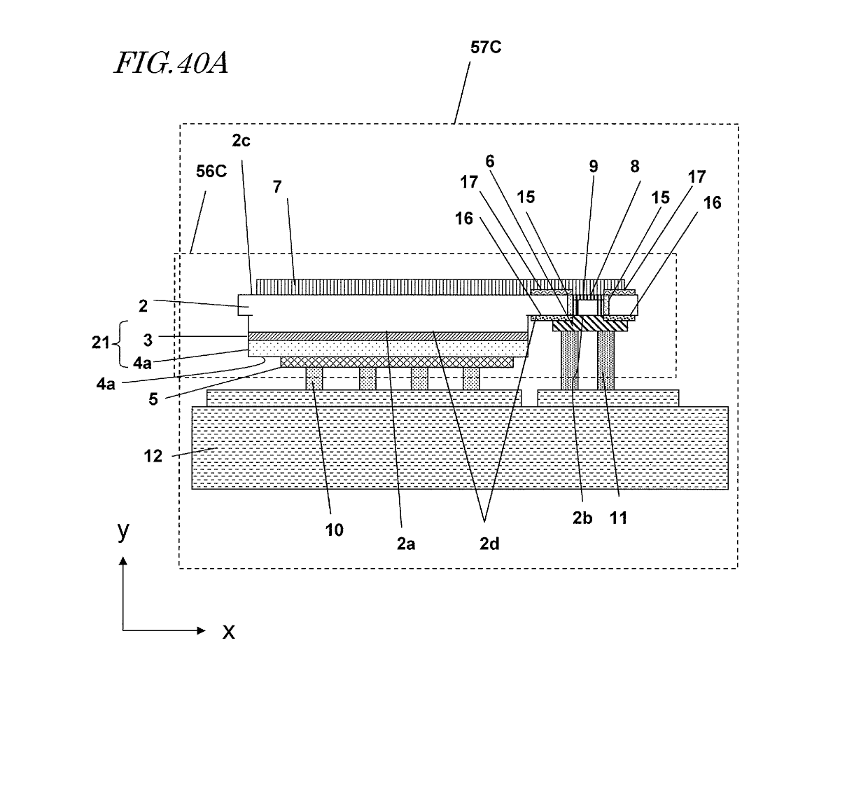

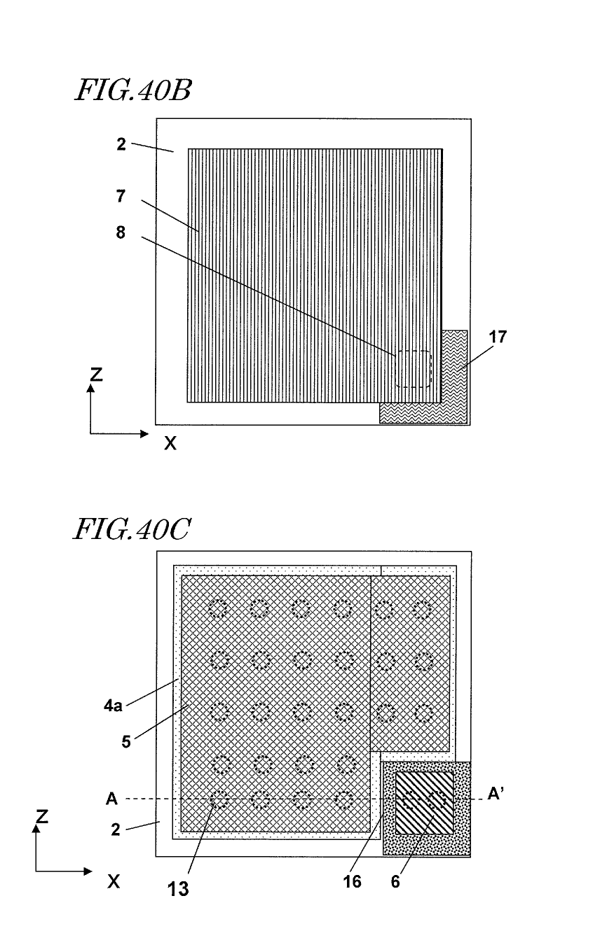

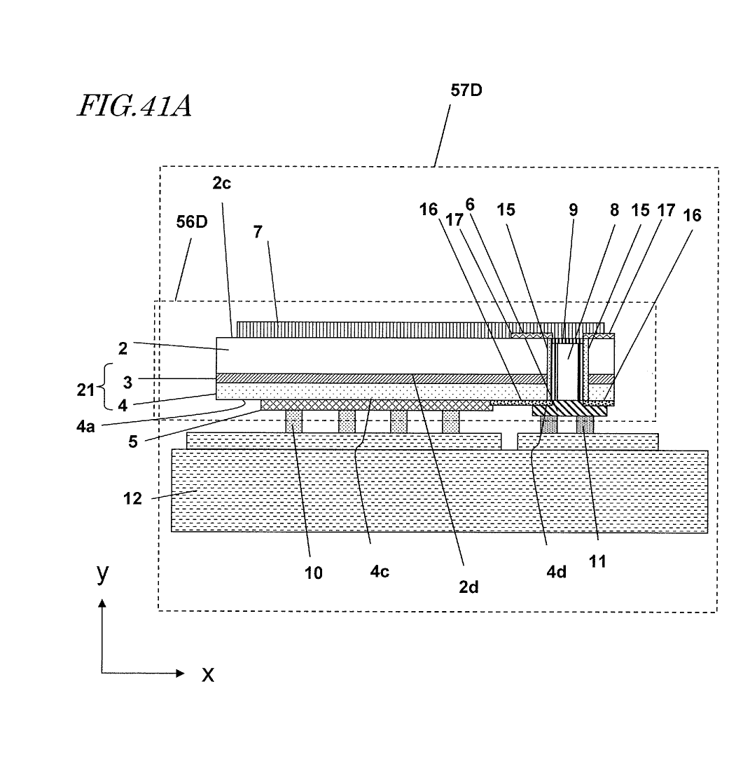

FIG. 40A is a cross-sectional view illustrating a third light-emitting diode device 57C of Embodiment 15. The third light-emitting diode device 57C is a modified example of the first light-emitting diode device 53A of Embodiment 15. FIG. 40B is a plan view illustrating a rear surface of a light-emitting diode element 56C illustrated in FIG. 40A. FIG. 40C is a plan view illustrating a principal surface of the light-emitting diode element 56C illustrated in FIG. 40A.

In the third light-emitting diode device 57C, the insulating film 15 covers the inner wall of the through hole 8, and the conductor portion 9 is formed on the inner side of the insulating film 15. The conductor portion 9 is not filled in the through hole 8 but a cavity is formed inside the through hole 8. The insulating film 17 is provided on the rear surface 2c of the n-type conductive layer 2 at a portion positioned in the vicinity of the through hole 8. The insulating film 16 is provided on the principal surface 2d of the n-type conductive layer 2 at a portion positioned in the vicinity of the through hole 8.

Other configurations of the third light-emitting diode device 57C are the same as those of the light-emitting diode device 51B illustrated in FIGS. 33A to 338C. In FIGS. 40A to 40C, the same components as those in FIGS. 33A to 33C are denoted by the same reference symbols.

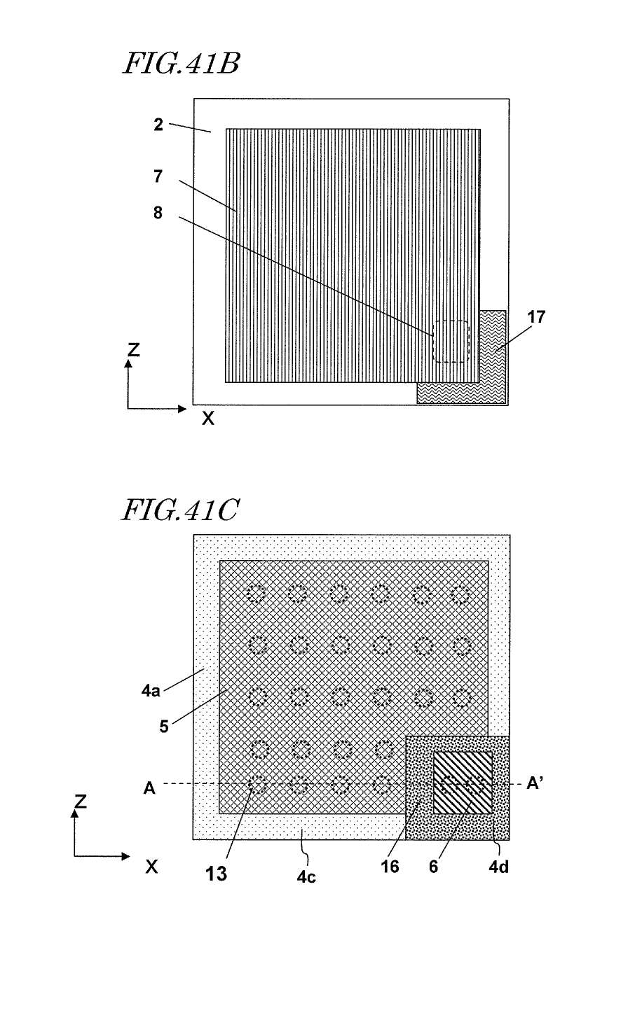

FIG. 41A is a cross-sectional view illustrating a fourth light-emitting diode device 57D of Embodiment 15. The fourth light-emitting diode device 57D is a modified example of the second light-emitting diode device 53B of Embodiment 15. FIG. 41B is a plan view illustrating a rear surface of a light-emitting diode element 56D illustrated in FIG. 41A. FIG. 41C is a plan view illustrating a principal surface of the light-emitting diode element 56D illustrated in FIG. 41A.

In the fourth light-emitting diode device 57D, the through hole 8 is provided in the n-type conductive layer 2, the active layer 3, and the p-type conductive layer 4. The insulating film 15 covers the inner wall of the through hole 8, and the conductor portion 9 is formed on the inner side of the insulating film 15. The conductor portion 9 is not filled in the through hole 8 but a cavity is formed inside the through hole 8. The insulating film 17 is provided on the rear surface of the n-type conductive layer 2 at a portion positioned in the vicinity of the through hole 8. The insulating film 16 is provided on the principal surface 2d of the n-type conductive layer 2 at a portion positioned in the vicinity of the through hole 8.

Other configurations of the fourth light-emitting diode device 57D are the same as those of the second light-emitting diode device 53B illustrated in FIGS. 34A to 34C. In FIGS. 41A to 41C, the same components as those in FIGS. 34A to 34C are denoted by the same reference symbols.

According to the first, second, third, and fourth light-emitting diode devices 57A, 57B, 57C, and 57D of this embodiment, the same effects as those in Embodiments 9, 10, and 13 can be obtained, respectively. In addition, this embodiment can obtain the following effects. A GaN light-emitting diode is apt to generate heat, and the chip temperature may increase to around 100 K. There is a large difference in coefficient of thermal expansion between GaN and Al used as the conductor portion 9, and GaN and Al have coefficients of thermal expansion of 3 to 6×10⁻⁶/K and 23×10⁻⁶/K, respectively. The cavity provided in the through hole 8 as in this embodiment can prevent a strong stress from being applied to the portion of the n-type conductive layer 2 which is positioned in the vicinity of the through hole 8 even when the conductor portion 9 expands along with the increase in element temperature. This can prevent the generation of cracks and peeling-off in the vicinity of the through hole 8.

Note that, the light-emitting diode device of this embodiment have the structure in which the cavity is provided at the center of the conductor portion 9 having the structure of Embodiment 9, 10, or 13, but a cavity may be provided at the center of the conductor portion 9 having the structure of Embodiment 11, 12, 14, or the like.

### Embodiment 16

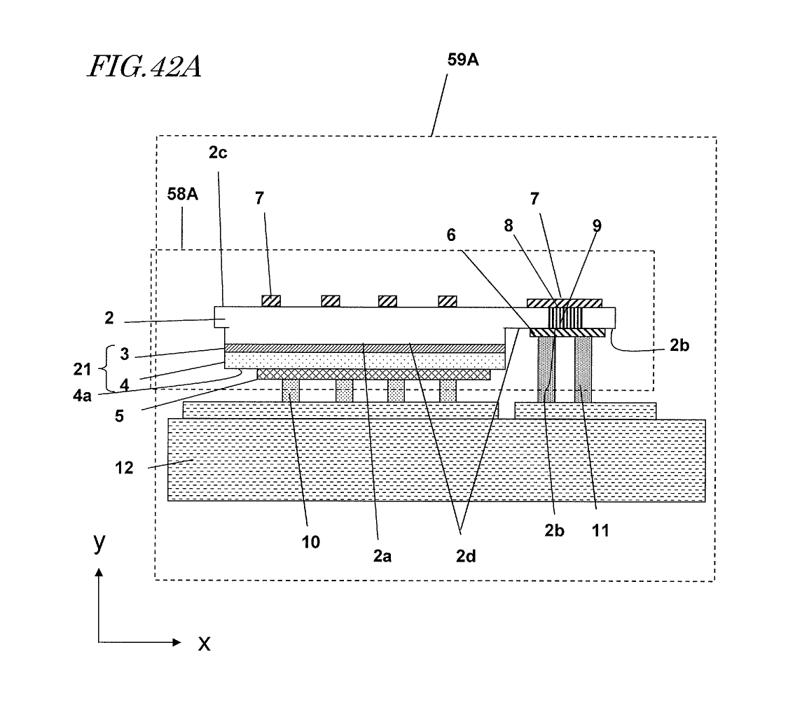

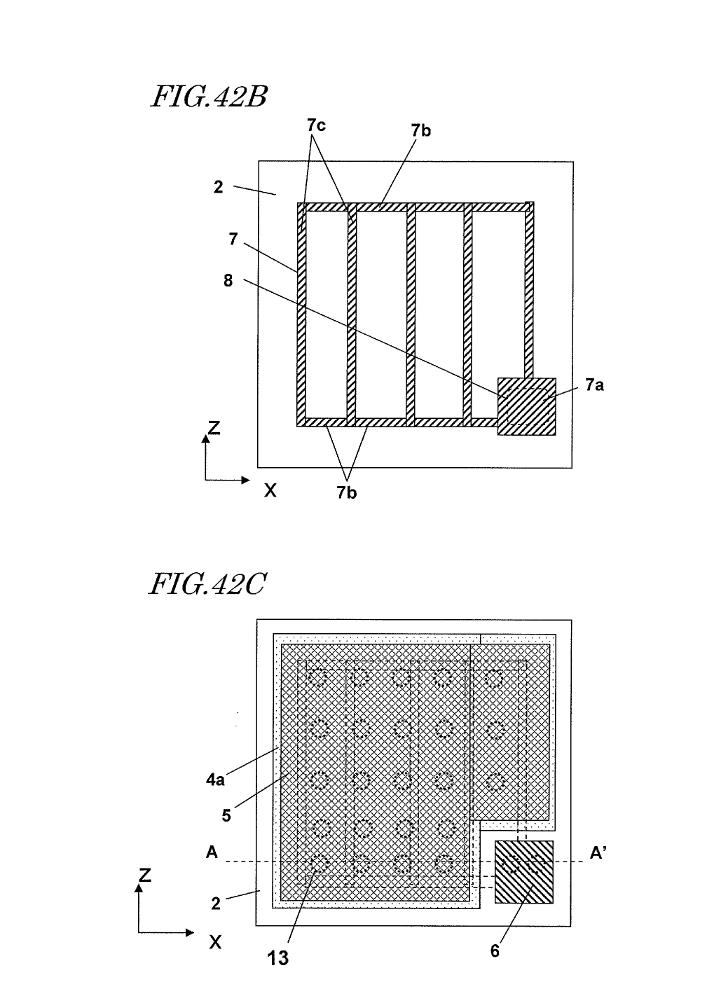

Next, a light-emitting diode device according to Embodiment 16 of the present invention is described with reference to FIGS. 42A to 44C. Although the n-type rear surface electrode 7 in Embodiments 9 to 15 is provided on the entire rear surface of the n-type conductive layer 2 (or n-type substrate 1), the n-type rear surface electrodes 7 in this embodiment are provided so as to be spaced apart from one another.

FIG. 42A is a cross-sectional view illustrating a first light-emitting diode device 59A of Embodiment 16. The first light-emitting diode device 59A is a modified example of the light-emitting diode device 51A of Embodiment 9. FIG. 42B is a plan view illustrating a rear surface of a light-emitting diode element 58A illustrated in FIG. 42A. FIG. 42C is a plan view illustrating a principal surface of the light-emitting diode element 58A illustrated in FIG. 42A.

In the first light-emitting diode device 59A of this embodiment, the n-type rear surface electrodes 7 are formed on the rear surface 2c of the n-type conductive layer 2. When seen in the direction perpendicular to the principal surface 2d of the n-type conductive layer 2 (y direction), the n-type rear surface electrode 7 is provided not only at the portion that overlaps the n-type front surface electrode 6 but also at the portion that overlaps the p-electrode 5 with the active layer 3 sandwiched therebetween. The n-type rear surface electrode 7 includes a main portion 7a covering the conductor portion (n-type through electrode) 9, linear x-direction extended portions 7b extending from the main portion 7a in the x direction, and a plurality of linear z-direction extended portions 7c extending in the z direction. The opposite ends of each of the z-direction extended portions 7c are connected to the x-direction extended portions 7b. With this, the main portion 7a, the x-direction extended portions 7b, and the z-direction extended portions 7c are all electrically connected together. In this way, the n-type rear surface electrode 7 is provided on the rear surface 2c at approximately uniform density so that the voltage can be uniformly applied to the active layer 3. Light generated in the active layer 3 is extracted at the rear surface of the n-type conductive layer 2, through the gaps between the x-direction extended portions 7b and the z-direction extended portions 7c.

Other configurations of the first light-emitting diode device 59A are the same as those of the light-emitting diode device 51A illustrated in FIGS. 28A to 28C. In FIGS. 42A to 42C, the same components as those in FIGS. 28A to 28C are denoted by the same reference symbols.

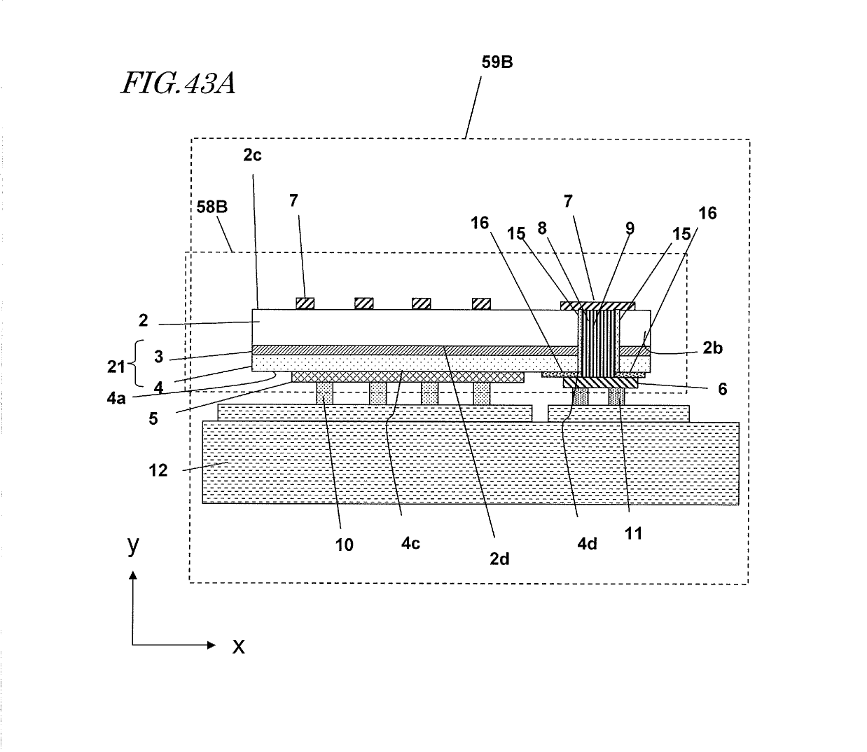

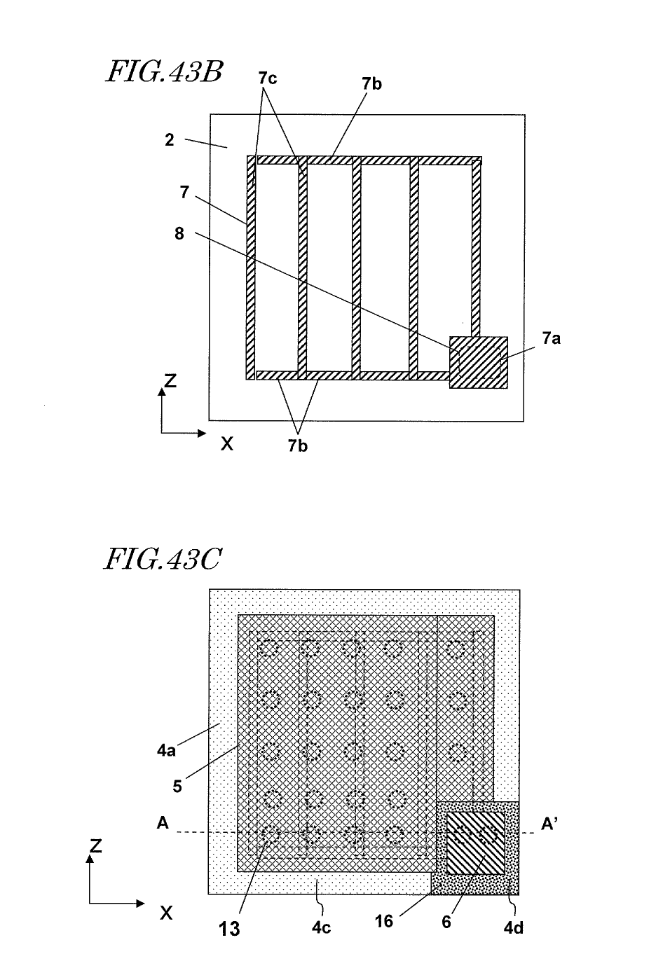

FIG. 43A is a cross-sectional view illustrating a second light-emitting diode device 59B of Embodiment 16. The second light-emitting diode device 59B is a modified example of the light-emitting diode device 51D of Embodiment 12. FIG. 43B is a plan view illustrating a rear surface of a light-emitting diode element 58B illustrated in FIG. 43A. FIG. 43C is a plan view illustrating a principal surface of the light-emitting diode element 58B illustrated in FIG. 43A.

In the second light-emitting diode device 59B of this embodiment, the n-type rear surface electrodes 7 are formed on the rear surface 2c of the n-type conductive layer 2. When seen in the direction perpendicular to the principal surface 2d of the n-type conductive layer 2 (y direction), the n-type rear surface electrode 7 is provided not only at the portion that overlaps the n-type front surface electrode 6 but also at the portion that overlaps the p-electrode 5 with the active layer 3 sandwiched therebetween. The n-type rear surface electrode 7 includes a main portion 7a covering the conductor portion 9, linear x-direction extended portions 7b extending from the main portion 7a in the x direction, and a plurality of linear z-direction extended portions 7c extending in the z direction. The opposite ends of each of the z-direction extended portions 7c are connected to the x-direction extended portions 7b. With this, the main portion 7a, the x-direction extended portions 7b, and the z-direction extended portions 7c are all electrically connected together. In this way, the n-type rear surface electrode 7 is provided on the rear surface 2c at approximately uniform density so that the voltage can be uniformly applied to the active layer 3. Light generated in the active layer 3 is extracted at the rear surface of the n-type conductive layer 2, through the gaps between the x-direction extended portions 7b and the z-direction extended portions 7c.

Other configurations of the second light-emitting diode device 59B are the same as those of the light-emitting diode device 51D illustrated in FIGS. 32A to 32C. In FIGS. 43A to 43C, the same components as those in FIGS. 32A to 32C are denoted by the same reference symbols.

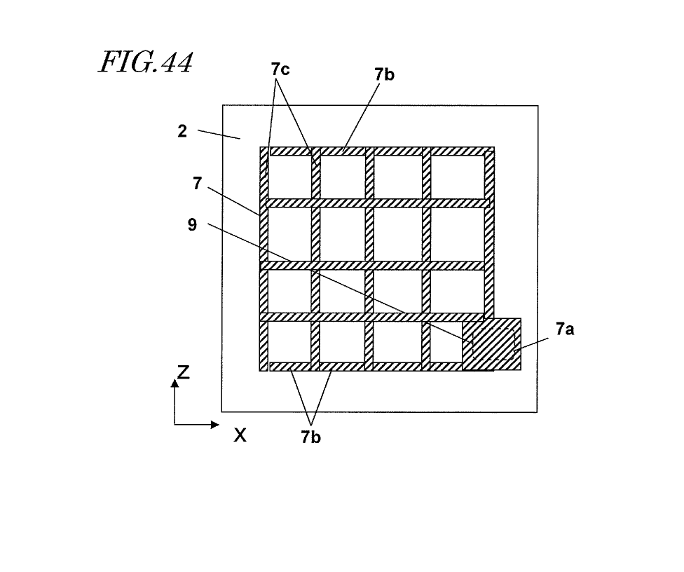

Note that, the n-type rear surface electrode 7 in this embodiment may not have the shape as illustrated in FIG. 42B or 43B. The n-type rear surface electrode 7 may have another shape, such as a lattice shape, as long as the n-type rear surface electrode 7 is disposed on the rear surface 2c at approximately uniform density and the gaps for extracting light from the rear surface 2c are provided. FIG. 44 is a plan view illustrating an n-type rear surface electrode 7 having a lattice shape.

According to the first and second light-emitting diode devices 59A and 59B of this embodiment, the same effects as those in Embodiments 9 and 12 can be obtained, respectively. In addition, in this embodiment, the gaps for extracting light are provided in the n-type rear surface electrode 7, and hence a non-transparent material can be used as the material of the n-type rear surface electrode 7. For example, metal such as Ti/Al, which has a low contact resistance and is inexpensive, can be used as the n-type rear surface electrode 7.

Note that, this embodiment is a modified example of the structures of Embodiments 9 and 12, but the n-type rear surface electrodes 7 may be spaced apart from one another in the structures of Embodiments 10, 11, 13 to 15, etc.

### Embodiment 17

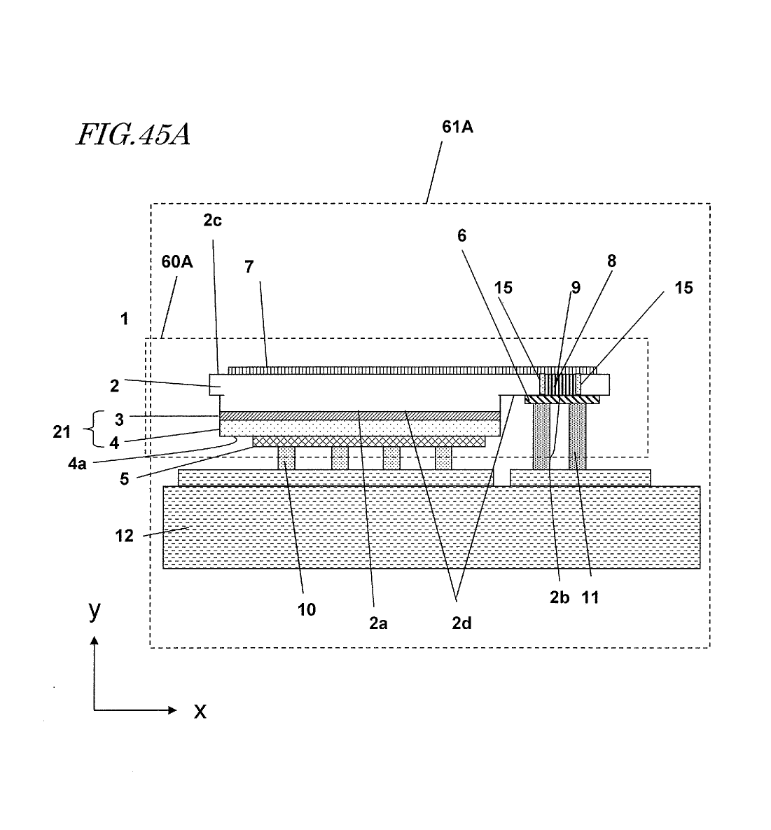

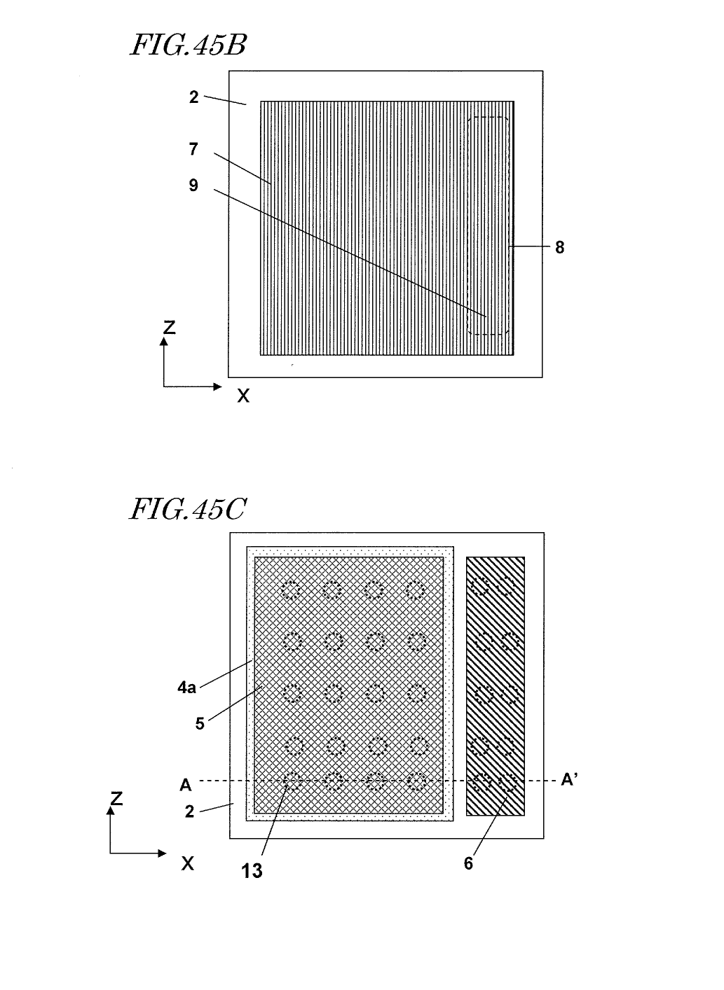

Next, a light-emitting diode device according to Embodiment 17 of the present invention is described with reference to FIG. 45A. In Embodiments 9 to 16, the through hole 8 is provided at the corner of the n-type conductive layer 2 having a square planar shape (planar shape in the direction parallel to the principal surface 2d of the n-type conductive layer 2). In this embodiment, however, the through hole 8 is formed along one side of the square.

FIG. 45A is a cross-sectional view illustrating a light-emitting diode device 61A of Embodiment 17. The light-emitting diode device 61A is a modified example of the light-emitting diode device 51B of Embodiment 10. FIG. 45B is a plan view illustrating a rear surface of a light-emitting diode element 60A illustrated in FIG. 45A. FIG. 45C is a plan view illustrating a principal surface of the light-emitting diode element 60A.

In this embodiment, the through hole 8 and the n-type front surface electrode 6 are disposed at an end (end in the x direction) of the n-type conductive layer 2 having a square planar shape. The through hole 8 and the n-type front surface electrode 6 each have the sides along the x direction and the sides along the z direction. The sides of the through hole 8 and the n-type front surface electrode 6 along the z direction are longer than the sides thereof in the x direction, and hence the through hole 8 and the n-type front surface electrode 6 each have a rectangular planar shape.

In Embodiment 10, the n-type front surface electrode 6 (illustrated in FIG. 30C etc.) is provided at the corner of the light-emitting diode element 50B having a square planar shape (at the corner seen in the direction perpendicular to the principal surface 2d of the n-type conductive layer 2), and the active layer 3, the p-type conductive layer 4, and the p-electrode 5 are provided so as to surround the periphery of the n-type front surface electrode 6. In this embodiment, on the other hand, the n-type front surface electrode 6 is formed along one side of the n-type conductive layer 2 (side along the z direction) so as to have a rectangular planar shape, and the active layer 3, the p-type conductive layer 4, and the p-electrode 5 each having a square planar shape are provided adjacent to the n-type front surface electrode 6.

The four corners of each of the through hole 8 and the n-type front surface electrode 6 may be round or substantially circular. That is, the shapes of the through hole 8 and the n-type front surface electrode 6 only need to be determined so that a desired light distribution pattern can be obtained.

Other configurations of the first light-emitting diode device 61A are the same as those of the light-emitting diode device 51B illustrated in FIGS. 30A to 30C. In FIGS. 45A to 45C, the same components as those in FIGS. 30A to 30C are denoted by the same reference symbols.

According to the light-emitting diode device 61A of this embodiment, the same effects as those in Embodiment 10 can be obtained.

In addition, in this embodiment, the p-electrode 5, the p-type conductive layer 4, and the active layer 3 each having a square planar shape are provided. Thus, as compared with Embodiment 10, a light emission distribution having no asymmetric part can be obtained. The planar shape of the active layer 3 may be any shape that can provide a desired light distribution pattern, such as a circle. According to this embodiment, a balanced configuration of light emission can be obtained.

Note that, this embodiment is a modified example of the structure of Embodiment 10, but the through hole 8 may have a rectangular planar shape in the structures of Embodiments 9, 11 to 16, etc.

According to Embodiments 9 to 17, a wire portion and a bonding portion does not make a shadow, and hence a good radiation pattern can be realized.

Note that, the above description is merely a description of exemplary embodiments, and the present invention is not limited to the above description.

The semiconductor light-emitting element of the present invention is suitably used as a light source for display devices, lighting devices, and LCD backlight devices.

While the present invention has been described with respect to embodiments thereof, it will be apparent to those skilled in the art that the disclosed invention may be modified in numerous ways and may assume many embodiments other than those specifically described above. Accordingly, it is intended by the appended claims to cover all modifications of the invention that fall within the true spirit and scope of the invention.

What is claimed is:

1. A light-emitting diode element, comprising:
a first semiconductor layer of a first conductivity type having a first front surface region, a second front surface region, and a rear surface, the first semiconductor layer being made of a gallium nitride-based compound;
a second semiconductor layer of a second conductivity type, which is provided at the first front surface region;
an active layer, which is positioned between the first semiconductor layer and the second semiconductor layer;
a first electrode, which is provided on a principal surface of the second semiconductor layer;
a first insulating film, which is provided on an inner wall of a through hole, the through hole penetrating through the first semiconductor layer and having openings in the second front surface region and the rear surface;
a conductor portion, which is provided on a surface of the first insulating film inside the through hole;
a second electrode, which is provided at the second front surface region and is in contact with the conductor portion; and
a third electrode, which is provided on the rear surface of the first semiconductor layer and is in contact with the conductor portion,
wherein, when seen in a direction perpendicular to a principal surface of the first semiconductor layer, the third electrode is provided in a region that overlaps the first electrode.

2. The light-emitting diode element of claim 1, wherein:
the first semiconductor layer includes a semiconductor substrate and a gallium nitride-based compound semiconductor layer formed on a principal surface of the semiconductor substrate;
the rear surface of the first semiconductor layer comprises a rear surface of the semiconductor substrate; and
the first front surface region and the second front surface region comprise regions on a surface of the gallium nitride-based compound semiconductor layer.

3. The light-emitting diode element of claim 1, further comprising a second insulating film, which is provided in a region of the second front surface region which is positioned around the through hole,
wherein the second electrode is provided on the second insulating film.

4. The light-emitting diode element of claim 1, wherein, when viewed in the direction perpendicular to the principal surface of the first semiconductor layer, the through hole is provided along one side of the first semiconductor layer, and the active layer is provided in a substantially square shape so as to be adjacent to a region of the first semiconductor layer in which the through hole is provided.

5. The light-emitting diode element of claim 1, wherein, when viewed in the direction perpendicular to the principal surface of the first semiconductor layer, the third electrode comprises third electrode portions disposed in the region overlapping the first electrode so that the third electrode portions are spaced apart from each other.

6. The light-emitting diode element of claim 1, wherein the through hole has a space inside surrounded by the conductor portion.

7. The light-emitting diode element of claim 1, further comprising a third insulating film, which is provided in a region of the rear surface of the first semiconductor layer which is positioned around the through hole,
wherein the third electrode is provided on a rear surface side of the third insulating film.

8. The light-emitting diode element of claim 1, wherein the first front surface region and the second front surface region comprise regions on an m-plane.

9. The light-emitting diode element of claim 1, wherein the first front surface region and the second front surface region comprise regions on a plane other than an m-plane.

10. A light-emitting diode element, comprising:
a first semiconductor layer of a first conductivity type including a semiconductor substrate of the first conductivity type and a gallium nitride-based compound semiconductor layer, the semiconductor substrate having a principal surface and a rear surface, the gallium nitride-based compound semiconductor layer being formed on the principal surface of the semiconductor substrate;
a second semiconductor layer of a second conductivity type, which is provided at a principal surface of the gallium nitride-based compound semiconductor layer;
an active layer, which is positioned between the first semiconductor layer and the second semiconductor layer;
a first electrode, which is provided in a first region of a principal surface of the second semiconductor layer;
a first insulating film, which is provided on an inner wall of a through hole, the through hole penetrating through the first semiconductor layer, the second semiconductor layer, and the active layer and having openings in a second region of the principal surface of the second semiconductor layer and in the rear surface of the semiconductor substrate;
a conductor portion, which is provided on a surface of the first insulating film inside the through hole;
a second electrode, which is provided at the second region and is in contact with the conductor portion; and
a third electrode, which is provided on the rear surface of the semiconductor substrate and is in contact with the conductor portion, wherein:
when seen in a direction perpendicular to the principal surface of the first semiconductor layer, the third electrode is provided in a region that overlaps the first electrode; and
the light-emitting diode element further comprises a second insulating film which is provided in a region of the second region which is positioned around the through hole, and the second electrode is provided on the second insulating film.

11. The light-emitting diode element of claim 10, wherein, when viewed in the direction perpendicular to the principal surface of the first semiconductor layer, the third electrode comprises third electrode portions disposed in the region overlapping the first electrode so that the third electrode portions are spaced apart from each other.

12. The light-emitting diode element of claim 10, wherein the through hole has a space inside surrounded by the conductor portion.

13. The light-emitting diode element of claim 10, further comprising a third insulating film, which is provided in a region of the rear surface of the first semiconductor layer which is positioned around the through hole,
wherein the third electrode is provided on a rear surface side of the third insulating film.

14. The light-emitting diode element of claim 10, wherein the principal surface of the gallium nitride-based compound semiconductor layer comprises an m-plane.

15. The light-emitting diode element of claim 10, wherein the principal surface of the gallium nitride-based compound semiconductor layer comprises a plane other than an m-plane.

16. A light-emitting diode device, comprising:
the light-emitting diode element of claim 1; and
a mounting base,
wherein the light-emitting diode element is disposed on the mounting base so that a side on which the first electrode and the second electrode are disposed faces the mounting base.

17. A light-emitting diode device, comprising:
the light-emitting diode element of claims 10; and
a mounting base,
wherein the light-emitting diode element is disposed on the mounting base so that a side on which the first electrode and the second electrode are disposed faces the mounting base.
